(19) United States
(12) Patent Application Publication
(10) Pub. No.: US 2026/0088799 A1
(43) Pub. Date: Mar. 26, 2026

(54) ACOUSTIC WAVE DEVICE AND ACOUSTIC WAVE FILTER DEVICE

(71) Applicant: Murata Manufacturing Co., Ltd., Nagaokakyo-shi (JP)

(72) Inventors: Katsuya DAIMON, Nagaokakyo-shi (JP); Yuta ISHII, Nagaokakyo-shi (JP); Akihiro IYAMA, Nagaokakyo-shi (JP)

(21) Appl. No.: 19/408,954

(22) Filed: Dec. 4, 2025

Related U.S. Application Data
(63) Continuation of application No. PCT/JP2024/021587, filed on Jun. 13, 2024.

(30) Foreign Application Priority Data
Jun. 13, 2023 (JP) 2023-097069

(51) Int. Cl. H03H 9/60; H03H 9/13; H03H 9/205

(52) U.S. Cl. CPC H03H 9/605; H03H 9/133; H03H 9/205

(57) ABSTRACT

An acoustic wave device includes a piezoelectric layer with first and second major surfaces, an IDT electrode on at least one of the first and second major surfaces and including electrode fingers arranged in a predetermined direction, a support facing the second major surface and including an acoustic reflection portion on the second major surface side, and a load film in a region that, in plan view in a first direction, overlaps at least one end portion of the IDT electrode in the arrangement direction. The end portion includes a first electrode finger positioned outermost in the arrangement direction, and d/p is about 0.5 or less where d is a thickness of the piezoelectric layer and p is a center-to-center distance between adjacent ones of the electrode fingers.

### CROSS REFERENCE TO RELATED APPLICATIONS

This application claims the benefit of priority to Japanese Patent Application No. 2023-097069 filed on Jun. 13, 2023 and is a Continuation Application of PCT Application No. PCT/JP2024/021587 filed on Jun. 13, 2024. The entire contents of each application are hereby incorporated herein by reference.

### BACKGROUND OF THE INVENTION

### 1. Field of the Invention

The present invention relates to acoustic wave devices and acoustic wave filter devices.

### 2. Description of the Related Art

Japanese Unexamined Patent Application Publication No. 2022-524136 and U.S. Pat. No. 11,349,450 describe acoustic wave devices.

The acoustic wave devices described in Japanese Unexamined Patent Application Publication No. 2022-524136 and U.S. Pat. No. 11,349,450 can leak acoustic waves in an arrangement direction of electrode fingers.

### SUMMARY OF THE INVENTION

Example embodiments of the present invention provide acoustic wave devices and acoustic wave filter devices that are each able to reduce or prevent acoustic wave leakage.

An acoustic wave device according to an example embodiment of the present invention includes a piezoelectric layer including a first major surface and a second major surface facing the first major surface in a first direction, an IDT electrode on at least one of the first major surface and the second major surface of the piezoelectric layer and including a plurality of electrode fingers arranged in a predetermined direction, a support facing the second major surface of the piezoelectric layer and including an acoustic reflection portion on a second major surface side of the piezoelectric layer, and a load film in a region that, in plan view in the first direction, overlaps at least one end portion of the IDT electrode in an arrangement direction of the plurality of electrode fingers, the at least one end portion includes a first electrode finger positioned outermost in the arrangement direction among the plurality of electrode fingers, and d/p is about 0.5 or less, where d is a thickness of the piezoelectric layer and p is a center-to-center distance between adjacent ones of the plurality of electrode fingers.

An acoustic wave device according to another example embodiment of the present invention includes a piezoelectric layer including a first major surface and a second major surface opposite to the first major surface, an IDT electrode on the first major surface of the piezoelectric layer and including a plurality of electrode fingers arranged in a predetermined direction, a support facing the second major surface of the piezoelectric layer, a protective film on at least one of the first major surface and the second major surface of the piezoelectric layer, and a load film in a region that does not overlap the IDT electrode on an outer side of a first electrode finger in an arrangement direction of the plurality of electrode fingers, the first electrode finger being positioned outermost among the plurality of electrode fingers in the arrangement direction of the plurality of electrode fingers, d/p is about 0.5 or less, where d is a thickness of the piezoelectric layer and p is a center-to-center distance between adjacent ones of the plurality of electrode fingers, and L/p is about 0.9 or less, where L is a distance between the first electrode finger and the load film in the arrangement direction of the plurality of electrode fingers.

An acoustic wave filter device according to another example embodiment of the present invention includes at least one connected resonator including an acoustic wave device according to an example embodiment of the present invention.

With each of acoustic wave devices and acoustic wave filter devices according to example embodiments of the present invention, acoustic wave leakage is able to be reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view of an acoustic wave device of a first example embodiment of the present invention.

FIG. 2 is a cross-sectional view along a line II-II′ in FIG. 1.

FIG. 3 is a schematic cross-sectional view for explaining a first-order thickness-shear mode bulk wave propagating in a piezoelectric layer of the first example embodiment of the present invention.

FIG. 4 is a schematic cross-sectional view for explaining a direction of amplitude of the first-order thickness-shear mode bulk wave propagating in a piezoelectric layer of the first example embodiment of the present invention.

FIG. 5 is an explanatory diagram illustrating an example of resonance characteristics of the acoustic wave device of the first example embodiment of the present invention.

FIG. 6 is an explanatory diagram illustrating a relationship between d/2p and a fractional bandwidth as a resonator in the acoustic wave device of the first example embodiment where p is the center-to-center distance, or an average center-to-center distance, between adjacent electrodes and d is the average thickness of the piezoelectric layer.

FIG. 7 is a plan view of an example of the acoustic wave device of the first example embodiment including a pair of electrodes.

FIG. 8 is a reference diagram illustrating an example of resonance characteristics of the acoustic wave device of the first example embodiment of the present invention.

FIG. 9 is an explanatory diagram illustrating a relationship in many acoustic wave resonators formed according to the acoustic wave device of the first example embodiment, between a fractional bandwidth and, as a spurious magnitude, an amount of phase rotation of a spurious impedance, which is normalized by about 180 degrees.

FIG. 10 is an explanatory diagram illustrating a relationship between d/2p, metallization ratio MR, and fractional bandwidth.

FIG. 11 is an explanatory diagram illustrating a fractional bandwidth map with respect to Euler angles (0°, θ, ψ) of LiNbO₃ as d/p is reduced infinitesimally close to zero.

FIG. 12 is an enlarged cross-sectional view of a region A illustrated in FIG. 2.

FIG. 13 is an explanatory diagram illustrating an example of admittance characteristics of the acoustic wave device according to the first example embodiment of the present invention.

FIG. 14 is an explanatory diagram illustrating an example of admittance characteristics of an acoustic wave device according to a first modification of the first example embodiment of the present invention.

FIG. 15 is an explanatory diagram illustrating an example of admittance characteristics of an acoustic wave device according to a second modification of the first example embodiment of the present invention.

FIG. 16 is an explanatory diagram illustrating an example of admittance characteristics of an acoustic wave device according to a third modification of the first example embodiment of the present invention.

FIG. 17 is a cross-sectional view of an acoustic wave device according to a fourth modification of the first example embodiment of the present invention.

FIG. 18 is an explanatory diagram illustrating an example of admittance characteristics of the acoustic wave device according to the fourth modification of the first example embodiment of the present invention.

FIG. 19 is a cross-sectional view of an acoustic wave device according to a fifth modification of the first example embodiment of the present invention.

FIG. 20 is an explanatory diagram illustrating a relationship between a number of electrode fingers overlapping a load film and phase in the acoustic wave devices according to the fourth and fifth modifications of the first example embodiment of the present invention.

FIG. 21 is a cross-sectional view of an acoustic wave device according to a sixth modification of the first example embodiment of the present invention.

FIG. 22 is an explanatory diagram illustrating an example of admittance characteristics of the acoustic wave device according to the sixth modification of the first example embodiment of the present invention.

FIG. 23 is a cross-sectional view of an acoustic wave device according to a seventh modification of the first example embodiment of the present invention.

FIG. 24 is an explanatory diagram illustrating an example of admittance characteristics of the acoustic wave device according to the seventh modification of the first example embodiment of the present invention.

FIG. 25 is a cross-sectional view of an acoustic wave device according to a second example embodiment of the present invention.

FIG. 26 is an explanatory diagram illustrating an example of admittance characteristics of the acoustic wave device according to the second example embodiment of the present invention.

FIG. 27 is a cross-sectional view of an acoustic wave device according to a third example embodiment of the present invention.

FIG. 28 is an explanatory diagram illustrating an example of admittance characteristics of the acoustic wave device according to the third example embodiment of the present invention.

FIG. 29 is an explanatory diagram illustrating a vibration mode distribution of the acoustic wave device according to the third example embodiment of the present invention.

FIG. 30 is an explanatory diagram illustrating a vibration mode distribution of the acoustic wave device according to a comparative example.

FIG. 31 is a cross-sectional view of an acoustic wave device according to an eighth modification of the third example embodiment of the present invention.

FIG. 32 is an explanatory diagram illustrating an example of admittance characteristics of the acoustic wave device according to the eighth modification of the third example embodiment of the present invention.

FIG. 33 is a cross-sectional view of an acoustic wave device according to a ninth modification of the third example embodiment of the present invention.

FIG. 34 is an explanatory diagram illustrating an example of admittance characteristics of the acoustic wave device according to the ninth modification of the third example embodiment of the present invention.

FIG. 35 is an explanatory diagram illustrating an example of admittance characteristics of an acoustic wave device according to a 10th modification of the third example embodiment of the present invention.

FIG. 36 is a cross-sectional view of an acoustic wave device according to an 11th modification of the third example embodiment of the present invention.

FIG. 37 is an explanatory diagram illustrating an example of admittance characteristics of the acoustic wave device according to the 11th modification of the third example embodiment.

FIG. 38 is an explanatory diagram illustrating a relationship between spurious phase and a Young's modulus of a load film in an acoustic wave device according to a 12th modification of the third example embodiment of the present invention.

FIG. 39 is an explanatory diagram illustrating an example of impedance characteristics of the acoustic wave device according to the third example embodiment of the present invention.

FIG. 40 is a cross-sectional view of an acoustic wave device according to a fourth example embodiment of the present invention.

FIG. 41 is an explanatory diagram illustrating an example of admittance characteristics of the acoustic wave device according to the fourth example embodiment of the present invention.

FIG. 42 is a cross-sectional view of an acoustic wave device according to a fifth example embodiment of the present invention.

FIG. 43 is an explanatory diagram illustrating an example of admittance characteristics of the acoustic wave device according to the fifth example embodiment of the present invention.

FIG. 44 is an explanatory diagram illustrating an example of admittance characteristics of an acoustic wave device according to a 13th modification of the fifth example embodiment of the present invention.

FIG. 45 is an explanatory diagram illustrating an example of admittance characteristics of an acoustic wave device according to a 14th modification of the fifth example embodiment of the present invention.

FIG. 46 is a cross-sectional view of an acoustic wave device according to a 15th modification of the fifth example embodiment of the present invention.

FIG. 47 is an explanatory diagram illustrating an example of admittance characteristics of the acoustic wave device according to the 15th modification of the fifth example embodiment of the present invention.

FIG. 48 is an explanatory diagram illustrating an example of admittance characteristics of an acoustic wave device according to a 16th modification of the fifth example embodiment of the present invention.

FIG. 49 is an explanatory diagram illustrating an example of admittance characteristics of an acoustic wave device according to a 17th modification of the fifth example embodiment of the present invention.

FIG. 50 is a cross-sectional view of an acoustic wave device according to a sixth example embodiment of the present invention.

FIG. 51 is an explanatory diagram illustrating an example of admittance characteristics of the acoustic wave device according to the sixth example embodiment of the present invention.

FIG. 52 is an explanatory diagram illustrating an example of admittance characteristics of an acoustic wave device according to an 18th modification of the sixth example embodiment of the present invention.

FIG. 53 is an explanatory diagram illustrating an example of admittance characteristics of an acoustic wave device according to a 19th modification of the sixth example embodiment of the present invention.

FIG. 54 is a cross-sectional view of an acoustic wave device according to a 20th modification of the sixth example embodiment of the present invention.

FIG. 55 is an explanatory diagram illustrating an example of admittance characteristics of the acoustic wave device according to the 20th modification of the sixth example embodiment of the present invention.

FIG. 56 is a cross-sectional view of an acoustic wave device according to a seventh example embodiment of the present invention.

FIG. 57 is an explanatory diagram illustrating an example of admittance characteristics of the acoustic wave device according to the seventh example embodiment of the present invention.

FIG. 58 is an explanatory diagram illustrating a relationship between a distance between a load film and a first electrode finger and an admittance in the acoustic wave device according to the seventh example embodiment of the present invention.

FIG. 59 is a plan view of an acoustic wave device according to an eighth example embodiment of the present invention.

FIG. 60 is a plan view of an acoustic wave device according to a 21st modification of the eighth example embodiment of the present invention.

FIG. 61 is a plan view of an acoustic wave device according to a 22nd modification of the eighth example embodiment of the present invention.

FIG. 62 is a circuit diagram illustrating an acoustic wave device according to a ninth example embodiment of the present invention.

FIG. 63 is a cross-sectional view of an acoustic wave device according to a 23rd modification of an example embodiment of the present invention.

FIG. 64 is a cross-sectional view of an acoustic wave device according to a 24th modification of an example embodiment of the present invention.

FIG. 65 is a cross-sectional view of an acoustic wave device according to a 25th modification of an example embodiment of the present invention.

FIG. 66 is an explanatory diagram illustrating an example of admittance characteristics of the acoustic wave device according to the 25th modification.

FIG. 67 is a cross-sectional view of an acoustic wave device according to a 26th modification of an example embodiment of the present invention.

FIG. 68 is an explanatory diagram illustrating an example of admittance characteristics of the acoustic wave device according to the 26th modification of an example embodiment of the present invention.

FIG. 69 is an explanatory diagram illustrating an example of admittance characteristics of an acoustic wave device according to a 27th modification of an example embodiment of the present invention.

FIG. 70 is an explanatory diagram illustrating an example of an impedance phase at high-order modes.

FIG. 71 is a cross-sectional view of an acoustic wave device according to a 28th modification of an example embodiment of the present invention.

FIG. 72 is an explanatory diagram illustrating a relationship between an offset amount of a load film and the admittance in the acoustic wave device according to the 28th modification.

FIG. 73 is a plan view of an acoustic wave device according to a 29th modification of an example embodiment of the present invention.

FIG. 74 is an explanatory diagram illustrating an example of impedance characteristics of the acoustic wave device according to the 29th modification of an example embodiment of the present invention.

FIG. 75 is an enlarged explanatory diagram illustrating a portion indicated by a dotted line Hi in FIG. 74.

FIG. 76 is a plan view of an acoustic wave device according to a 30th modification of an example embodiment of the present invention.

FIG. 77 is a plan view of an acoustic wave device according to a 31st modification of an example embodiment of the present invention.

FIG. 78 is a plan view of an acoustic wave device according to a 32nd modification of an example embodiment of the present invention.

FIG. 79 is a plan view of an acoustic wave device according to a 33rd modification of an example embodiment of the present invention.

FIG. 80 is a cross-sectional view along a line LXXX-LXXX′ in FIG. 79.

FIG. 81 is a cross-sectional view of an acoustic wave device according to a 34th modification of an example embodiment of the present invention.

FIG. 82 is an enlarged cross-sectional view of a portion of FIG. 81.

FIG. 83 is an explanatory diagram illustrating an example of admittance characteristics of the acoustic wave device according to the 34th modification of an example embodiment of the present invention.

FIG. 84 is an explanatory diagram illustrating an example of admittance characteristics of an acoustic wave device according to a 35th modification of an example embodiment of the present invention.

FIG. 85 is a plan view of an acoustic wave device according to a 36th modification of an example embodiment of the present invention.

FIG. 86 is a plan view of an acoustic wave device according to a 37th modification of an example embodiment of the present invention.

FIG. 87 is a plan view of an acoustic wave device according to a 38th modification of an example embodiment of the present invention.

FIG. 88 is a plan view of an acoustic wave device according to a 39th modification of an example embodiment of the present invention.

### DETAILED DESCRIPTION OF THE EXAMPLE EMBODIMENTS

The following describes example embodiments of the present invention in detail based on the drawings. These example embodiments will not limit the present invention. Each example embodiment described in the present disclosure is illustrative. In modifications, the second example embodiment, and the subsequent example embodiments in which configurations can be partially substituted or combined between different example embodiments, the description of the same or corresponding matters as those of the first example embodiment is omitted, and only the differences are described. The same or substantially the same advantageous operational effects due to the same or substantially the same configurations are not described in each example embodiment.

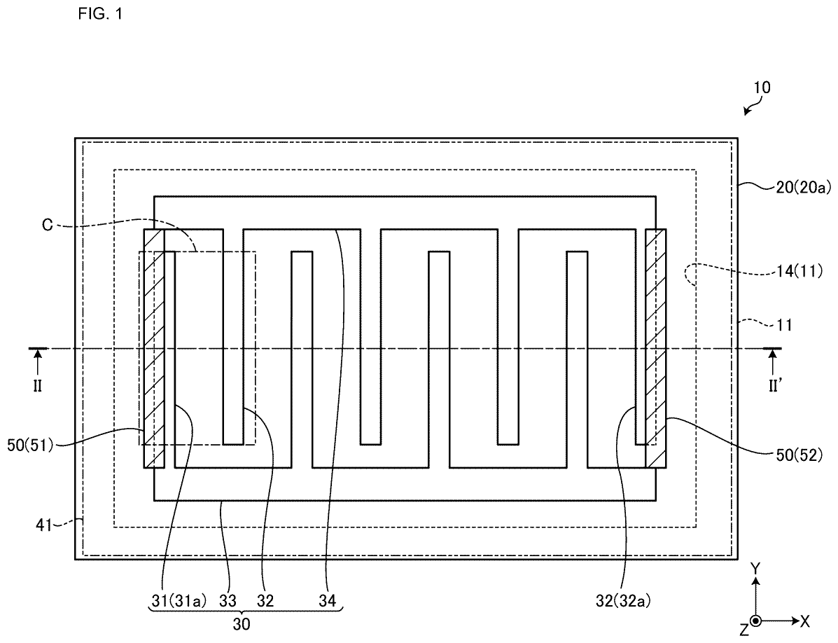

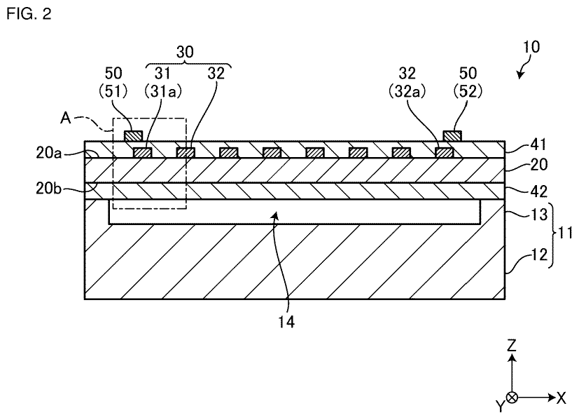

FIG. 1 is a plan view of an acoustic wave device according to a first example embodiment of the present invention. FIG. 2 is a cross-sectional view along a line II-II′ in FIG. 1. In FIG. 1, load films 50 are indicated by hatching for ease of viewing. In FIG. 1, a first protective film 41 is indicated by a long-dashed double-short dashed line.

As illustrated in FIGS. 1 and 2, an acoustic wave device according to the first example embodiment includes a piezoelectric layer 20, an interdigital transducer (IDT) electrode 30, a support substrate 11, a first protective film 41, a second protective film 42, and the load films 50. In the acoustic wave device 10, as illustrated in FIG. 2, the second protective film 42, the piezoelectric layer 20, the IDT electrode 30, the first protective film 41, and the load films 50 are sequentially laminated on the support substrate 11 in this order.

The piezoelectric layer 20 has a plate shape including a first major surface 20a and a second major surface 20b opposite to the first major surface 20a. The piezoelectric layer 20 includes, for example, lithium niobate (LiNbO₃). Alternatively, the piezoelectric layer 20 may include, for example, lithium tantalate (LiTaO₃). The cut-angle of LiNbO₃ and LiTaO₃ is the Z cut in the first example embodiment. The cut-angle of LiNbO₃ and LiTaO₃ may be a rotated Y cut or the X cut. The preferred propagation directions are, for example, Y propagation and X propagation about ±30°. Preferably, for example, the piezoelectric layer 20 includes lithium niobate (LiNbO₃) or lithium tantalate (LiTaO₃) and is a 120°±10° rotated Y cut or a 90°±10° rotated Y cut.

The thickness of the piezoelectric layer 20 is not limited but is, for example, preferably about 50 nm or more and about 1000 nm or less for effective excitation of the first-order thickness-shear mode. The film thickness of the piezoelectric layer 20 according to the first example embodiment is, for example, about 180 nm.

The interdigital transducer (IDT) electrode 30 is provided on the first major surface 20a of the piezoelectric layer 20. As illustrated in FIG. 1, the IDT electrode 30 includes electrode fingers 31 and 32 and busbar electrodes 33 and 34. The plurality of electrode fingers 31 extend in a Y direction, and ends of the electrode fingers 31 on one side in the extending direction are connected to the busbar electrode 33. The plurality of electrode fingers 32 extend in the Y direction, and ends of the electrode fingers 32 on the other side in the extending direction are connected to the busbar electrode 34. The plurality of electrode fingers 31 and the plurality of electrode fingers 32 are arranged alternately at intervals in an X direction. The busbar electrodes 33 and 34 extend in the X direction and are spaced apart from each other in the Y direction. The plurality of electrode fingers 31 and 32 are arranged between the busbar electrodes 33 and 34.

In the following description, the thickness direction of the piezoelectric layer 20 may be the Z direction, the extending direction of the electrode fingers 31 and 32 may be the Y direction, and the arrangement direction of the electrode fingers 31 and 32 may be the X direction. In the following description, plan view shows a layout when viewed in a direction vertical to the first major surface 20a of the piezoelectric layer 20.

The center-to-center distance (hereinafter, referred to as an electrode pitch) between the electrode fingers 31 and 32 is, for example, preferably in the range of about 1 μm to about 10 μm, inclusive. The electrode pitch refers to a distance between the center of the width dimension of the electrode finger 31 in a direction perpendicular or substantially perpendicular to the extending direction of the electrode finger 31 and the center of the width dimension of the electrode finger 32 in a direction perpendicular or substantially perpendicular to the extending direction of the electrode finger 32. The width (hereinafter, referred to as electrode width) of the electrode fingers 31 and 32, that is, the dimension of the electrode fingers 31 and 32 in a direction perpendicular or substantially perpendicular to the extending direction thereof, is, for example, preferably in a range of about 150 nm to about 1000 nm, inclusive.

Furthermore, when at least one of the electrode fingers 31 and 32 includes a plurality of fingers (the IDT electrode 30 includes 1.5 or more electrode pairs, each electrode pair being a pair of electrode fingers 31 and 32), the electrode pitch of the electrode fingers 31 and 32 refers to an average center-to-center distance between each electrode finger 31 and the electrode finger 32 adjacent thereto among 1.5 or more pairs of electrode fingers 31 and 32.

Since the first example embodiment uses the Z-cut piezoelectric layer, the direction perpendicular or substantially perpendicular to the extending direction of the electrode fingers 31 and 32 corresponds to the direction perpendicular or substantially perpendicular to the polarization direction of the piezoelectric layer 20. This does not apply when the piezoelectric layer 20 includes a piezoelectric substance with a different cut-angle. Here, “perpendicular” is not limited only to “exactly perpendicular” and may be “substantially perpendicular (the angle between the direction perpendicular to the extending direction of the electrode fingers 31 and 32 and the polarization direction is, for example, about 90°±10°)”.

The IDT electrode 30 (the electrode fingers 31 and 32 and the busbar electrodes 33 and 34) includes metal or alloy, such as Al or AlCu alloy, for example. In the first example embodiment, the IDT electrode 30 has a structure including, for example, an Al film laminated on a titanium (Ti) film. The IDT electrode 30 may include an adhesion layer other than Ti film.

To be more specific, for example, the electrode structure of the IDT electrode 30 includes a laminate film of Ti, AlCu, Ti, and AlCu from the piezoelectric layer 20 side. The film thicknesses thereof are, for example, about 12 nm, about 70 nm, about 18 nm, and about 12 nm, respectively. The total number of electrode fingers 31 and 32 of the IDT electrode 30 is, for example, 51. For example, the electrode pitch of the electrode fingers 31 and 32 is about 2.38 μm, and the electrode width is about 0.6 μm.

Here, an intersecting region C (an excitation region) illustrated in FIG. 1 refers to a region in which the electrode fingers 31 and 32 overlap each other when viewed in the X direction. The length of the intersecting region C refers to the dimension of the intersecting region C in the extending direction of the electrode fingers 31 and 32. In the first example embodiment, the length of the intersecting region C is, for example, about 40 μm.

For driving the acoustic wave device 10, alternating-current voltage is applied across the plurality of electrode fingers 31 and the plurality of electrode fingers 32. More specifically, alternating-current voltage is applied across the busbar electrodes 33 and 34. This can provide resonance characteristics using the first-order thickness-shear mode bulk wave excited in the piezoelectric layer 20.

In the acoustic wave device 10, for example, d/p is set to about 0.5 or less. Here, d is the thickness of the piezoelectric layer 20, and p is the electrode pitch of the plurality of pairs of electrode fingers 31 and 32. This enables effective excitation of the first-order thickness-shear mode bulk wave, thus achieving favorable resonance characteristics. More preferably, for example, d/p is about 0.24 or less. In this case, more favorable resonance characteristics can be achieved.

In the acoustic wave device 10 of the first example embodiment, due to the above-described configuration, the Q factor is unlikely to decrease even if the number of pairs of electrode fingers 31 and 32 is reduced to achieve size reduction. This is because the acoustic wave device 10 is a resonator that does not require reflectors on either side and has lower propagation loss. Furthermore, the acoustic wave device 10 does not require reflectors because the acoustic wave device 10 uses the first-order thickness-shear mode bulk wave.

The first protective film 41 is provided on the first major surface 20a of the piezoelectric layer 20, covering the IDT electrode 30. The second protective film 42 is provided on the second major surface 20b of the piezoelectric layer 20. The first and second protective films 41 and 42 include, for example, silicon oxide (SiO₂). In addition to silicon oxide, the first and second protective films 41 and 42 may include a proper insulating material, such as silicon nitride or alumina, for example. The film thicknesses of the first and second protective films 41 and 42 are each greater than the film thickness of the IDT electrode 30. The film thicknesses of the first and second protective films 41 and 42 are, for example, about 142 nm, respectively. The acoustic wave device 10 needs to include at least one of the first protective film 41 and the second protective film 42. For example, the first protective film 41 may be provided while the second protective film 42 is not provided.

The load films 50 are provided on the first protective film 41. One of the load films 50 is provided in a region overlapping an electrode finger 31 (hereinafter, referred to as a first electrode finger 31a) that, among the plurality of electrode fingers 31 and 32, is positioned outermost in the arrangement direction of the plurality of electrode fingers 31 and 32. Another load film 50 is provided in a region overlapping the electrode finger 32 (hereinafter, referred to as a second electrode finger 32a) that is positioned outermost on the opposite side to the first electrode finger 31a.

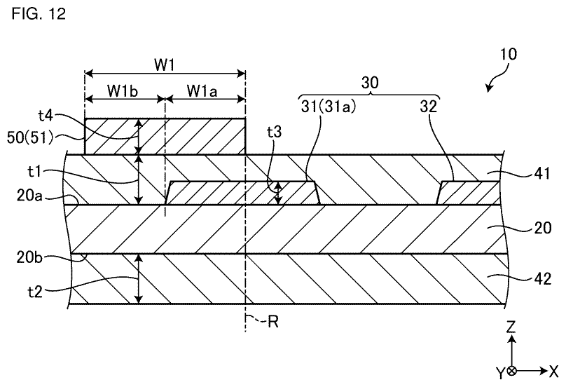

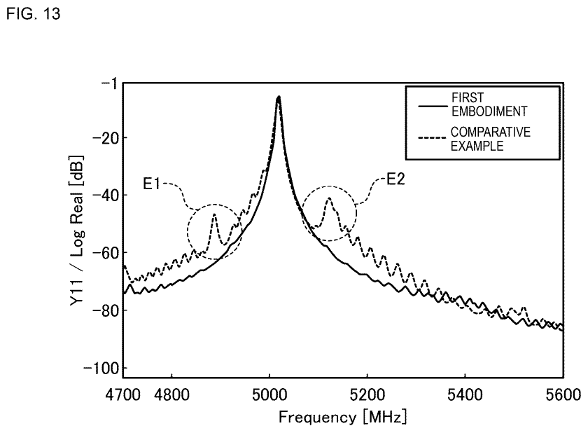

A portion of the load film 50 overlapping the first electrode finger 31a is referred to as a first extending portion 51, and a portion overlapping the second electrode finger 32a is referred to as a second extending portion 52. The first and second extending portions 51 and 52 are spaced apart from each other in the arrangement direction of the plurality of electrode fingers 31 and 32, and the plurality of electrode fingers 31 and 32 are arranged between the first and second extending portions 51 and 52. The first extending portion 51 overlaps a portion of the first electrode finger 31a and extends in the extending direction of the first electrode finger 31a. The second extending portion 52 overlaps a portion of the second electrode finger 32a and extends in the extending direction of the second electrode finger 32a. The configuration of the load films 50 will be described later in detail with FIGS. 12 and 13.

The support substrate 11 (support) is disposed facing the second major surface 20b of the piezoelectric layer 20. The support substrate 11 includes a cavity portion 14 (a space portion) on the surface facing the second major surface 20b of the piezoelectric layer 20. To be more specific, the support substrate 11 includes a bottom portion 12 and a wall portion 13 provided in a frame shape on the upper surface of the bottom portion 12. The cavity portion 14 is provided in a space bounded by the bottom portion 12 and the wall portion 13. The piezoelectric layer 20 is laminated on the upper surface of the wall portion 13 of the support substrate 11 with the second protective film 42 interposed therebetween. In such a manner, the acoustic wave device 10 has a membrane structure in which the cavity portion 14 (the hollow portion) is provided on the second major surface 20b side of the piezoelectric layer 20. The support may include the support substrate 11 and an intermediate (insulating) layer. That is, the support substrate 11 may be indirectly laminated on the second major surface 20b of the piezoelectric layer 20. In this case, the support substrate 11 and the intermediate layer each have a frame shape, thus defining the cavity portion 14. Alternatively, the intermediate layer may include a recess portion, thus defining the cavity portion 14.

The cavity portion 14 is provided so that vibration in the intersecting region C of the piezoelectric layer 20 is not hindered. The second protective film 42 covers the opening of the cavity portion 14. However, the second protective film 42 does not need to be provided as described above. In such a case, the support substrate 11 can be directly laminated on the second major surface 20b of the piezoelectric layer 20. Alternatively, the second protective film 42 is provided in a region between the upper surface of the wall portion 13 and the second major surface 20b of the piezoelectric layer 20 and does not need to be provided in a region overlapping the cavity portion 14.

The support substrate 11 includes, for example, silicon (Si). The plane orientation of Si in the surface on the piezoelectric layer 20 side may be (100), (110), or (111). Preferably, the Si has a high resistance with a resistivity of, for example, about 4 kΩ or higher. The support substrate 11 can include a proper insulating or semiconductor material. Examples of the material of the support substrate 11 include piezoelectric substances such as aluminum oxide, lithium tantalate, lithium niobate, or quartz crystal, various ceramics such as alumina, magnesia, sapphire, silicon nitride, aluminum nitride, silicon carbide, zirconia, cordierite, mullite, steatite, or forsterite, dielectric substances such as diamond or glass, and semiconductors such as gallium nitride.

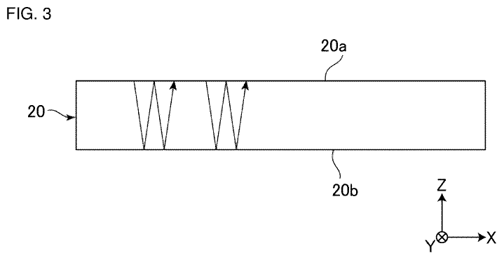

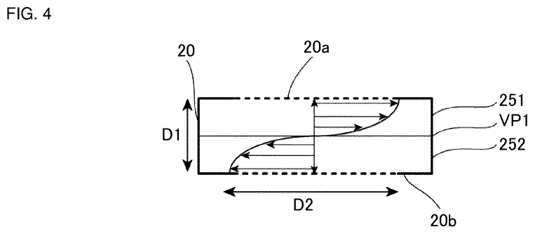

FIG. 3 is a schematic cross-sectional view for explaining the first-order thickness-shear mode bulk wave propagating in the piezoelectric layer of the first example embodiment. FIG. 4 is a schematic cross-sectional view for explaining the direction of amplitude of the first-order thickness-shear mode bulk wave propagating in the piezoelectric layer of the first example embodiment.

As illustrated in FIG. 3, in the acoustic wave device 10 of the first example embodiment, the vibration displacement occurs in the thickness-shear direction, and the wave propagates substantially in the direction connecting the first and second major surfaces 20a and 20b of the piezoelectric layer 20, that is, in the Z direction and resonates. This means that the wave component in the X direction is significantly smaller than that in the Z direction. This wave propagation in the Z direction provides the resonance characteristics, thus eliminating the need for reflectors. Therefore, propagation loss due to reflectors does not occur, and the Q factor is unlikely to decrease even if the number of electrode pairs of electrode fingers 31 and 32 is reduced to achieve size reduction.

As illustrated in FIG. 4, the direction of amplitude of the first-order thickness-shear mode bulk wave is reversed between a first region 251 included in the intersecting region C (see FIG. 1) of the piezoelectric layer 20 and a second region 252 included in the intersecting region C. FIG. 4 schematically illustrates a bulk wave when a voltage is applied across the electrode finger 31 and the electrode finger 32 such that the potential of the electrode finger 32 is higher than that of the electrode finger 31. Here, a virtual plane VP1 is a plane that is perpendicular or substantially perpendicular to the thickness direction of the piezoelectric layer 20 and divides the piezoelectric layer 20 into two. The first region 251 is a region between the virtual plane VP1 and the first major surface 20a in the intersecting region C. The second region 252 is a region between the virtual plane VP1 and the second major surface 20b in the intersecting region C.

In the acoustic wave device 10, at least one pair of electrodes including the electrode fingers 31 and 32 are provided. However, since waves do not propagate in the X direction, the number of electrode pairs including the electrode fingers 31 and 32 does not need to be more than one. That is, it is sufficient that at least one pair of electrodes is provided.

For example, the electrode finger 31 is an electrode coupled to a hot potential, and the electrode finger 32 is an electrode coupled to a ground potential. The electrode finger 31 may be coupled to the ground potential while the electrode finger 32 is coupled to a hot potential. In the first example embodiment, at least one pair of electrodes includes an electrode coupled to a hot potential and an electrode coupled to the ground potential as described above, and no floating electrode is provided.

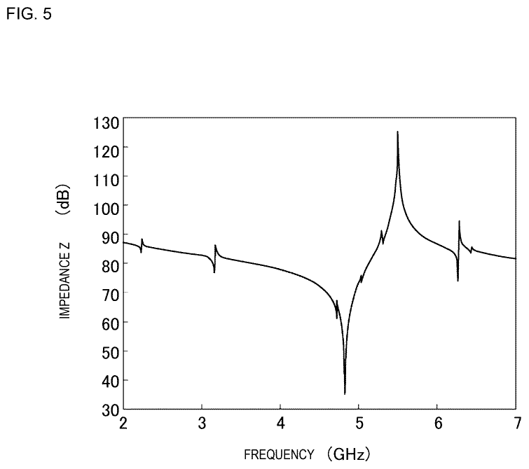

FIG. 5 is an explanatory diagram illustrating an example of the resonance characteristics of the acoustic wave device of the first example embodiment. The design parameters of the acoustic wave device 10 that achieved the resonance characteristics illustrated in FIG. 5 are as follows:
Piezoelectric layer 20: LiNbO₃ with Euler angles (0°, 0°, 90°)
Thickness of piezoelectric layer 20: about 400 nm
Length of intersecting region C: about 40 μm
Number of pairs of electrodes, including electrode fingers 31 and 32: 21 pairs
Electrode pitch of electrode fingers 31 and 32: about 3 μm
Width of electrode fingers 31 and 32: about 500 nm
d/p: about 0.133
First protective film 41, second protective film 42: about 1 μm-thick silicon oxide film
Support substrate 11: Si

In the first example embodiment, the electrode pitch of each pair of electrodes, including the electrode fingers 31 and 32, is the same or substantially the same for all pairs. That is, the electrode fingers 31 and 32 are disposed at equal or substantially pitches.

As seen from FIG. 5, the acoustic wave device 10 achieves good resonance characteristics with a fractional bandwidth of about 12.5% despite not including reflectors.

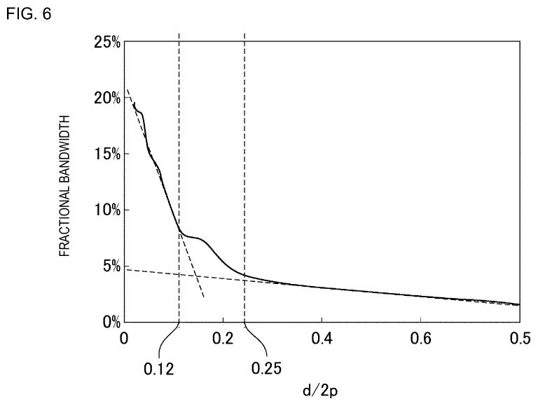

In the first example embodiment about, d/p is about 0.5 or less, more preferably, about 0.24 or less, where d is the thickness of the piezoelectric layer 20 and p is the electrode pitch of the electrode fingers 31 and 32. This will be described with reference to FIG. 6.

FIG. 6 is an explanatory diagram illustrating the relationship between d/2p and the fractional bandwidth as a resonator in the acoustic wave device of the first example embodiment where p is the center-to-center distance, or average center-to-center distance, between adjacent electrodes and d is the average thickness of the piezoelectric layer. In FIG. 6, multiple acoustic wave devices were obtained in the same or substantially the same manner as the acoustic wave device that achieved the resonance characteristics illustrated in FIG. 5, except that d/2p was varied.

As illustrated in FIG. 6, for example, when d/2p exceeds about 0.25, that is, when d/p>about 0.5, the fractional bandwidth is lower than 5% even if d/p is adjusted. In contrast, when d/2p about 0.25, that is, when d/p≤about 0.5, the fractional bandwidth can be about 5% or higher by varying d/p within the above range. This can provide a resonator with a high electromechanical coupling coefficient. When d/2p is about 0.12 or less, that is, when d/p is about 0.24 or less, the fractional bandwidth can be increased to about 7% or higher. In addition, when d/p is adjusted within this range, a resonator with a wider fractional bandwidth can be obtained, and a resonator with a higher electromechanical coupling coefficient can be achieved. This reveals that, for example, by setting d/p to about 0.5 or less, a resonator that uses the first-order thickness-shear mode bulk wave and has a high electromechanical coupling coefficient can be provided.

When the piezoelectric layer 20 varies in thickness, the thickness d of the piezoelectric layer 20 may use the average thickness.

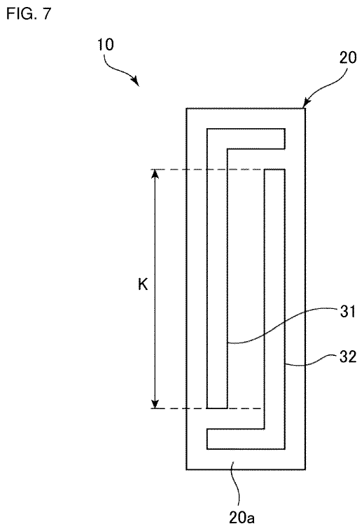

FIG. 7 is a plan view of an example of the acoustic wave device of the first example embodiment including a pair of electrodes. In the acoustic wave device 10, a pair of electrodes, including the electrode fingers 31 and 32, is provided on the first major surface 20a of the piezoelectric layer 20. K in FIG. 7 indicates an intersecting width. As described above, the number of pairs of electrodes may be one in the acoustic wave device 10 of the present invention. In this case as well, the first-order thickness-shear mode bulk wave can be effectively excited when d/p is about 0.5 or less, for example.

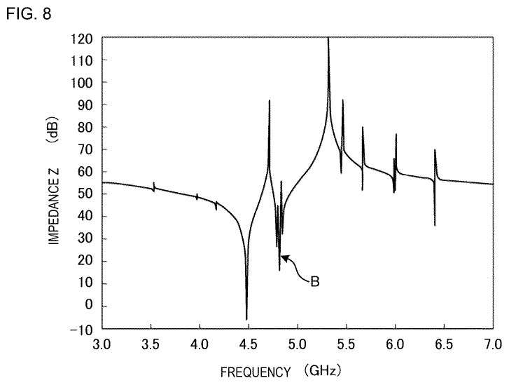

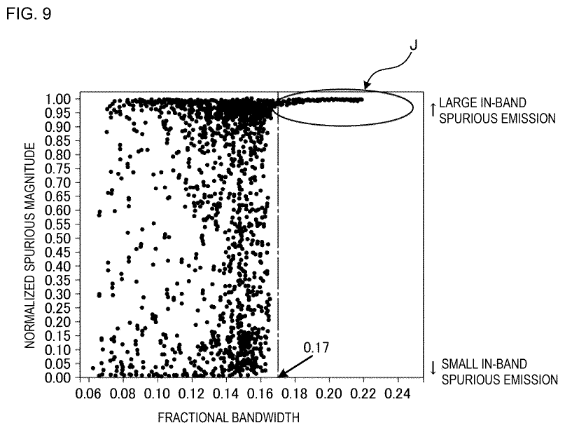

In the acoustic wave device 10, for example, preferably, a metallization ratio MR of the adjacent electrode fingers 31 and 32 to the intersecting region C satisfies MR about 1.75(d/p)+0.075. In this case, spurious emissions can be effectively reduced. This will be described with reference to FIGS. 8 and 9.

FIG. 8 is a reference diagram illustrating an example of the resonance characteristics of the acoustic wave device of the first example embodiment. As illustrated in FIG. 8, a spurious emission indicated by arrow B appears between the resonant frequency and the anti-resonant frequency. Here, d/p was set to about 0.08, and Euler angles of LiNbO₃ were set to (0°, 0°, 90°). The above-described metallization ratio MR was set to about 0.35.

The metallization ratio MR will be described with reference to FIG. 1. Focusing on a pair of electrode fingers 31 and 32 in the electrode structure of FIG. 1, it is assumed that only this pair of electrode fingers 31 and 32 is provided. In this case, the portion bounded by the dashed-dotted line is the intersecting region C. This intersecting region C includes a region of the electrode finger 31 that overlaps the electrode finger 32 as the electrode fingers 31 and 32 are seen in the direction perpendicular or substantially perpendicular to the extending direction of the electrode fingers 31 and 32, that is, in the direction that the electrode fingers 31 and 32 face each other, a region of the electrode finger 32 that overlaps the electrode finger 31, and a region in which the electrode fingers 31 and 32 overlap each other within the region between the electrode fingers 31 and 32. The metallization ratio MR is the total area of the electrode fingers 31 and 32 within the intersecting region C with respect to the area of the excitation region C. That is, the metallization ratio MR is the ratio of the area of the metallized portion to the area of the intersecting region C.

When more than one pair of electrode fingers 31 and 32 is provided, MR can be defined as a ratio of the metallized portion included in all of the intersecting regions C to the total area of the intersecting regions C.

FIG. 9 is an explanatory diagram illustrating the relationship in many acoustic wave resonators formed according to the acoustic wave device of the first example embodiment, between the fractional bandwidth and, as the spurious magnitude, the amount of phase rotation of spurious impedance, which is normalized by about 180 degrees. The fractional bandwidth is adjusted by variously changing the film thickness of the piezoelectric layer 20 and the dimensions of the electrode fingers 31 and 32. FIG. 9 is the results when the piezoelectric layer 20 includes Z-cut LiNbO₃. However, the results for the piezoelectric layer 20 with different cut-angles produce the same tendency.

In the region bounded by an ellipse J in FIG. 9, spurious emissions are as large as about 1.0. As can be seen in FIG. 9, when the fractional bandwidth is greater than about 0.17, that is, greater than about 17%, large spurious emissions with a spurious level of not less than about 1 appear in the pass band even if the parameters of the fractional bandwidth are changed. As in the resonance characteristics illustrated in FIG. 8, the large spurious emission indicated by the arrow B appears in the band. Preferably, for example, the fractional bandwidth is therefore not greater than about 17%. In this case, spurious emissions can be reduced by adjusting the film thickness of the piezoelectric layer 20, dimensions of the electrode fingers 31 and 32, and other parameters.

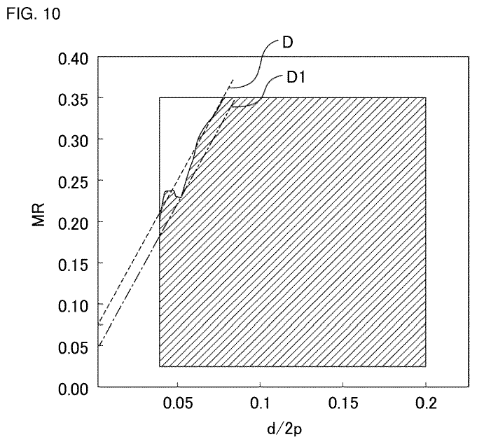

FIG. 10 is an explanatory diagram illustrating the relationship between d/2p, the metallization ratio MR, and the fractional bandwidth. Various acoustic wave devices 10 varying in d/2p and MR were produced according to the acoustic wave device 10 of the first example embodiment, and the fractional bandwidth thereof was measured. The hatched portion to the right of a dashed line D in FIG. 10 is a region in which the fractional bandwidth is about 17% or less. The boundary between the region with hatching and the region without hatching is represented by MR=about 3.5(d/2p)+0.075, that is, MR=about 1.75(d/p)+0.075. Preferably, for example, therefore, MR≤about 1.75(d/p)+0.075. In this case, the fractional bandwidth can be easily set to about 17% or less. The region to the right of MR=about 3.5(d/2p)+0.05 indicated by a dashed-dotted line D1 in FIG. 10 is more preferred. That is, when MR about 1.75(d/p)+0.05, the fractional bandwidth can be reliably about 17% or less.

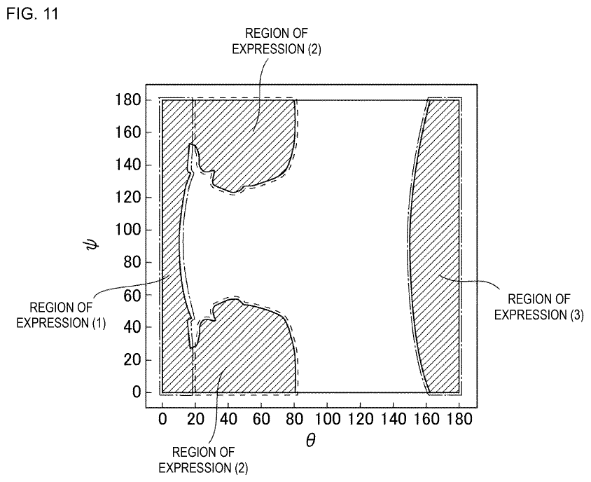

FIG. 11 is an explanatory diagram illustrating a fractional bandwidth map with respect to Euler angles (0°, Q, $) of LiNbO₃ as d/p is reduced infinitesimally close to zero. The hatched portions in FIG. 11 indicate regions in which the fractional bandwidth is at least about 5%. The ranges of these regions are approximated by the ranges represented by the following expressions (1), (2), and (3):

(0°±10°, 0° to 20°, any ψ) Expression (1)

(0°±10°, 20° to 80°, 0° to 60° (1−(θ−50)²/900)^{1/2}) or (0°±10°, 20° to 80°, [180°−60°(1−(θ−50)²/900)^{1/2}] to 180°) Expression (2)

(0°±10°, [180°−30° (1−(ψ−90)²/8100)^{1/2}] to 180°, any ψ) Expression (3)

It is therefore preferable that the Euler angles are within the range represented by Expression (1), (2), or (3) because the fractional bandwidth can be widened sufficiently.

Next, the configuration of the load films 50 will be described in detail. FIG. 12 is an enlarged cross-sectional view of a region A illustrated in FIG. 2. In FIG. 12, the load film 50 (the first extending portion 51) overlapping the first electrode finger 31a, which is positioned outermost in the arrangement direction of the plurality of electrode fingers 31 and 32, will be described. The second extending portion 52 (see FIGS. 1 and 2), which overlaps the second electrode finger 32a positioned outermost on the opposite side to the first electrode finger 31a, has a symmetrical layout relative to the first extending portion 51. The description of the first extending portion 51 can be applied to the second extending portion 52. In the following description, when there is no need to distinguish between the first and second extending portions 51 and 52, they are simply referred to as the load films 50.

As illustrated in FIG. 12, the load film 50 is provided on the first protective film 41 and overlaps a portion of the first electrode finger 31a. In the first example embodiment, the upper surface of the first protective film 41 is flat. Specifically, the upper surface of the first protective film 41 is flat or substantially flat across the region in which the electrode fingers 31 and 32 are provided and the region in which no electrode fingers 31 and 32 are provided.

The load film 50 protrudes from the upper surface of the first protective film 41. In the region overlapping the first electrode finger 31a, the load film 50 and the first protective film 41 define a step. To be more specific, the acoustic wave device 10 includes a region in which the first electrode finger 31a and the first protective film 41 are laminated in this order on the first major surface 20a of the piezoelectric layer 20, a region in which the first electrode finger 31a, the first protective film 41, and the load film 50 are laminated in this order, and a region in which the first protective film 41 and the load film 50 are laminated in this order. In the region overlapping the first electrode finger 31a, a portion where the first protective film 41 is provided and no load film 50 is provided and a portion where the load film 50 and the first protective film 41 are laminated define a step.

The load film 50 is positioned offset outwardly relative to the first electrode finger 31a in the arrangement direction of the plurality of electrode fingers 31 and 32. One of the side surfaces of the load film 50 is disposed overlapping the widthwise midpoint of the first electrode finger 31a, and the other side surface of the load film 50 is positioned on the outer side of the first electrode finger 31a in the arrangement direction. That is, the load film 50 includes an overlap region that overlaps the first electrode finger 31a and a non-overlap region that does not overlap the first electrode finger 31a. A width W1 of the load film 50 is, for example, about 0.8 μm. A width W1a of the overlap region of the load film 50 is, for example, about 0.3 μm. A width W1b of the non-overlap region of the load film 50 is, for example, about 0.5 μm.

In the first example embodiment, a film thickness t4 of the load film 50 is, for example, about 55 nm. As described above, a film thickness t1 of the first protective film 41 and a film thickness t2 of the second protective film 42 are, for example, about 142 nm, and a film thickness t3 of the IDT electrode 30 is, for example, about 112 nm. The film thickness t1 of the first protective film 41 is greater than the film thickness t4 of the load film 50 and the film thickness t3 of the IDT electrode 30.

The load film 50 is made of the same material as the first protective film 41. In the first example embodiment, the load film 50 and the first protective film 41 are made of silicon oxide (SiO₂), for example. When the load film 50 and the first protective film 41 are made of the same material, the density of the load film 50 may be different from that of the first protective film 41. For example, when the load film 50 is formed by vapor deposition, the real density of the load film 50 is lower than that of the first protective film 41.

Since the load film 50 overlaps the first electrode finger 31a as described above, in the region overlapping the first electrode finger 31a, which is positioned outermost in the arrangement direction of the plurality of electrode fingers 31 and 32, the acoustic impedance in the region in which the load film 50 and the first protective film 41 are laminated differs from that in the region in which only the first protective film 41 is laminated and the load film 50 is not provided. As a result, an acoustic reflection plane R is provided at the step (the portion overlapping one side surface of the load film 50) that is defined by the load film 50 and the first protective film 41.

Acoustic waves excited in the piezoelectric layer 20 are therefore reflected by the acoustic reflection plane R, and the acoustic wave device 10 can reduce leakage of acoustic waves in the arrangement direction of the plurality of electrode fingers 31 and 32.

FIG. 13 is an explanatory diagram illustrating an example of the admittance characteristics of the acoustic wave device according to the first example embodiment. To be more specific, FIG. 13 is an explanatory diagram illustrating the real portion of the admittance, that is, the conductance component, of the acoustic wave device according to the first example embodiment. The admittance characteristics illustrated in FIG. 13 represent simulation results of the admittance characteristics of the acoustic wave device 10 according to the first example embodiment. FIG. 13 also illustrates simulation results of the admittance characteristics of an acoustic wave device according to a comparative example. The comparative example is the same acoustic wave device as the first example embodiment, except that the load films 50 are not provided.

As illustrated in FIG. 13, in the acoustic wave device according to the comparative example, ripples are produced at frequencies different from the resonant frequency. In the comparative example, large ripples indicated by dotted lines E1 and E2 are produced. In the acoustic wave device 10 according to the first example embodiment, it is revealed that, due to the load films 50, the ripples indicated by the dotted lines E1 and E2 are reduced or prevented, compared with the comparative example. The acoustic wave device 10 according to the first example embodiment has a narrower peak width associated with the resonant frequency than that in the acoustic wave device according to the comparative example. Therefore, the propagation loss is reduced or prevented, and the leakage of acoustic waves is reduced or prevented.

The above-described shape, width, film thickness, and other parameters of the load films 50, the first protective film 41, and the IDT electrode 30 are merely examples and can be properly changed. For example, the side surfaces of the load films 50 may be tapered. The first and second extending portions 51 and 52 of the load films 50 illustrated in FIG. 1 may have the same or substantially the same width and the same or substantially the same film thickness. Alternatively, the first and second extending portions 51 and 52 of the load films 50 may have different widths and different film thicknesses, for example, due to process variations.

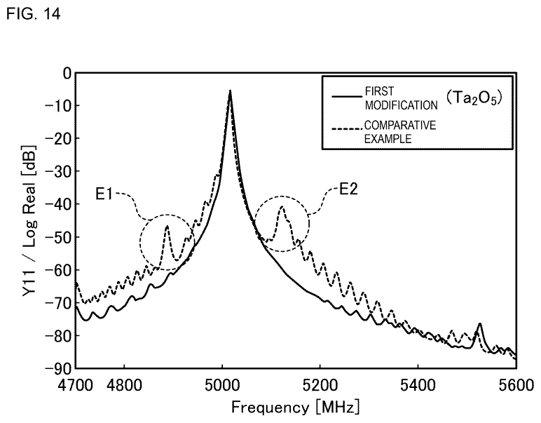

FIG. 14 is an explanatory diagram illustrating an example of the admittance characteristics of an acoustic wave device according to a first modification of the first example embodiment. The acoustic wave device according to the first modification differs from the acoustic wave device 10 according to the first example embodiment in that the load films 50 are made of, for example, tantalum oxide (Ta₂O₅). That is, in the first modification, the load films 50 are made of a material different from the first protective film 41. More specifically, the load films 50 of the first modification are made of a material with a higher density than silicon oxide used in the first protective film 41. The film thickness t4 of the load films 50 is, for example, about 25 nm. The widths W1, W1a, and W1b of the load films 50 and the configurations of the first protective film 41, the IDT electrode 30, and other members are the same or substantially the same as those of the first example embodiment. The term “density” in the example embodiments refers to a material-specific physical property value unless otherwise specified.

As illustrated in FIG. 14, in the acoustic wave device according to the first modification, the ripples indicated by dotted lines E1 and E2 are reduced or prevented compared with the comparative example, as in the acoustic wave device 10 according to the first example embodiment. Furthermore, the first modification also has a narrow peak width associated with the resonant frequency, thus reducing or preventing the propagation loss.

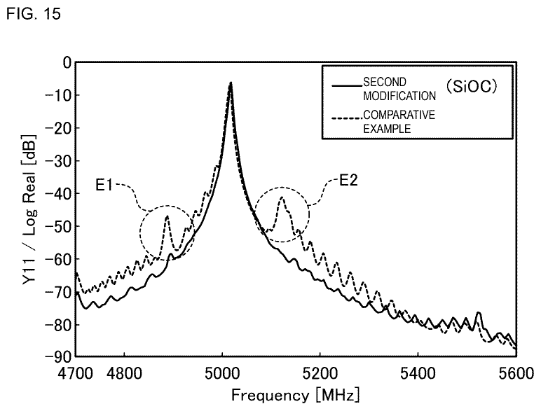

FIG. 15 is an explanatory diagram illustrating an example of the admittance characteristics of an acoustic wave device according to a second modification of the first example embodiment. The acoustic wave device according to the second modification differs from the acoustic wave device 10 according to the first example embodiment in that the load films 50 are made of carbon-added silicon oxide (SiOC), for example. That is, in the second modification, the load films 50 are made of a material different from the first protective film 41. More specifically, the load films 50 of the second modification are made of a material with a lower density than silicon oxide used in the first protective film 41. The film thickness t4 of the load films 50 is, for example, about 105 nm. The widths W1, W1a, and W1b of the load films 50 and the configurations of the first protective film 41, the IDT electrode 30, and other members are the same or substantially the same as those of the first example embodiment.

As illustrated in FIG. 15, in the acoustic wave device according to the second modification, the ripples indicated by dotted lines E1 and E2 are reduced or prevented compared with the comparative example, as in the acoustic wave device 10 according to the first example embodiment. Furthermore, the second modification also has a narrow peak width associated with the resonant frequency, thereby suppressing the propagation loss.

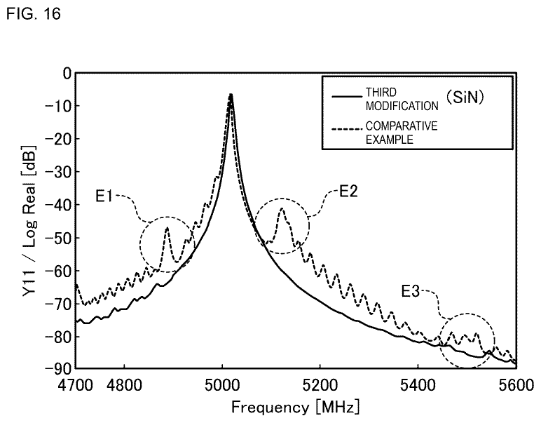

FIG. 16 is an explanatory diagram illustrating an example of the admittance characteristics of an acoustic wave device according to a third modification of the first example embodiment. The acoustic wave device according to the third modification differs from the acoustic wave device 10 according to the first example embodiment in that the load films 50 are made of silicon nitride (Si₃N₄), for example. That is, in the third modification, the load films 50 are made of a material different from the first protective film 41. More specifically, the load films 50 of the third modification are made of a material with a higher hardness than silicon oxide used in the first protective film 41. The film thickness t4 of the load films 50 is, for example, about 55 nm. The widths W1, W1a, and W1b of the load films 50 and the configurations of the first protective film 41, the IDT electrode 30, and other members are the same or substantially the same as those of the first example embodiment. The term “hardness” in the example embodiments refers to a material-specific physical property value unless otherwise specified.

As illustrated in FIG. 16, in the acoustic wave device according to the third modification, the ripples indicated by dotted lines E1 and E2 are reduced or prevented compared with the comparative example. Furthermore, in the acoustic wave device according to the third modification, the ripples indicated by a dotted line E3 are also reduced or prevented. In the acoustic wave device according to the third modification, ripples are reduced or prevented as in the acoustic wave device 10 according to the first example embodiment, and propagation loss is reduced or prevented.

The materials of the load films 50 illustrated in the first to third modifications are merely examples, and the present invention is not limited thereto. For example, the load films 50 include at least one of carbon-added silicon oxide, silicon oxide, silicon nitride, tantalum oxide, aluminum nitride, alumina, hafnium oxide, niobium oxide, or tungsten oxide.

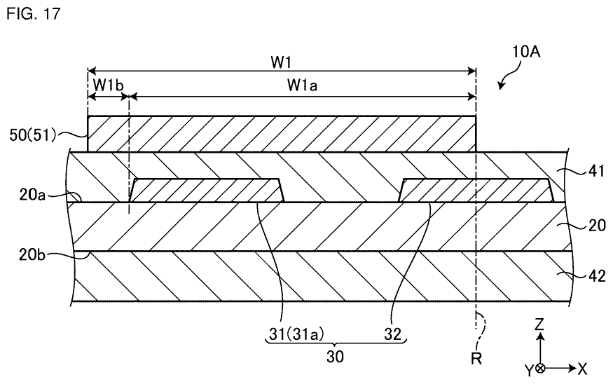

FIG. 17 is a cross-sectional view of an acoustic wave device according to a fourth modification of the first example embodiment. As illustrated in FIG. 17, in an acoustic wave device 10A according to the fourth modification, a load film 50 is provided in a region that overlaps the first electrode finger 31a, which is positioned outermost, and the electrode finger 32 adjacent to the first electrode finger 31a.

The load film 50 is continuously provided across two electrode fingers (the first electrode finger 31a and the electrode finger 32). One side surface of the load film 50 is disposed so as to overlap the widthwise midpoint of the electrode finger 32 while the other side surface of the load film 50 is positioned on the outer side of the first electrode finger 31a in the arrangement direction. The load film 50 is made of, for example, silicon oxide (SiO₂), as in the first example embodiment.

In the fourth modification, the film thickness t4 of the load film 50 is, for example, about 35 nm. The width W1 of the load film 50 is, for example, about 2.88 μm. The width W1a of the overlap region of the load film 50 is, for example, about 2.63 μm. The width W1b of the non-overlap region of the load film 50 is, for example, about 0.25 μm.

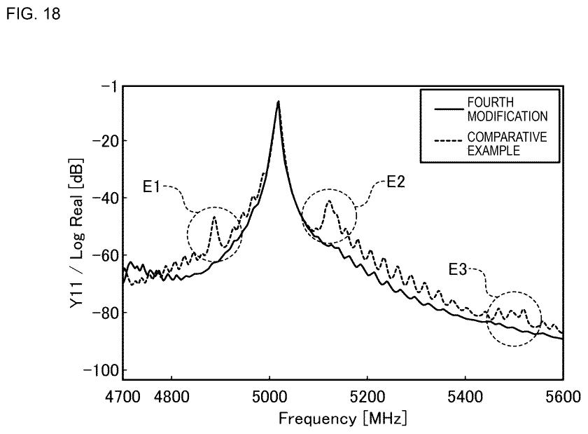

FIG. 18 is an explanatory diagram illustrating an example of the admittance characteristics of the acoustic wave device according to the fourth modification of the first example embodiment. As illustrated in FIG. 18, in the acoustic wave device 10A according to the fourth modification, the ripples indicated by dotted lines E1 and E2 are reduced or prevented compared with the comparative example, as in the acoustic wave device 10 according to the first example embodiment. Furthermore, in the acoustic wave device 10A according to the fourth modification, the ripples indicated by a dotted line E3 are also reduced or prevented. In the fourth modification, propagation loss is reduced or prevented on the high-frequency side ranging from the dotted line E2 to the dotted line E3.

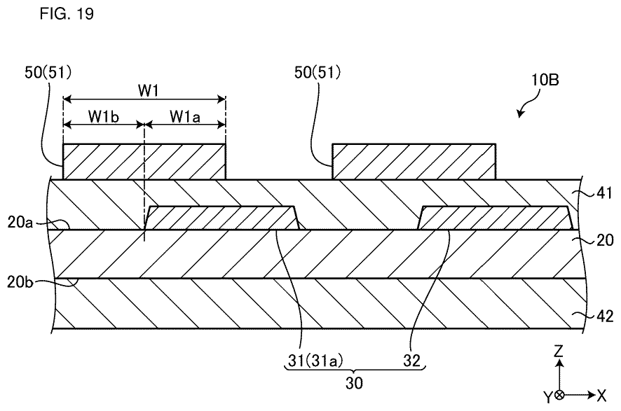

FIG. 19 is a cross-sectional view of an acoustic wave device according to a fifth modification of the first example embodiment. As illustrated in FIG. 19, in an acoustic wave device 10B according to the fifth modification, a plurality of load films 50 are each provided so as to correspond to the multiple electrode fingers, including an electrode finger 31 (the first electrode finger 31a) and an electrode finger 32, unlike the fourth modification. The plurality of load films 50 are respectively provided in a region overlapping the first electrode finger 31a, which is positioned outermost, and a region overlapping the electrode finger 32 adjacent to the first electrode finger 31a. The load film 50 overlapping the first electrode finger 31a and the load film 50 overlapping the electrode finger 32 are spaced apart from each other.

In the fifth modification, the material and shape of the plurality of load films 50 are the same or substantially the same as those of the first example embodiment. That is, for example, the load films 50 are made of silicon oxide (SiO₂), as in the first example embodiment. The film thickness t4 of the load films 50 is, for example, about 55 nm. The width W1 of the load films 50 is, for example, about 0.8 μm. The width W1a of the overlap region of the load films 50 is, for example, about 0.3 μm. The width W1b of the non-overlap region of the load films 50 is, for example, about 0.5 μm.

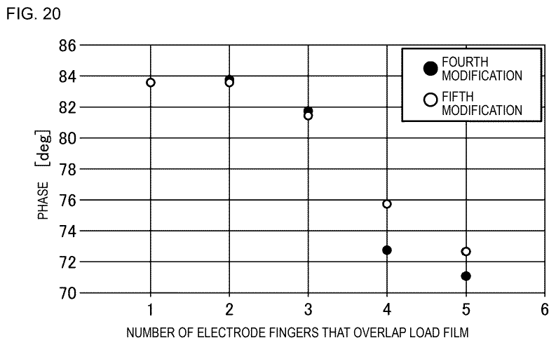

FIG. 20 is an explanatory diagram illustrating the relationship between the number of electrode fingers overlapping load films and phase in the acoustic wave devices according to the fourth and fifth modifications of the first example embodiment. The phase on the vertical axis in FIG. 20 represents the phase in the vicinity of the resonant frequency.

In the examples illustrated in the first example embodiment and modifications, one load film 50 is disposed overlapping one or two electrode fingers 31 and 32 positioned outermost in the arrangement direction of the plurality of electrode fingers 31 and 32, but the present invention is not limited thereto. As illustrated in FIG. 20, the phase is large (for example, about 81 deg or more) when the number of electrode fingers 31 and 32 overlapping the load films 50 is three or fewer and is small (for example, about 76 deg or less) when the number of electrode fingers 31 and 32 overlapping the load films 50 is four or more. This reveals that the load films 50 may overlap three electrode fingers 31 and 32 positioned outermost in the arrangement direction of the plurality of electrode fingers 31 and 32.

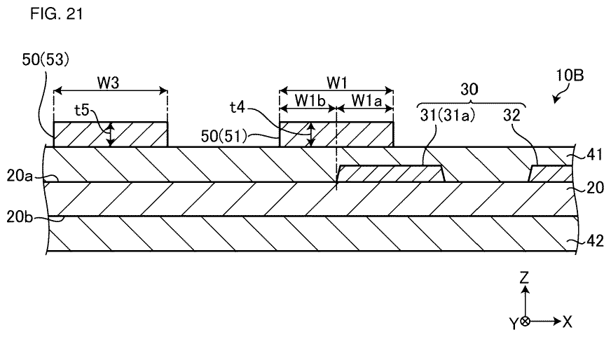

FIG. 21 is a cross-sectional view of an acoustic wave device according to a sixth modification of the first example embodiment. As illustrated in FIG. 21, in the acoustic wave device 10B according to the sixth modification of the first example embodiment, the load films 50 include the first extending portion 51 overlapping the first electrode finger 31a and an outer load film 53 provided in a region that does not overlap the IDT electrode 30 (the electrode fingers 31 and 32) on the outer side of the first extending portion 51 in the arrangement direction.

The outer load film 53 is provided on the first protective film 41 in the same layer as the first extending portion 51 and is spaced apart from the first extending portion 51. The outer load film 53 is made of, for example, silicon oxide (SiO₂), the same material as the first extending portion 51. A film thickness t5 of the outer load film 53 is, for example, about 55 nm, which is the same or substantially the same as the film thickness t4 of the first extending portion 51. A width W3 of the outer load film 53 is, for example, about 0.8 μm, which is the same or substantially the same as the width W1 of the first extending portion 51. However, the present invention is not limited thereto. The film thickness t5 and the width W3 of the outer load film 53 may be different from the film thickness t4 and the width W1 of the first extending portion 51, respectively.

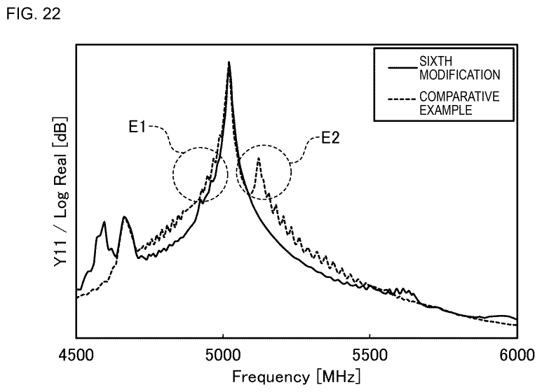

FIG. 22 is an explanatory diagram illustrating an example of the admittance characteristics of the acoustic wave device according to the sixth modification of the first example embodiment. As illustrated in FIG. 22, in the acoustic wave device 10B according to the sixth modification, at least the ripples indicated by a dotted line E2 are reduced or prevented compared with the comparative example. Furthermore, in the acoustic wave device 10B according to the sixth modification, propagation loss is reduced or prevented on the low-frequency side relative to a dotted line E1.

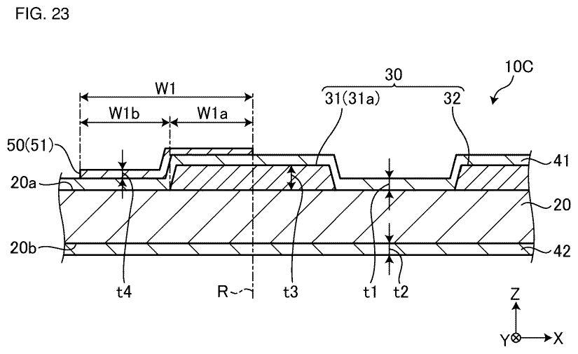

FIG. 23 is a cross-sectional view of an acoustic wave device according to a seventh modification of the first example embodiment. As illustrated in FIG. 23, in an acoustic wave device 10C according to the seventh modification, the film thickness t1 of the first protective film 41 and the film thickness t2 of the second protective film 42 are smaller than the film thickness of the piezoelectric layer 20. Specifically, the film thickness of the piezoelectric layer 20 is, for example, about 360 nm. The film thickness t1 of the first protective film 41 is, for example, about 30 nm. The film thickness t2 of the second protective film 42 is, for example, about 30 nm. The lamination structure of the IDT electrode 30 is the same as that in the first example embodiment described above, and the film thickness t3 of the IDT electrode 30 is, for example, about 112 nm.

The material of the load film 50 is, for example, silicon oxide as in the first example embodiment, and the film thickness t4 of the load film 50 is, for example, about 70 nm. The film thickness t1 of the first protective film 41 is smaller than the film thickness t4 of the load film 50 and the film thickness t3 of the IDT electrode 30. The width W1 of the load film 50 is, for example, about 0.98 μm. The width W1a of the overlap region of the load film 50 is, for example, about 0.3 μm. The width W1b of the non-overlap region of the load film 50 is, for example, about 0.68 μm.

In the seventh modification, the first protective film 41 is provided conforming to the surfaces and side surfaces of the electrode fingers 31 and 32 and the first major surface 20a of the piezoelectric layer 20. Since the film thickness t1 of the first protective film 41 is small, the upper surface of the first protective film 41 includes protrusions and depressions that reflect the shapes of the electrode fingers 31 and 32.

The load film 50 is provided overlapping the first electrode finger 31a, as in the first example embodiment. The load film 50 covers the upper and side surfaces of the first electrode finger 31a and is provided on the first protective film 41 on the outer side of the first electrode finger 31a in the arrangement direction. In the seventh modification, the acoustic reflection plane R is also provided at the step (the portion overlapping the side surface of the load film 50) that is defined by the load film 50 and the first protective film 41 within the region overlapping the first electrode finger 31a.

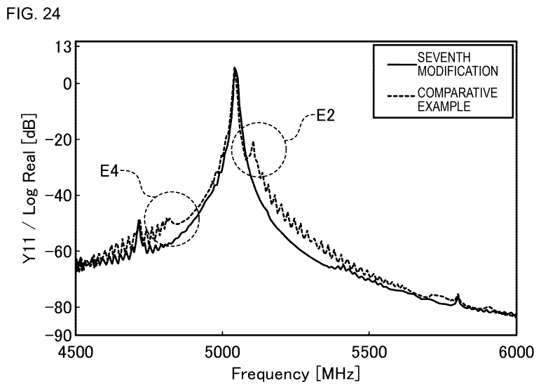

FIG. 24 is an explanatory diagram illustrating an example of the admittance characteristics of the acoustic wave device according to the seventh modification of the first example embodiment. The comparative example illustrated in FIG. 24 has the same or substantially the same structure as the acoustic wave device 10C according to the seventh modification, that is, the acoustic wave device 10C having a structure in which the film thicknesses of the first and second protective films 41 and 42 are smaller than the film thickness of the piezoelectric layer 20, except that the load films 50 are not provided. In the acoustic wave device according to the comparative example, ripples are produced at frequencies different from the resonant frequency. In the comparative example, the large ripples indicated by dotted lines E2 and E4 are produced in particular.

In the acoustic wave device 10C according to the seventh modification, due to the load film 50, the ripples indicated by the dotted lines E2 and E4 are reduced or prevented compared with the comparative example. The acoustic wave device 10C according to the seventh modification has a narrower peak width associated with the resonant frequency than that in the acoustic wave device according to the comparative example. Therefore, propagation loss is reduced or prevented, and leakage of acoustic waves is reduced or prevented. Thus, even when the first and second protective films 41 and 42 are thin, the provision of the load film 50 reduces or prevents ripples and propagation loss.

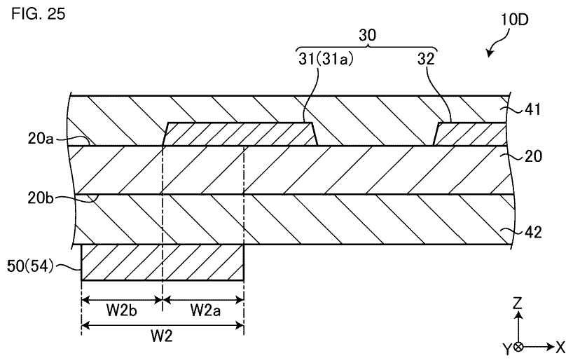

FIG. 25 is a cross-sectional view of an acoustic wave device according to a second example embodiment of the present invention. In the configurations illustrated in the first example embodiment and the first to seventh modifications, the load film 50 is provided on the first protective film 41 on the first major surface 20a side of the piezoelectric layer 20. However, the present invention is not limited thereto. As illustrated in FIG. 25, in an acoustic wave device 10D according to the second example embodiment, a load film 50 (a lower first extending portion 54) is provided on the lower surface of the second protective film 42 on the second major surface 20b side of the piezoelectric layer 20. In other words, no load film 50 is provided on the first major surface 20a side of the piezoelectric layer 20, and the upper surface of the first protective film 41 is flat. The lower surface of the second protective film 42 corresponds to the surface of the second protective film 42 that faces the support substrate 11 (see FIG. 2).

The lower surface of the second protective film 42 is flat along the second major surface 20b of the piezoelectric layer 20. The load film 50 is provided on the lower surface of the second protective film 42 and overlaps a portion of the first electrode finger 31a. The load film 50 protrudes from the lower surface of the second protective film 42. In the second example embodiment, the region overlapping the first electrode finger 31a includes a region in which the second protective film 42 is provided on the second major surface 20b of the piezoelectric layer 20 and the load film 50 is not provided and a region in which the second protective film 42 and the load film 50 are laminated. The load film 50 and the second protective film 42 thus define a step within the region overlapping the first electrode finger 31a.

In the second example embodiment, the load film 50 is made of the same material as that of the first and second protective films 41 and 42, for example, silicon oxide (SiO₂). A width W2 of the load film 50 is, for example, about 0.6 μm. A width W2a of the overlap region of the load film 50 is, for example, about 0.3 μm. A width W2b of the non-overlap region of the load film 50 is, for example, about 0.3 μm. The film thickness t4 of the load film 50 is, for example, about 55 nm.

In plan view, the configuration of the lower first extending portion 54 is the same or substantially the same as that of the first extending portion 51 (see FIG. 1), and the repetitive explanation is omitted. A lower second extending portion (not illustrated) is provided at the position overlapping the second electrode finger 32a (see FIG. 1) on the opposite side to the lower first extending portion 54 in the arrangement direction of the plurality of electrode fingers 31 and 32.

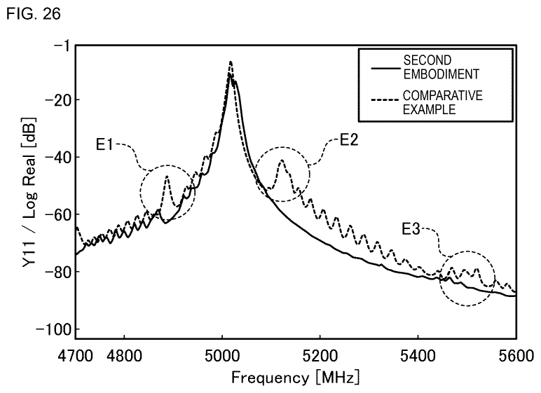

FIG. 26 is an explanatory diagram illustrating an example of the admittance characteristics of the acoustic wave device according to the second example embodiment. As illustrated in FIG. 26, in the acoustic wave device 10D according to the second example embodiment, in which the load film 50 is provided on the second major surface 20b side of the piezoelectric layer 20, the ripples indicated by dotted lines E1, E2, and E3 are reduced or prevented compared with the comparative example, as in the acoustic wave device 10 according to the first example embodiment. Furthermore, the second example embodiment also has a narrow peak width associated with the resonant frequency, thus reducing or preventing propagation loss. In the second example embodiment, since no load film 50 is provided on the first protective film 41, compared with the first example embodiment, the resonant frequency can be easily adjusted by changing the film thickness of the first protective film 41.

The second example embodiment can be properly combined with the first to seventh modifications. Specifically, the load film 50 may be provided on the lower surface of the second protective film 42 while it includes various materials different from the second protective film 42. Alternatively, the load film 50 may be provided on the lower surface of the second protective film 42 while it is provided in a region that overlaps two electrode fingers (the first electrode finger 31a and the electrode finger 32) or three electrode fingers positioned on the outer side in the arrangement direction. Alternatively, the load film 50 may be provided on the lower surface of the second protective film 42 while the film thicknesses of the first and second protective films 41 and 42 are smaller than the thickness of the piezoelectric layer 20.

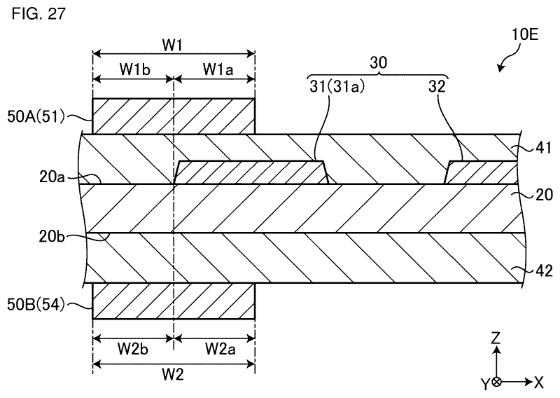

FIG. 27 is a cross-sectional view of an acoustic wave device according to a third example embodiment of the present invention. As illustrated in FIG. 27, in an acoustic wave device 10E according to the third example embodiment, load films 50 are provided on the first protective film 41 and the lower surface (the surface facing the support substrate 11 (see FIG. 2)) of the second protective film 42, respectively. In the following description, the load film 50 provided on the first protective film 41 is referred to as an upper load film 50A, and the load film 50 provided on the lower surface of the second protective film 42 is referred to as a lower load film 50B. When there is no need to distinguish between the upper load film 50A and the lower load film 50B, they are simply referred to as the load films 50.

In the third example embodiment, the upper load film 50A and the lower load film 50B are made of the same material, for example, silicon oxide (SiO₂). The first extending portion 51 of the upper load film 50A and the lower first extending portion 54 of the lower load film 50B overlap each other and each overlap a portion of the first electrode finger 31a.

The width W1 of the upper load film 50A (the first extending portion 51) and the width W2 of the lower load film 50B (the lower first extending portion 54) are, for example, about 0.6 μm, respectively. The width W1a of the overlap region of the upper load film 50A and the width W2a of the overlap region of the lower load film 50B are, for example, about 0.3 μm, respectively. The width W1b of the non-overlap region of the upper load film 50A and the width W2b of the non-overlap region of the lower load film 50B are, for example, about 0.3 μm, respectively. The film thickness t4 of the upper load film 50A and the film thickness of the lower load film 50B are, for example, about 55 nm.

In the example illustrated above, the upper and lower load films 50A and 50B include the same material and have the same or substantially the same shape. However, the present invention is not limited thereto. As described later in eighth to 10th modifications, the upper and lower load films 50A and 50B may include different materials and have different shapes.

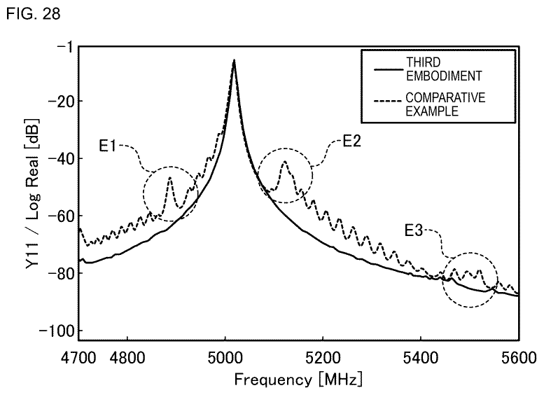

FIG. 28 is an explanatory diagram illustrating an example of the admittance characteristics of the acoustic wave device according to the third example embodiment. As illustrated in FIG. 28, it is revealed that in the acoustic wave device 10E according to the third example embodiment, by providing the load films 50 on both of the first and second major surface 20a and 20b sides of the piezoelectric layer 20, the ripples indicated by dotted lines E1, E2, and E3 are favorably reduced or prevented, compared with the comparative example. Furthermore, the third example embodiment also has a narrow peak width associated with the resonant frequency, thus reducing or preventing propagation loss.

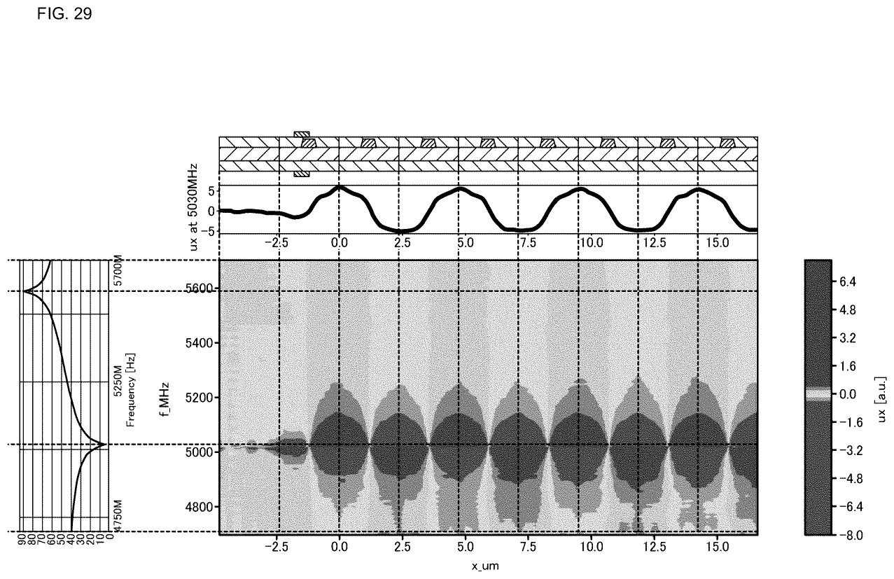

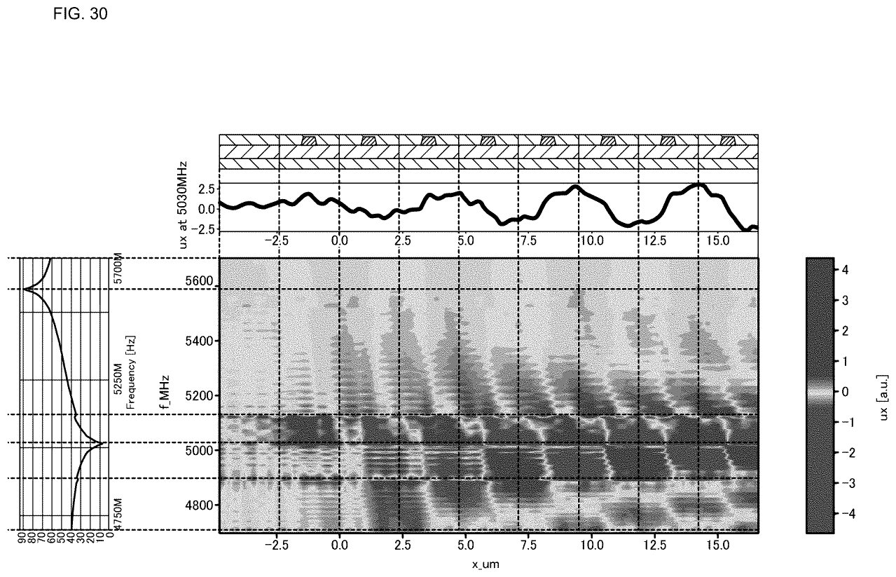

FIG. 29 is an explanatory diagram illustrating the vibration mode distribution of the acoustic wave device according to the third example embodiment. FIG. 30 is an explanatory diagram illustrating the vibration mode distribution of the acoustic wave device according to the comparative example. The comparative example illustrated in FIG. 30 is the same or substantially the same as the acoustic wave device 10E of the third example embodiment, except that the load films 50 (the upper load film 50A and no lower load film 50B) are not provided.

FIGS. 29 and 30 illustrate the distribution of displacement magnitude of the piezoelectric layer 20 in the third example embodiment and the comparative example. Here, the horizontal axis represents the X direction (the arrangement direction of the electrode fingers 31 and 32), and the vertical axis represents frequency. The top diagrams in FIGS. 29 and 30 schematically illustrate cross-sections of the respective acoustic wave devices along the X direction. The left diagrams in FIGS. 29 and 30 illustrate the impedance characteristics of the respective acoustic wave devices.

As illustrated in FIG. 30, in the acoustic wave device according to the comparative example, the X-direction dependence (X-direction positions of displacement antinodes and nodes) of displacement exhibits significant frequency dependence. For example, the X-direction position indicating the displacement peak varies with the frequency, resulting in unstable excitation between electrodes. Furthermore, focusing on a predetermined X position (near X=5.0 μm), the phase is inverted at the resonant frequency of about 5030 MHz and frequencies of about 4900 MHz and about 5120 MHz, at which ripples occur. As described above, the acoustic wave device according to the comparative example may fail to achieve a preferable excitation mode.

In contrast, as illustrated in FIG. 29, in the acoustic wave device 10E according to the third example embodiment, the X-direction dependence (X-direction positions of displacement antinodes and nodes) of displacement does not exhibit frequency dependence. That is, it is revealed that the X-direction position indicating the peak of displacement is constant independently of the frequency, resulting in stable excitation between electrodes. The magnitude (amplitude) of displacement is also constant for each region between electrodes, and no phase inversion occurs at the resonant frequency or frequencies at which ripples occur. Thus, only by providing the load films 50 at the position overlapping the first electrode finger 31a, which is positioned outermost in the arrangement direction, the third example embodiment can provide a favorable excitation mode, compared with the comparative example.

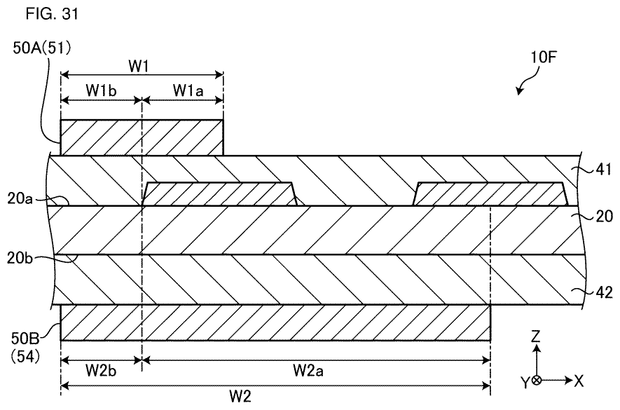

FIG. 31 is a cross-sectional view of an acoustic wave device according to an eighth modification of the third example embodiment. As illustrated in FIG. 31, in an acoustic wave device 10F according to the eighth modification, the width W1 of the upper load film 50A differs from the width W2 of the lower load film 50B. The width W2 of the lower load film 50B is greater than the width W1 of the upper load film 50A. In the eighth modification, the upper and lower load films 50A and 50B are made of, for example, silicon oxide (SiO₂).

The width W1 of the upper load film 50A is, for example, about 0.6 μm. The width W1a of the overlap region of the upper load film 50A is, for example, about 0.3 μm. The width W1b of the non-overlap region of the upper load film 50A is, for example, about 0.3 μm. The film thickness t4 of the upper load film 50A is, for example, about 55 nm.

The lower load film 50B is provided in a region that overlaps two electrode fingers positioned outermost in the arrangement direction, that is, the first electrode finger 31a and the electrode finger 32 adjacent to the first electrode finger 31a.

The lower load film 50B is continuously provided across two electrode fingers (the first electrode finger 31a and the electrode finger 32). One side surface of the lower load film 50B is disposed overlapping the widthwise midpoint of the electrode finger 32, and the other side surface of the lower load film 50B is positioned on the outer side of the first electrode finger 31a in the arrangement direction. The other side surface of the lower load film 50B is provided at the position overlapping one side surface of the upper load film 50A.

In the eighth modification, the width W2 of the lower load film 50B is, for example, about 2.98 μm. The width W2a of the overlap region of the lower load film 50B is, for example, about 2.68 μm. The width W2b of the non-overlap region of the lower load film 50B is, for example, about 0.3 μm. The film thickness of the lower load film 50B is, for example, about 40 nm. That is, the film thickness of the lower load film 50B differs from that of the upper load film 50A.

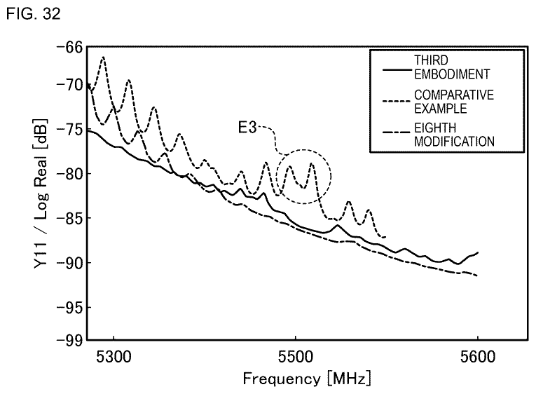

FIG. 32 is an explanatory diagram illustrating an example of the admittance characteristics of the acoustic wave device according to the eighth modification of the third example embodiment. FIG. 32 illustrates an enlarged view of the admittance characteristics around a frequency of about 5500 MHz. FIG. 32 also illustrates the admittance characteristics of the acoustic wave device 10E according to the third example embodiment and an acoustic wave device according to a comparative example.

As illustrated in FIG. 32, in the acoustic wave device 10F according to the eighth modification, it is revealed that, by making the widths W1 and W2 of the upper and lower load films 50A and 50B different from each other, the ripples indicated by a dotted line E3 are reduced or prevented, compared with the comparative example. Furthermore, in the acoustic wave device 10F according to the eighth modification, the propagation loss around the anti-resonant frequency indicated by the dotted line E3 is reduced or prevented, compared with the acoustic wave device 10E according to the third example embodiment.

In the illustrated structure of the acoustic wave device 10F according to the eighth modification, the width W2 of the lower load film 50B is greater than the width W1 of the upper load film 50A. However, the present invention is not limited thereto. The width W1 of the upper load film 50A may be greater than the width W2 of the lower load film 50B.

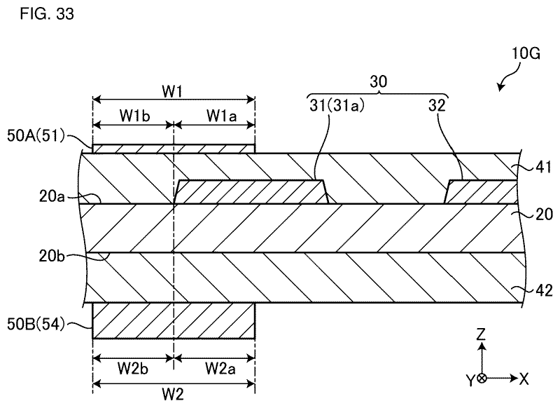

FIG. 33 is a cross-sectional view of an acoustic wave device according to a ninth modification of the third example embodiment. As illustrated in FIG. 33, in an acoustic wave device 10G according to the ninth modification, the film thickness of the upper load film 50A is different from that of the lower load film 50B. In the ninth modification, the upper and lower load films 50A and 50B are made of silicon oxide (SiO₂), for example.

In the ninth modification, the film thickness of the upper load film 50A is smaller than that of the lower load film 50B. The film thickness of the upper load film 50A is, for example, about 10 nm, and the film thickness of the lower load film 50B is, for example, about 80 nm. The width W1 of the upper load film 50A and the width W2 of the lower load film 50B are, for example, about 0.6 μm. The width W1a of the overlap region of the upper load film 50A and the width W2a of the overlap region of the lower load film 50B are, for example, about 0.3 μm. The width W1b of the non-overlap region of the upper load film 50A and the width W2b of the non-overlap region of the lower load film 50B are, for example, about 0.3 μm.

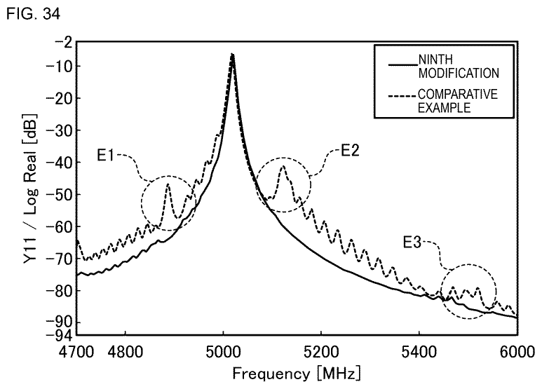

FIG. 34 is an explanatory diagram illustrating an example of the admittance characteristics of the acoustic wave device according to the ninth modification of the third example embodiment. As illustrated in FIG. 34, in the acoustic wave device 10G according to the ninth modification, even when the film thickness of the upper load film 50A differs from that of the lower load film 50B, the ripples indicated by dotted lines E1, E2, and E3 are reduced or prevented, and propagation loss is reduced or prevented.

In the ninth modification, the film thickness of the upper load film 50A is smaller than the film thickness of the lower load film 50B. As a result, even when the film thickness of the first protective film 41 is changed to adjust the resonant frequency, changes in the admittance characteristics can be reduced or prevented.

In the illustrated structure of the acoustic wave device 10G according to the ninth modification, the film thickness of the upper load film 50A is smaller than that of the lower load film 50B. However, the present invention is not limited thereto. The film thickness of the lower load film 50B may be smaller than that of the upper load film 50A.

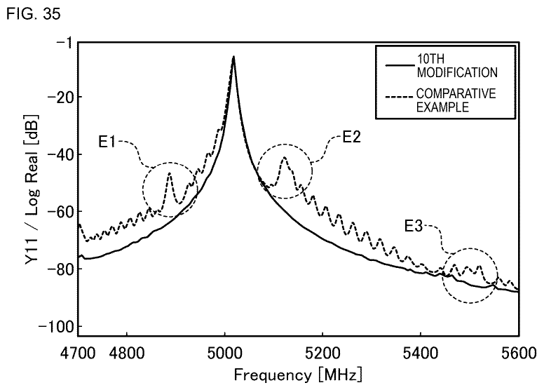

FIG. 35 is an explanatory diagram illustrating an example of the admittance characteristics of an acoustic wave device according to a 10th modification of the third example embodiment. The acoustic wave device according to the 10th modification differs from the acoustic wave device 10E (see FIG. 27) of the third example embodiment in that the material of the upper load film 50A is different from that of the lower load film 50B. Specifically, for example, the material of the upper load film 50A is silicon oxide (SiO₂), and the material of the lower load film 50B is carbon-added silicon oxide (SiOC).

The other configuration of the acoustic wave device according to the 10th modification is the same or substantially the same as that of the acoustic wave device 10E (see FIG. 27) according to the third example embodiment, the shape (width, film thickness), layout, and other parameters of the upper and lower load films 50A and 50B are the same or substantially the same as those in the third example embodiment described above.

As illustrated in FIG. 35, in the acoustic wave device according to the 10th modification, even when the material of the upper load film 50A differs from that of the lower load film 50B, the ripples indicated by dotted lines E1, E2, and E3 are reduced or prevented, and propagation loss is reduced or prevented.

The combination of the materials of the upper and lower load films 50A and 50B is merely an example and can be properly changed. The material of each of the upper and lower load films 50A and 50B includes, for example, at least one of carbon-added silicon oxide, silicon oxide, silicon nitride, tantalum oxide, aluminum nitride, alumina, hafnium oxide, niobium oxide, or tungsten oxide.

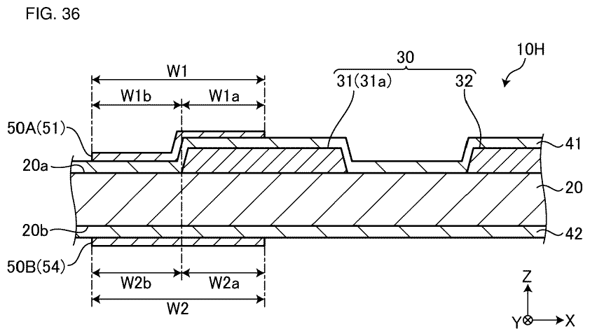

FIG. 36 is a cross-sectional view of an acoustic wave device according to an 11th modification of the third example embodiment. As illustrated in FIG. 36, in an acoustic wave device 10H according to the 11th modification, the film thicknesses of the first and second protective films 41 and 42 are smaller than that of the piezoelectric layer 20. Specifically, the film thickness of the piezoelectric layer 20 is, for example, about 360 nm. The film thickness of the first protective film 41 is, for example, about 30 nm. The film thickness of the second protective film 42 is, for example, about 30 nm.

The width W1 of the upper load film 50A is, for example, about 0.98 μm. The width W1a of the overlap region of the upper load film 50A is, for example, about 0.3 μm. The width W1b of the non-overlap region of the upper load film 50A is, for example, about 0.68 μm. The width W2 of the lower load film 50B is, for example, about 0.98 μm. The width W2a of the overlap region of the lower load film 50B is, for example, about 0.3 μm. The width W2b of the non-overlap region of the lower load film 50B is, for example, about 0.68 μm.

The materials of the upper and lower load films 50A and 50B are, for example, silicon oxide (SiO₂). The film thicknesses of the upper and lower load films 50A and 50B are, for example, about 70 nm, respectively. The film thickness of the first protective film 41 is smaller than the film thicknesses of the load films 50 and the film thickness of the IDT electrode 30.

In the 11th modification, the first protective film 41 is conforms to the surfaces and side surfaces of the electrode fingers 31 and 32 and the first major surface 20a of the piezoelectric layer 20. The upper surface of the first protective film 41 includes protrusions and depressions that reflect the shapes of the electrode fingers 31 and 32. The second protective film 42 is flat along the second major surface 20b of the piezoelectric layer 20.

The upper load film 50A covers the upper and side surfaces of the first electrode finger 31a and is provided on the first protective film 41 on the outer side of the first electrode finger 31a in the arrangement direction. The lower load film 50B is flat along the second major surface 20b of the piezoelectric layer 20.

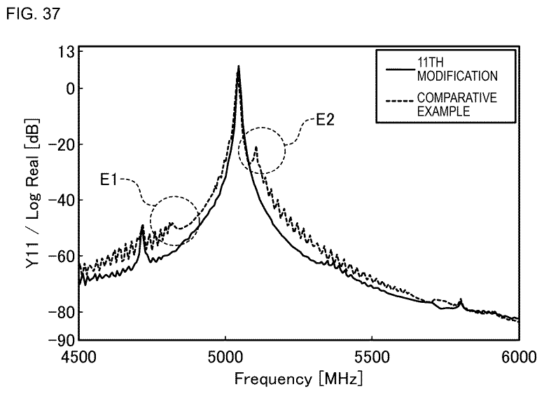

FIG. 37 is an explanatory diagram illustrating an example of the admittance characteristics of the acoustic wave device according to the 11th modification of the third example embodiment. As illustrated in FIG. 37, in the acoustic wave device 10H according to the 11th modification, it is revealed that the ripples indicated by dotted lines E1 and E2 are reduced or prevented, compared with the comparative example. Thus, even when the load films 50 are provided on both the first major surface 20a side and the second major surface 20b side of the piezoelectric layer 20 and the first and second protective films 41 and 42 are thin, ripples and propagation loss are reduced or prevented.

In the illustrated structure of the acoustic wave device 10H according to the 11th modification, the film thicknesses of the first and second protective films 41 and 42 are smaller than the film thickness of the piezoelectric layer 20. However, the present invention is not limited thereto. The film thickness of either the first protective film 41 or the second protective film 42 may be smaller than that of the piezoelectric layer 20.

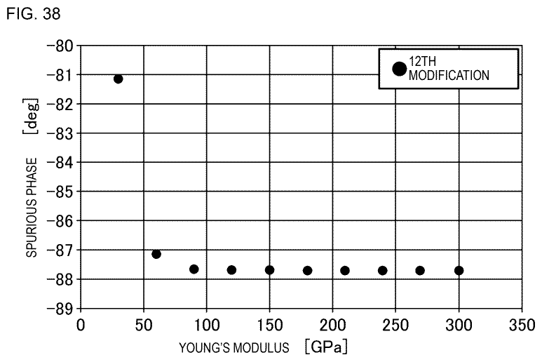

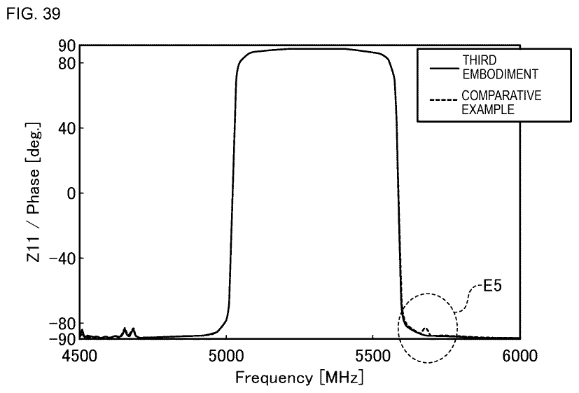

FIG. 38 is an explanatory diagram illustrating the relationship between spurious phase and the Young's modulus of the load films in an acoustic wave device according to a 12th modification of the third example embodiment. FIG. 39 is an explanatory diagram illustrating an example of the impedance characteristics of the acoustic wave device according to the third example embodiment. FIG. 39 illustrates the impedance characteristics of the acoustic wave device 10E (see FIG. 27) according to the third example embodiment and the acoustic wave device according to the comparative example. FIG. 38 illustrates the relationship between the ripple phase in the spurious region indicated by a dotted line E5 in FIG. 39 and the Young's modulus of the load films in the acoustic wave device according to the 12th modification.

The acoustic wave device according to the 12th modification of the third example embodiment differs from the acoustic wave device 10E (see FIG. 27) according to the third example embodiment in the Young's moduli of the materials of the upper and lower load films 50A and 50B. The conditions, such as width and film thickness, of the upper and lower load films 50A and 50B are the same or substantially the same as those in the third example embodiment.

As illustrated in FIG. 38, when the Young's moduli of the upper and lower load films 50A and 50B are in the range of, for example, about 50 GPa to about 300 GPa, inclusive, the spurious phase is small, and ripples are reduced or prevented.

In the illustrated structure of the 12th modification, the Young's moduli of both the upper and lower load films 50A and 50B differ from those of the third example embodiment. However, the present invention is not limited thereto. The spurious phase can be reduced or prevented when the Young's modulus of at least one of the upper load film 50A and the lower load film 50B is in the range of, for example, about 50 GPa to about 300 GPa, inclusive.

The structures illustrated in the third example embodiment and the eighth to 12th modifications can be properly combined. Furthermore, the third example embodiment and the eighth to 12th modifications can be properly combined with the first to seventh modifications. For example, in the third example embodiment and the eighth to 12th modifications, the upper and lower load films 50A and 50B may be provided in a region that overlaps two electrode fingers (the first electrode finger 31a and the electrode finger 32) or three electrode fingers positioned outermost in the arrangement direction.

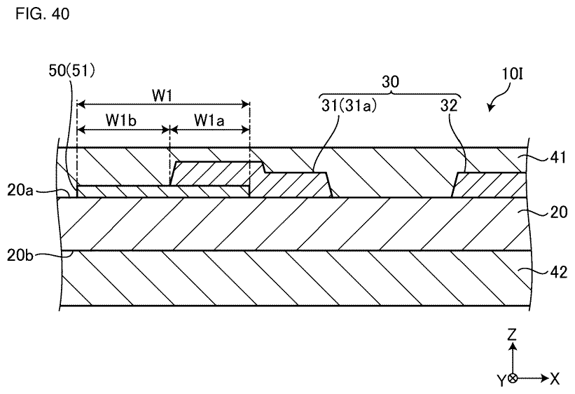

FIG. 40 is a cross-sectional view of an acoustic wave device according to a fourth example embodiment of the present invention. In the structures illustrated in the first to third example embodiments, the load films 50 are provided on at least one of the first protective film 41 and the lower surface of the second protective film 42. However, the present invention is not limited thereto.

As illustrated in FIG. 40, in an acoustic wave device 10I according to the fourth example embodiment, a load film 50 is provided on the first major surface 20a of the piezoelectric film 20. The first electrode finger 31a is provided on the first major surface 20a of the piezoelectric layer 20, covering a portion of the load film 50. That is, the load film 50 is provided between the first major surface 20a of the piezoelectric layer 20 and the first electrode finger 31a in a direction vertical to the first major surface 20a of the piezoelectric layer 20.

The first protective film 41 is provided on the first major surface 20a of the piezoelectric layer 20, covering the load film 50 and the IDT electrode 30. That is, in the fourth example embodiment, the acoustic wave device 10I includes a region in which the first electrode finger 31a and the first protective film 41 are laminated in this order on the first major surface 20a of the piezoelectric layer 20, a region in which the load film 50, the first electrode finger 31a, and the first protective film 41 are laminated in this order, and a region in which the load film 50 and the first protective film 41 are laminated in this order. The upper surface of the first protective film 41 is flat across the region that overlaps the load film 50 and the IDT electrode 30 and the region in which the load film 50 and the IDT electrode 30 are not provided.

The load film 50 is made of, for example, silicon oxide (SiO₂). The width W1 of the load film 50 is, for example, about 0.6 μm. The width W1a of the overlap region of the load film 50 is, for example, about 0.3 μm. The width W1b of the non-overlap region of the load film 50 is, for example, about 0.3 μm. The film thickness of the load film 50 is, for example, about 45 nm. As in the first example embodiment described above, the film thicknesses of the first and second protective films 41 and 42 are, for example, about 142 nm, and the film thickness of the IDT electrode 30 is, for example, about 112 nm.

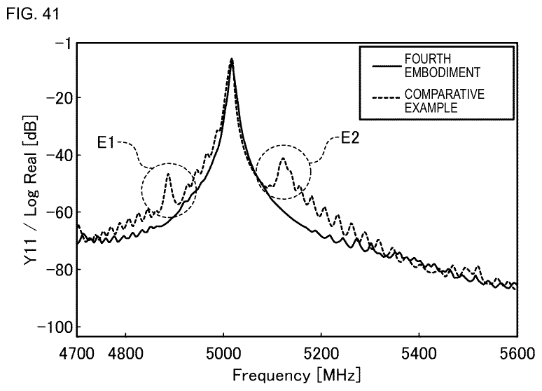

FIG. 41 is an explanatory diagram illustrating an example of the admittance characteristics of the acoustic wave device according to the fourth example embodiment. As illustrated in FIG. 41, it is revealed that in the acoustic wave device 10I according to the fourth example embodiment, the ripples indicated by dotted lines E1 and E2 are reduced or prevented, compared with the comparative example. Thus, even when the load film 50 is provided on the first major surface 20a of the piezoelectric layer 20, ripples and propagation loss are reduced or prevented. In the fourth example embodiment, furthermore, since the upper surface of the first protective film 41 is flat, the resonant frequency can be easily adjusted by changing the film thickness of the first protective film 41.

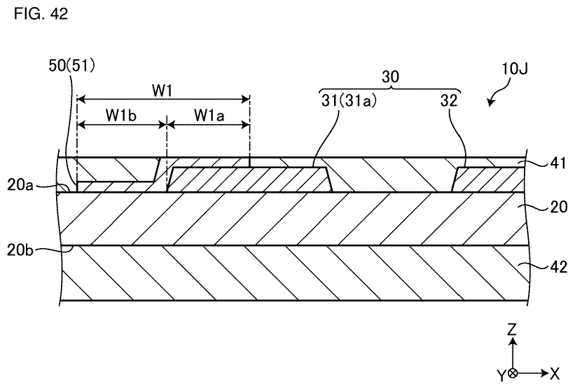

FIG. 42 is a cross-sectional view of an acoustic wave device according to a fifth example embodiment of the present invention. As illustrated in FIG. 42, in an acoustic wave device 10J according to the fifth example embodiment, the load film 50 is provided on the first electrode finger 31a, which is positioned outermost. To be more specific, the load film 50 is provided on the upper and side surfaces of the first electrode finger 31a and on a portion of the first major surface 20a of the piezoelectric layer 20 in which no electrode fingers 31 and 32 are provided. The load film 50 is provided conforming to a step formed by the piezoelectric layer 20 and the first electrode finger 31a.

The load film 50 is made of, for example, tantalum oxide (Ta₂O₅). The width W1 of the load film 50 is, for example, about 0.89 μm. The width W1a of the overlap region of the load film 50 is, for example, about 0.3 μm. The width W1b of the non-overlap region of the load film 50 is, for example, about 0.59 μm. The film thickness of the load film 50 is, for example, about 35 nm. As in the first example embodiment described above, the film thicknesses of the first and second protective films 41 and 42 are, for example, about 142 nm, and the film thickness of the IDT electrode 30 is, for example, about 112 nm.

The first protective film 41 is provided on the first major surface 20a of the piezoelectric layer 20, covering the load film 50 and the IDT electrode 30. In the fifth example embodiment, the upper surface of the load film 50 is provided in the same plane as the upper surface of the first protective film 41. The region that overlaps the first electrode finger 31a includes a portion where the load film 50 is provided but the first protective film 41 is not provided, and a portion where the first protective film 41 is provided but the load film 50 is not provided. In the region that overlaps the first electrode finger 31a, the film thickness of the load film 50 is the same or substantially the same as that of the first protective film 41.

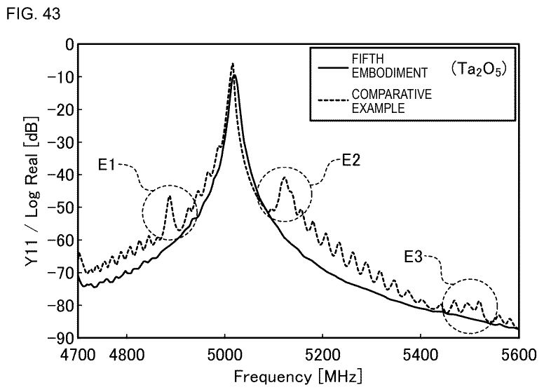

FIG. 43 is an explanatory diagram illustrating an example of the admittance characteristics of the acoustic wave device according to the fifth example embodiment. As illustrated in FIG. 43, it is revealed that in the acoustic wave device 10J according to the fifth example embodiment, the ripples indicated by dotted lines E1, E2, and E3 are reduced or prevented, compared with the comparative example. Thus, even when the load film 50 is provided on the first electrode finger 31a and the upper surface of the load film 50 is provided in the same plane as the upper surface of the first protective film 41, ripples and propagation loss are reduced or prevented.

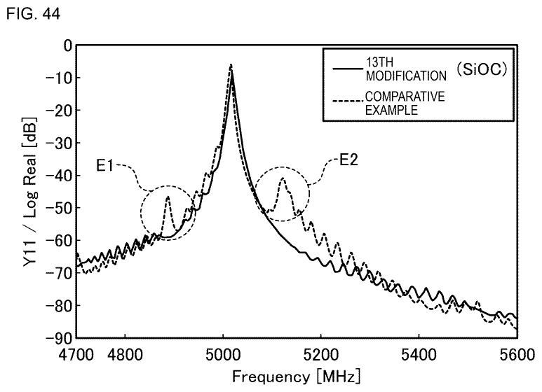

FIG. 44 is an explanatory diagram illustrating an example of the admittance characteristics of an acoustic wave device according to a 13th modification of the fifth example embodiment. The acoustic wave device according to the 13th modification differs from the acoustic wave device 10J according to the fifth example embodiment in that the load film 50 includes, for example, carbon-added silicon oxide (SiOC). The film thickness of the load film 50 is, for example, about 45 nm. The width of the load film 50 and the configurations of the first protective film 41, the IDT electrode 30, and other members are the same or substantially the same as those in the fifth example embodiment.

As illustrated in FIG. 44, it is revealed that in the acoustic wave device according to the 13th modification, at least the ripples indicated by dotted lines E1 and E2 are reduced or prevented, compared with the comparative example. In the acoustic wave device according to the 13th modification, as in the acoustic wave device 10J according to the fifth example embodiment, ripples and propagation loss are reduced or prevented.

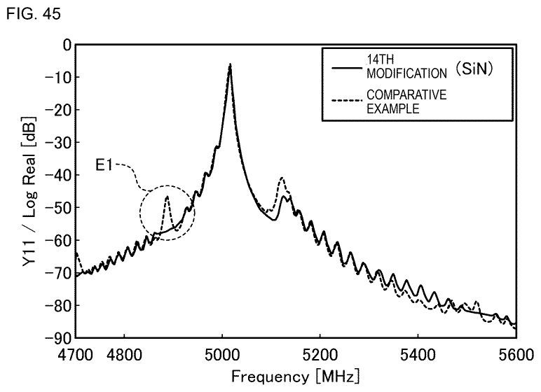

FIG. 45 is an explanatory diagram illustrating an example of the admittance characteristics of an acoustic wave device according to a 14th modification of the fifth example embodiment. The acoustic wave device according to the 14th modification differs from the acoustic wave device 10J according to the fifth example embodiment in that the load film 50 includes, for example, silicon nitride (Si₃N₄). The film thickness of the load film 50 is, for example, about 75 nm. The width of the load film 50 and the configurations of the first protective film 41, the IDT electrode 30, and other members are the same or substantially the same as those in the fifth example embodiment.

As illustrated in FIG. 45, it is revealed that in the acoustic wave device according to the 14th modification, at least the ripples indicated by a dotted line E1 are reduced or prevented, compared with the comparative example. In the acoustic wave device according to the 14th modification, as in the acoustic wave device 10J according to the fifth example embodiment, ripples and propagation loss are reduced or prevented.

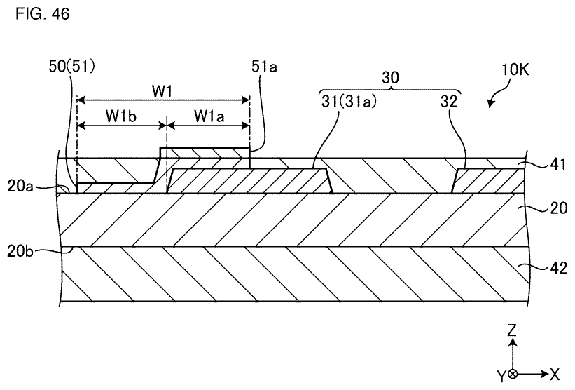

FIG. 46 is a cross-sectional view of an acoustic wave device according to a 15th modification of the fifth example embodiment. As illustrated in FIG. 46, an acoustic wave device 10K according to the 15th modification differs from the acoustic wave device 10J according to the fifth example embodiment in that the load film 50 includes a protrusion portion 51a. The protrusion portion 51a is provided on the overlap portion of the load film 50 that overlaps the first electrode finger 31a and protrudes from the upper surface of the first protective film 41.

The load film 50 and the protrusion portion 51a include, for example, tantalum oxide (Ta₂O₅) as in the fifth example embodiment described above. The film thickness of the load film 50 is, for example, about 35 nm, and the film thickness (the protrusion from the upper surface of the first protective film 41) of the protrusion portion 51a is, for example, about 5 nm. The width of the load film 50 and the configurations of the first protective film 41, the IDT electrode 30, and other members are the same or substantially the same as those in the fifth example embodiment.

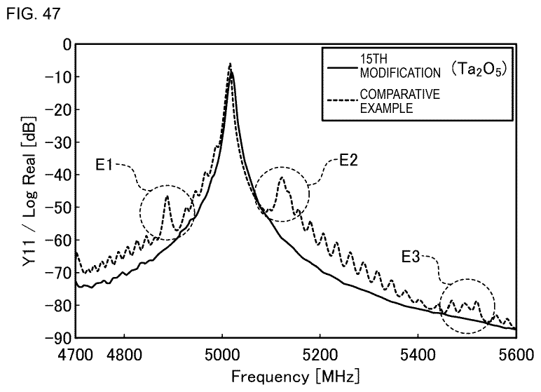

FIG. 47 is an explanatory diagram illustrating an example of the admittance characteristics of the acoustic wave device according to the 15th modification of the fifth example embodiment. As illustrated in FIG. 47, it is revealed that in the acoustic wave device according to the 15th modification, the ripples indicated by dotted lines E1, E2, and E3 are reduced or prevented, compared with the comparative example. In the acoustic wave device according to the 15th modification, as in the acoustic wave device 10J according to the fifth example embodiment, ripples and propagation loss are reduced or prevented.

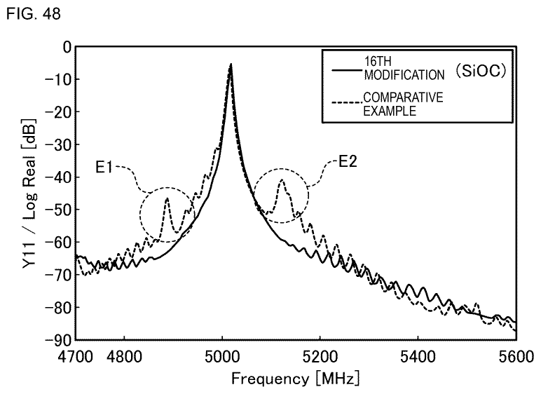

FIG. 48 is an explanatory diagram illustrating an example of the admittance characteristics of an acoustic wave device according to a 16th modification of the fifth example embodiment. The acoustic wave device according to the 16th modification differs from the acoustic wave device 10K according to the 15th modification in that the load film 50 includes, for example, carbon-added silicon oxide (SiOC). The film thickness of the load film 50 is, for example, about 65 nm. The film thickness (the protrusion from the upper surface of the first protective film 41) of the protrusion portion 51a is, for example, about 35 nm. The width of the load film 50 and the configurations of the first protective film 41, the IDT electrode 30, and other members are the same or substantially the same as those in the 15th modification.

As illustrated in FIG. 48, it is revealed that in the acoustic wave device according to the 16th modification, at least the ripples indicated by dotted lines E1 and E2 are reduced or prevented, compared with the comparative example. In the acoustic wave device according to the 16th modification, as in the acoustic wave device 10K according to the 15th modification, ripples and propagation loss are reduced or prevented.

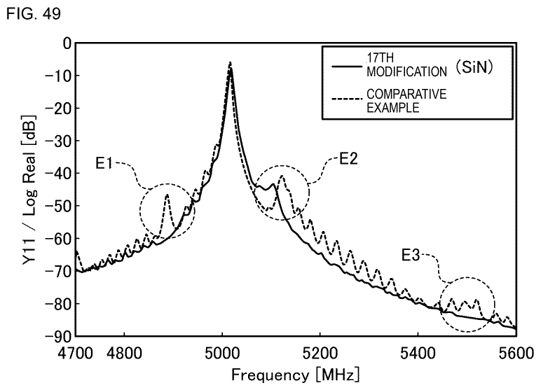

FIG. 49 is an explanatory diagram illustrating an example of the admittance characteristics of an acoustic wave device according to a 17th modification of the fifth example embodiment. The acoustic wave device according to the 17th modification differs from the acoustic wave device 10K according to the 15th modification in that the load film 50 includes, for example, silicon nitride (Si₃N₄). The film thickness of the load film 50 is, for example, about 75 nm. The film thickness (the protrusion from the upper surface of the first protective film 41) of the protrusion portion 51a is, for example, about 45 nm. The width of the load film 50 and the configurations of the first protective film 41, the IDT electrode 30, and other members are the same or substantially the same as those in the 15th modification.

As illustrated in FIG. 49, it is revealed that in the acoustic wave device according to the 17th modification, at least the ripples indicated by dotted lines E1, E2, and E3 are reduced or prevented, compared with the comparative example. In the acoustic wave device according to the 17th modification, as in the acoustic wave device 10K according to the 15th modification, ripples and propagation loss are reduced or prevented.

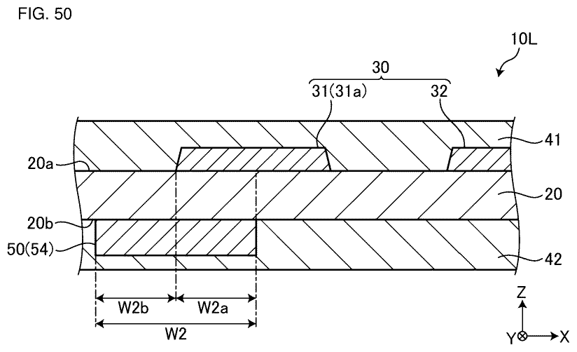

FIG. 50 is a cross-sectional view of an acoustic wave device according to a sixth example embodiment of the present invention. As illustrated in FIG. 50, in an acoustic wave device 10L according to the sixth example embodiment, a load film 50 is provided on the second major surface 20b of the piezoelectric layer 20. The second protective film 42 is provided on the second major surface 20b of the piezoelectric layer 20, covering the load film 50. The lower surface of the second protective film 42 is provided flat across the region that overlaps the load film 50 and the region that does not overlap the load film 50. In the sixth example embodiment, no load film 50 is provided on the first major surface 20a side of the piezoelectric layer 20, and the upper surface of the first protective film 41 is flat.

The load film 50 is provided overlapping a portion of the first electrode finger 31a. In the sixth example embodiment, the load film 50 is made of a material different from the first and second protective films 41 and 42, for example, tantalum oxide (Ta₂O₅). The width W2 of the load film 50 is, for example, about 0.8 μm. The width W2a of the overlap region of the load film 50 is, for example, about 0.3 μm. The width W2b of the non-overlap region of the load film 50 is, for example, about 0.5 μm. The film thickness t4 of the load film 50 is, for example, about 95 nm.

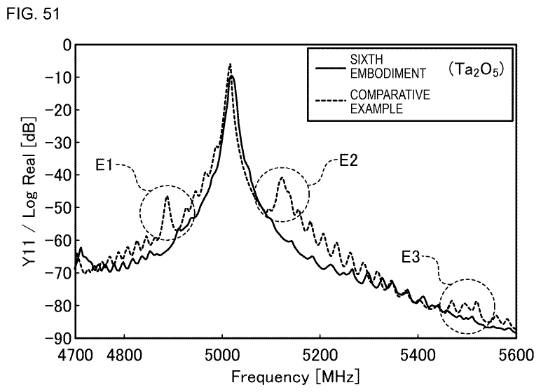

FIG. 51 is an explanatory diagram illustrating an example of the admittance characteristics of the acoustic wave device according to the sixth example embodiment. As illustrated in FIG. 51, in the acoustic wave device 10L according to the sixth example embodiment, the ripples indicated by dotted lines E1, E2, and E3 are reduced or prevented, compared with the comparative example. Thus, in the sixth example embodiment, even when the load film 50 is provided on the second major surface 20b of the piezoelectric layer 20, ripples and propagation loss are reduced or prevented.

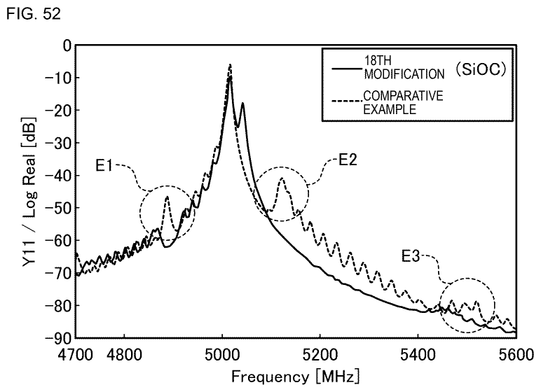

FIG. 52 is an explanatory diagram illustrating an example of the admittance characteristics of an acoustic wave device according to an 18th modification of the sixth example embodiment. The acoustic wave device according to the 18th modification differs from the acoustic wave device 10L according to the sixth example embodiment in that the load film 50 includes, for example, of carbon-added silicon oxide (SiOC). The film thickness and width of the load film 50 and the configurations of the first protective film 41, the second protective film 42, the IDT electrode 30, and other members are the same or substantially the same as those in the sixth example embodiment.

As illustrated in FIG. 52, in the acoustic wave device according to the 18th modification, as in the acoustic wave device 10L according to the sixth example embodiment, the ripples indicated by dotted lines E1, E2, and E3 are reduced or prevented, compared with the comparative example. Thus, in the 18th modification, as in the acoustic wave device 10L according to the sixth example embodiment, ripples and propagation loss are reduced or prevented.

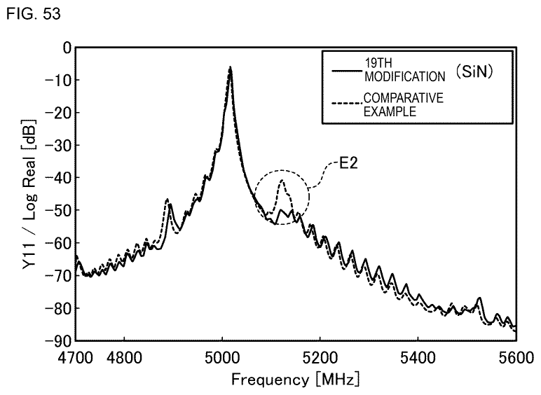

FIG. 53 is an explanatory diagram illustrating an example of the admittance characteristics of an acoustic wave device according to a 19th modification of the sixth example embodiment. The acoustic wave device according to the 19th modification differs from the acoustic wave device 10L according to the sixth example embodiment in that the load film 50 includes, for example, silicon nitride (Si₃N₄). The film thickness of the load film 50 is, for example, about 55 nm. The width of the load film 50 and the configurations of the first protective film 41, the second protective film 42, the IDT electrode 30, and other members are the same or substantially the same as those in the sixth example embodiment.

As illustrated in FIG. 53, in the acoustic wave device according to the 19th modification, at least the ripples indicated by a dotted line E2 are reduced or prevented, compared with the comparative example. In the 19th modification, although the effect is smaller than that of the acoustic wave device 10L according to the sixth example embodiment, ripples and propagation loss are reduced or prevented.

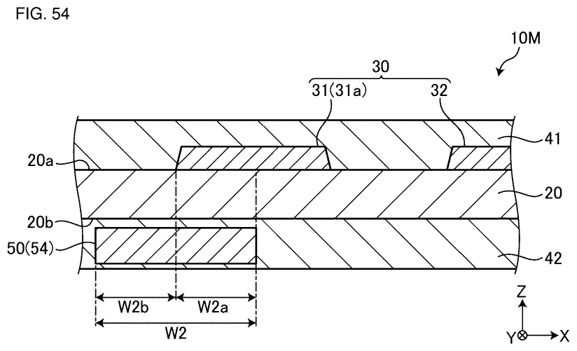

FIG. 54 is a cross-sectional view of an acoustic wave device according to a 20th modification of the sixth example embodiment. As illustrated in FIG. 54, in an acoustic wave device 10M according to the 20th modification, the load film 50 is provided on the second major surface 20b side of the piezoelectric layer 20. To be more specific, the load film 50 faces the second major surface 20b of the piezoelectric layer 20 and is spaced apart from the second major surface 20b.

The load film 50 is disposed within the second protective film 42. That is, the second protective film 42 is provided between the second major surface 20b of the piezoelectric layer 20 and the load film 50 and covers the side surface and the lower surface (the surface opposite to the piezoelectric layer 20) of the load film 50. In other words, the load film 50 is provided on the outer side of the second major surface 20b of the piezoelectric layer 20 in the direction vertical to the second major surface 20b of the piezoelectric layer 20. The load film 50 is not limited to the configuration in which it is arranged within the second protective film 42 and may be provided on the lower surface of the second protective film 42.

The load film 50 includes, for example, tantalum oxide (Ta₂O₅) as in the sixth example embodiment. The width W2 of the load film 50 is, for example, about 0.8 μm. The width and film thickness of the load film 50 and the configurations of the first protective film 41, the second protective film 42, the IDT electrode 30, and other members are the same or substantially the same as those in the sixth example embodiment. The distance between the load film 50 and the second major surface 20b of the piezoelectric layer 20 is, for example, about 10 nm in the direction vertical to the second major surface 20b of the piezoelectric layer 20.

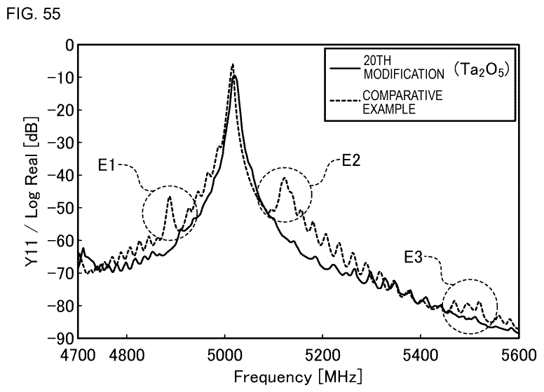

FIG. 55 is an explanatory diagram illustrating an example of the admittance characteristics of the acoustic wave device according to the 20th modification of the sixth example embodiment. As illustrated in FIG. 55, in the acoustic wave device according to the 20th modification, the ripples indicated by dotted lines E1, E2, and E3 are reduced or prevented, compared with the comparative example. Thus, even when the load film 50 is spaced apart from the second major surface 20b of the piezoelectric layer 20, ripples and propagation loss are reduced or prevented as in the acoustic wave device 10L according to the sixth example embodiment.

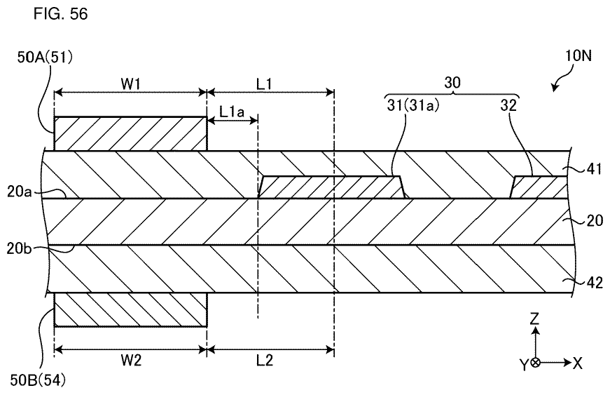

FIG. 56 is a cross-sectional view of an acoustic wave device according to a seventh example embodiment of the present invention. As illustrated in FIG. 56, in an acoustic wave device 10N according to the seventh example embodiment, load films 50 are provided in a region that does not overlap the IDT electrode 30, on the outer side of the first electrode finger 31a in the arrangement direction of the plurality of electrode fingers 31 and 32. Here, the first electrode finger 31a is positioned outermost in the arrangement direction among the plurality of electrode fingers 31 and 32.

The load films 50 of the seventh example embodiment include an upper load film 50A provided on the first protective film 41 as in the third example embodiment (see FIG. 27), and a lower load film 50B provided on the lower surface of the second protective film 42. The upper load film 50A and the lower load film 50B are both provided on the outer side of the first electrode finger 31a in the arrangement direction.

The upper load film 50A and the lower load film 50B are provided in overlapping regions and have the same or substantially the same shape. The width W1 of the upper load film 50A is the same or substantially the same as the width W2 of the lower load film 50B, which are, for example, about 0.6 μm. A distance L1 between one side surface of the upper load film 50A and the widthwise midpoint of the first electrode finger 31a is, for example, about 0.4 μm. A distance L2 between one side surface of the lower load film 50B and the widthwise midpoint of the first electrode finger 31a is the same or substantially the same as the distance L1, which is, for example, about 0.4 μm.

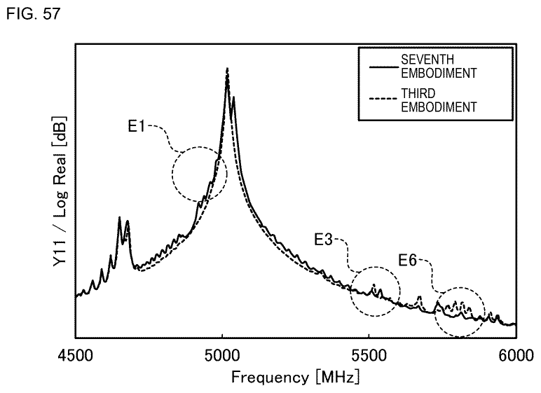

FIG. 57 is an explanatory diagram illustrating an example of the admittance characteristics of the acoustic wave device according to the seventh example embodiment. FIG. 57 illustrates the admittance characteristics of the acoustic wave device 10N according to the seventh example embodiment in comparison with those of the acoustic wave device 10E according to the third example embodiment (see FIGS. 27 and 28).

As illustrated in FIG. 57, in the acoustic wave device 10N according to the seventh example embodiment, even when the load films 50 are provided on the outer side of the IDT electrode 30 in the arrangement direction, ripples and propagation loss are reduced or prevented as in the acoustic wave device 10E according to the third example embodiment. Furthermore, in the seventh example embodiment, the ripples on the high-frequency side, indicated by a dotted line E6, are favorably reduced or prevented, compared to the third example embodiment.

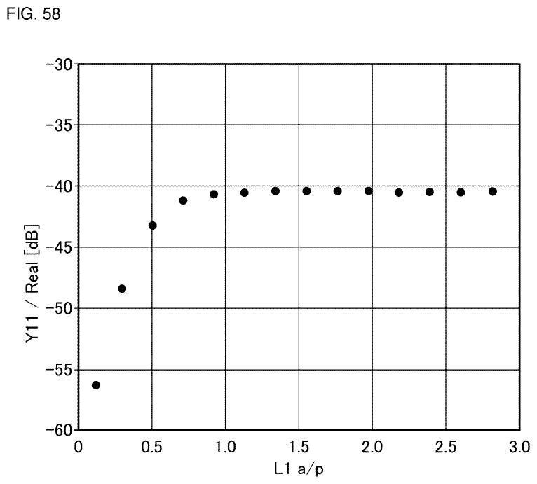

FIG. 58 is an explanatory diagram illustrating the relationship between the distance between a load film and the first electrode finger and the admittance in the acoustic wave device according to the seventh example embodiment. Here, a distance L1a (see FIG. 56) refers to the distance between the first electrode finger 31a, which is positioned outermost in the arrangement direction of the plurality of electrode fingers 31, and the load film 51. In the graph illustrated in FIG. 58, the horizontal axis represents the ratio (L1a/p) of the distance L1a to the electrode pitch p, and the vertical axis represents the real portion of the admittance at the frequency indicated by the dotted line E2 (see FIG. 14, etc.).

As illustrated in FIG. 58, as the ratio L1a/p decreases, that is, as the distance L1a between the first electrode finger 31a and the load film 51 decreases, the admittance decreases. Preferably, for example, L1a/p is about 0.9 or less.

The seventh example embodiment can be combined with any of the example embodiments and modifications described above. For example, the load films 50 may include only one of the upper or lower load film 50A or 50B. Alternatively, the upper and lower load films 50A and 50B may have different shapes (width, film thickness) or may be disposed at different positions in the arrangement direction of the plurality of electrode fingers 31 and 32.

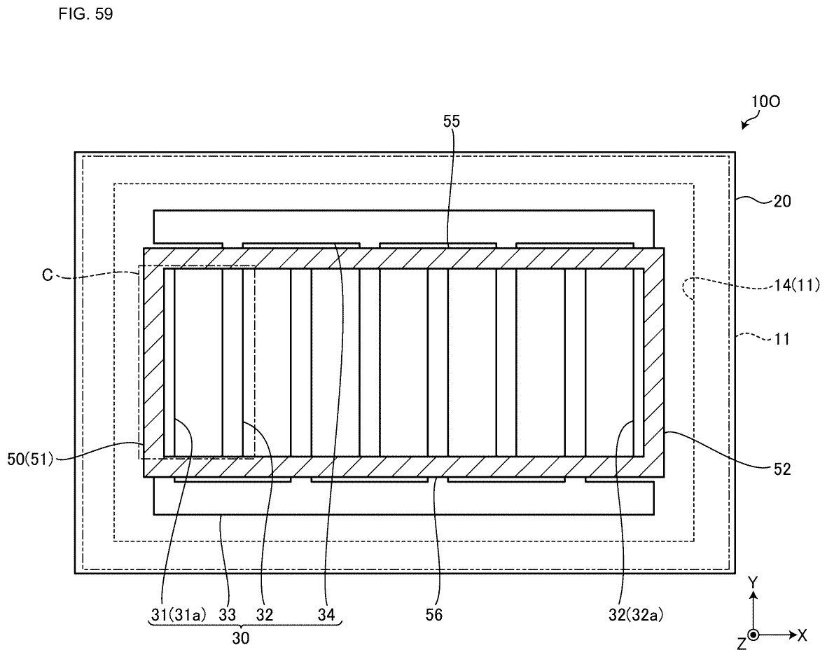

FIG. 59 is a plan view of an acoustic wave device according to an eighth example embodiment of the present invention. As illustrated in FIG. 59, in the acoustic wave device 10O according to the eighth example embodiment, a load film 50 is provided in a frame. Specifically, the load film 50 includes the first extending portion 51, the second extending portion 52, a third extending portion 55, and a fourth extending portion 56.

The first extending portion 51 is provided in a region that overlaps the first electrode finger 31a, which is positioned outermost in the arrangement direction of the plurality of electrode fingers 31 and 32, and extends in the extending direction of the first electrode finger 31a. The second extending portion 52 is provided in a region that overlaps the second electrode finger 32a, which is positioned outermost in the arrangement direction of the plurality of electrode fingers 31 and 32 on the opposite side to the first electrode finger 31a, and extends in the extending direction of the second electrode finger 32a.

The third extending portion 55 is connected to the ends of the first and second extending portions 51 and 52 on one side in the extending direction thereof and extends in the arrangement direction of the plurality of electrode fingers 31 and 32. The third extending portion 55 also extends overlapping the ends of the plurality of electrode fingers 31 in the extending direction. The fourth extending portion 56 is connected to the ends of the first and second extending portions 51 and 52 on the other side in the extending direction thereof and extends in the arrangement direction of the plurality of electrode fingers 31 and 32. The fourth extending portion 56 also extends overlapping the ends of the plurality of electrode fingers 32 in the extending direction.

As described above, in the acoustic wave device 10O according to the eighth example embodiment, the load film 50 is provided as a continuous frame. The acoustic reflection plane R (see FIG. 12) is thus provided along each of the first to fourth extending portions 51, 52, 55, and 56. As a result, the acoustic wave device 10O can reduce leakage of acoustic waves in the arrangement direction of the plurality of electrode fingers 31 and 32 and can also reduce leakage of acoustic waves in the extending direction of the plurality of electrode fingers 31 and 32.

The third and fourth extending portions 55 and 56 are provided in the same layer as the first and second extending portions 51 and 52 illustrated in the first example embodiment (see FIG. 12) and are made of the same material with the same film thickness. The third and fourth extending portions 55 and 56 can be formed in the same process as the first and second extending portions 51 and 52, thus reducing the manufacturing costs.

In the eighth example embodiment, the load film 50 is provided on the first protective film 41 as in the first example embodiment (see FIG. 12). However, the present invention is not limited thereto. The load film 50 according to the eighth example embodiment may be combined with any of the example embodiments and modifications described above.

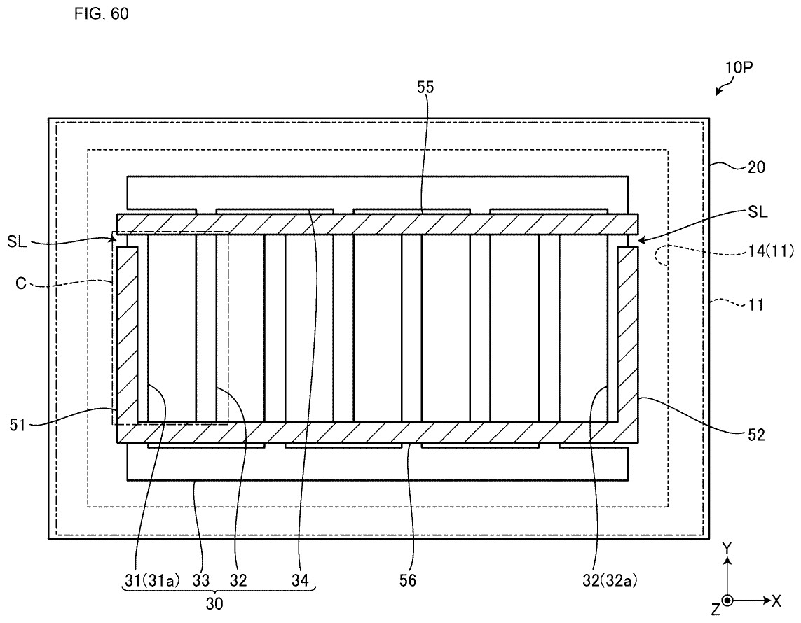

FIG. 60 is a plan view of an acoustic wave device according to a 21st modification of the eighth example embodiment. In the illustrated structure of the acoustic wave device 10O according to the eighth example embodiment, the load film 50 is provided as a continuous frame. However, the present invention is not limited thereto.

As illustrated in FIG. 60, in an acoustic wave device 10P according to the 21st modification, the third extending portion 55 is disposed at ends of the first and second extending portions 51 and 52 on one side in the extending direction thereof and is spaced apart from the first and second extending portions 51 and 52 with slits SL interposed therebetween. The fourth extending portion 56 is disposed at the ends of the first and second extending portions 51 and 52 on the other side in the extending direction thereof and is connected to the first and second extending portions 51 and 52.

In the 21st modification, the first, second, third, and fourth extending portions 51, 52, 55, and 56 are at least partially provided with the slits SL. The 21st modification is thus advantageous over the eighth example embodiment when the load film 50 is formed by lift-off process.

The configuration of the load film 50 can be properly changed. For example, the third extending portion 55 may be connected to the ends of the first and second extending portions 51 and 52 on one side in the extending direction while the fourth extending portion 56 is spaced apart from the ends of the first and second extending portions 51 and 52 on the other side in the extending direction with slits SL interposed therebetween. Alternatively, both of the third and fourth extending portions 55 and 56 may be spaced apart from the first and second extending portions 51 and 52 with slits SL interposed therebetween.

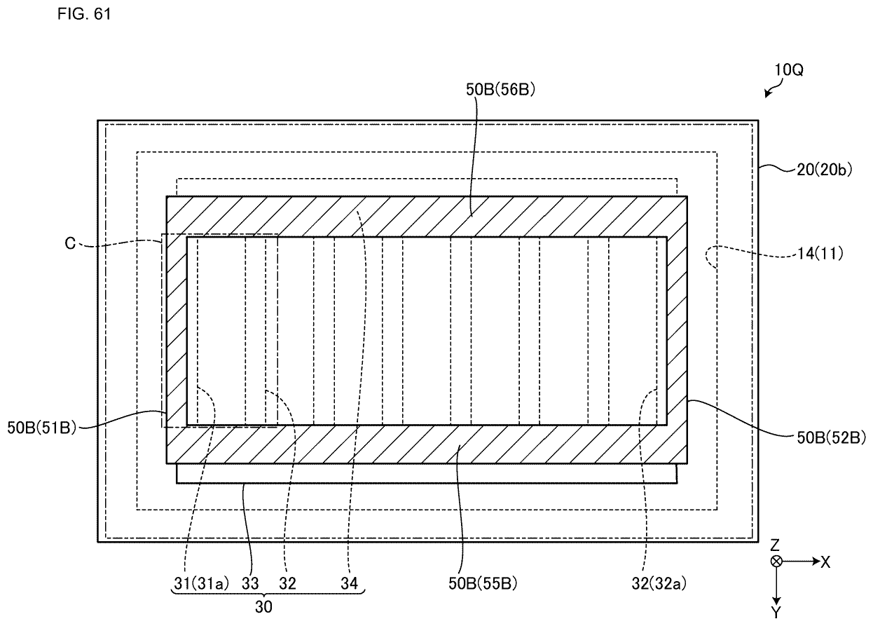

FIG. 61 is a plan view of an acoustic wave device according to a 22nd modification of the eighth example embodiment. As illustrated in FIG. 61, in an acoustic wave device 10Q according to the 22nd modification, a frame-shaped lower load film 50B is provided on the second major surface 20b side of the piezoelectric layer 20. The configurations of a first extending portion 51B, a second extending portion 52B, a third extending portion 55B, and a fourth extending portion 56B of the lower load film 50B are the same or substantially the same as those in the eighth example embodiment, and the repetitive description is omitted. However, in the lower load film 50B, the widths (the lengths in the direction perpendicular or substantially perpendicular to the extending direction) of the third and fourth extending portions 55B and 56B are greater than the widths (the lengths in the direction perpendicular or substantially perpendicular to the extending direction) of the first and second extending portions 51B and 52B.

In the acoustic wave device 10Q according to the 22nd modification, the upper load film 50A, which includes the first and second extending portions 51 and 52 (see FIGS. 1 and 2) as in the load film 50 of the first example embodiment, is provided on the first major surface 20a side of the piezoelectric layer 20. The upper and lower load films 50A and 50B are made of silicon oxide, for example, as in the first example embodiment.

Since the upper load film 50A, which is provided on the first major surface 20a side of the piezoelectric layer 20, has a different configuration from the lower load film 50B, which is provided on the second major surface 20b side of the piezoelectric layer 20, the membrane shape of the piezoelectric layer 20 protrudes toward the first major surface 20a side. This can reduce or prevent sticking of the piezoelectric layer 20.

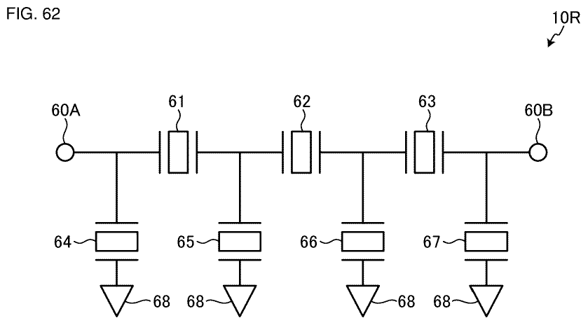

FIG. 62 is a circuit diagram illustrating an acoustic wave device according to a ninth example embodiment of the present invention. As illustrated in FIG. 62, an acoustic wave device 10R according to the ninth example embodiment includes a plurality of series arm resonators 61, 62, and 63 and a plurality of parallel arm resonators 64, 65, 66, and 67. The plurality of series arm resonators 61, 62, and 63 are coupled in series on a signal path between an input terminal 60A and an output terminal 60B. The plurality of parallel arm resonators 64, 65, 66, and 67 are coupled in parallel between ground 68 and the signal path between the input and output terminals 60A and 60B. The acoustic wave device 10R according to the ninth example embodiment defines ladder filter.

One terminal of the plurality of series arm resonators 61, 62, and 63 coupled in series is electrically coupled to the input terminal 60A, and the other terminal is electrically coupled to the output terminal 60B. One terminal of the parallel arm resonator 64 is electrically coupled to the input terminal 60A while the other terminal is electrically coupled to the ground 68. One terminal of the parallel arm resonator 65 is electrically coupled to the signal path connecting the series arm resonators 61 and 62 while the other terminal is electrically coupled to the ground 68. One terminal of the parallel arm resonator 66 is electrically coupled to the signal path connecting the series arm resonators 62 and 63 while the other terminal is electrically coupled to the ground 68. One terminal of the parallel arm resonator 67 is electrically coupled to the output terminal 60B while the other terminal is electrically coupled to the ground 68.

In the ninth example embodiment, the plurality of series arm resonators 61, 62, and 63 include the load film 50 having a configuration different from that of the plurality of parallel arm resonators 64, 65, 66, and 67. For example, the plurality of series arm resonators 61, 62, and 63 include the load film 50 illustrated in the first example embodiment (see FIGS. 12 and 13). The admittance characteristics of the plurality of series arm resonators 61, 62, and 63 are the same or substantially the same as those in FIG. 13, and the repetitive description is omitted.

The plurality of parallel arm resonators 64, 65, 66, and 67 include the load film 50 illustrated in the fourth modification (see FIGS. 17 and 18). The admittance characteristics of the plurality of parallel arm resonators 64, 65, 66, and 67 are the same or substantially the same as those in FIG. 17, and the repetitive description is omitted.

In the ninth example embodiment, the load films 50 are configured differently between the plurality of series arm resonators 61, 62, and 63 and the plurality of parallel arm resonators 64, 65, 66, and 67, thus achieving a favorable output waveform as a filter.

In the illustrated example of the acoustic wave device 10R according to the ninth example embodiment, the load films 50 illustrated in the first example embodiment and the fourth modification are combined. However, the present invention is not limited thereto. The ninth example embodiment can be combined with any of the example embodiments and modifications described above.

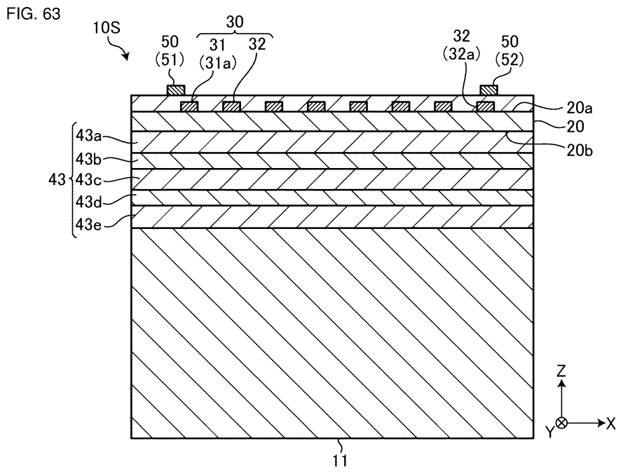

FIG. 63 is a cross-sectional view of an acoustic wave device according to a 23rd modification. In the acoustic wave device 10 of the first example embodiment, the membrane structure is illustrated, in which the support substrate 11 includes the cavity portion 14 and the cavity portion 14 (the hollow portion) is provided on the second major surface 20b side of the piezoelectric layer 20. However, the present invention is not limited thereto.

As illustrated in FIG. 63, an acoustic wave device 10S according to the 23rd modification includes an acoustic multilayer film 43, which is laminated on the second major surface 20b of the piezoelectric layer 20. The acoustic multilayer film 43 includes a multilayer structure including low acoustic impedance layers 43a, 43c, and 43e with relatively low acoustic impedance and high acoustic impedance layers 43b and 43d with relatively high acoustic impedance. The low acoustic impedance layers 43a, 43c, and 43e are, for example, SiO₂ layers, and the high acoustic impedance layers 43b and 43d are, for example, metal layers of W, Pt, or the like or dielectric layers of AlN, Si₃N₄, or the like. By using the acoustic multilayer film 43, the first-order thickness-shear mode bulk wave can be confined within the piezoelectric layer 20 without using the cavity portion 14.

The acoustic wave device 10S can also provide the resonance characteristics based on the first-order thickness-shear mode bulk wave when d/p is set to about 0.5 or less, for example. In the acoustic multilayer film 43, the number of the laminated low acoustic impedance layers 43a, 43c, and 43e and the number of the laminated high acoustic impedance layers 43b and 43d are not limited. At least one of the high acoustic impedance layers 43b and 43d needs to be disposed on the side farther from the piezoelectric layer 20 than the low acoustic impedance layer 43a, 43c, or 43e.

The low acoustic impedance layers 43a, 43c, and 43e and the high acoustic impedance layers 43b and 43d can be made of a proper material when they satisfy the acoustic impedance relationship. For example, the material of the low acoustic impedance layers 43a, 43c, and 43e can be silicon oxide, silicon oxynitride, or the like. The material of the high acoustic impedance layers 43b and 43d can be alumina, silicon nitride, metal, or the like.

In the 23rd modification in FIG. 63, the load film 50 illustrated in the first example embodiment is provided. However, the present invention is not limited thereto. The 23rd modification can be combined with any of the example embodiments and modifications described above.

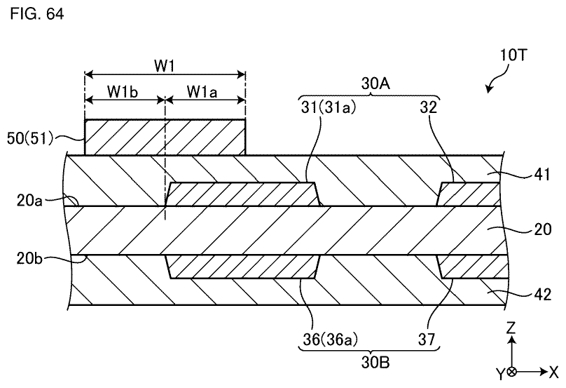

FIG. 64 is a cross-sectional view of an acoustic wave device according to a 24th modification. In the illustrated structure of the acoustic wave device 10 of the first example embodiment, the IDT electrode 30 is provided on the first major surface 20a of the piezoelectric layer 20. However, the present invention is not limited thereto. As illustrated in FIG. 64, an acoustic wave device 10T according to the 24th modification includes a first IDT electrode 30A provided on the first major surface 20a of the piezoelectric layer 20, and a second IDT electrode 30B provided on the second major surface 20b of the piezoelectric layer 20. The first and second IDT electrodes 30A and 30B have the same or substantially the same configuration as the IDT electrode 30 (see FIGS. 1 and 2).

Electrode fingers 36 and 37 of the second IDT electrodes 30B are provided in regions that overlap the electrode fingers 31 and 32 of the first IDT electrode 30A, respectively. The electrode fingers 36 and 37 of the second IDT electrode 30B have the same or substantially the same width and electrode pitch as the electrode fingers 31 and 32 of the first IDT electrode 30A. The load film 50 is provided in a region that overlaps the first electrode finger 31a of the first IDT electrode 30A and a first electrode finger 36a of the second IDT electrode 30B.

In the 24th modification, the first and second IDT electrodes 30A and 30B are provided on the first and second major surfaces 20a and 20b of the piezoelectric layer 20, respectively, thus improving the temperature coefficients of frequency (TCF).

In the example in FIG. 64, the load film 50 illustrated in the first example embodiment is provided. However, the present invention is not limited thereto. The 24th modification can be combined with any of the example embodiments and modifications.

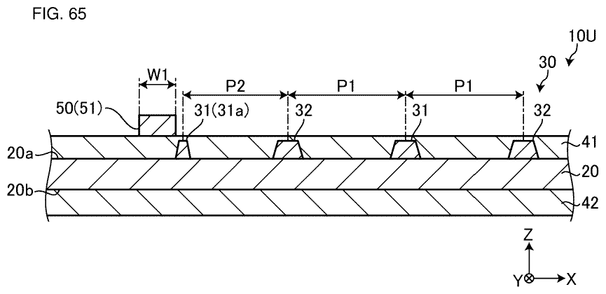

FIG. 65 is a cross-sectional view of an acoustic wave device according to a 25th modification. As illustrated in FIG. 65, in an acoustic wave device 10U according to the 25th modification, the electrode width of the first electrode finger 31a, which is located outermost in the arrangement direction of the plurality of electrode fingers 31 and 32, is smaller than that of the electrode fingers 31 and 32 positioned in the center in the arrangement direction. Furthermore, an electrode pitch P2, which is positioned outermost in the arrangement direction, is smaller than the electrode pitch P1, which is positioned closer to the center than the electrode pitch P2. Here, the electrode pitch P2 is the electrode-to-electrode distance between the first electrode finger 31a, which is positioned outermost in the arrangement direction of the plurality of the electrode fingers 31 and 32, and the electrode finger 32 adjacent thereto. The electrode pitch P1 is the electrode-to-electrode distance between multiple electrode fingers 31 and 32 positioned closer to the center in the arrangement direction than the first electrode finger 31a and the electrode finger 32 adjacent thereto.

Specifically, for example, the electrode width of the first electrode finger 31a, which is positioned outermost in the arrangement direction, is about 0.3 μm, and the electrode width of the other multiple electrode fingers 31 and 32 located in the center is about 0.6 μm. The electrode pitch P2, which is positioned outermost in the arrangement direction, is, for example, about 2.23 μm, and the electrode pitch P1, which is closer to the center than the electrode pitch P2, is, for example, about 2.38 μm.

The load film 50 is provided in a region that does not overlap the first electrode finger 31a. Specifically, in the arrangement direction of the plurality of electrode fingers 31 and 32, the load film 50 is provided in a region that does not overlap the IDT electrode 30 on the outer side of the first electrode finger 31a, which is positioned outermost among the plurality of electrode fingers 31 and 32. The width W1 of the load film 50 is, for example, about 0.6 μm. The film thickness of the load film 50 is, for example, about 90 nm.

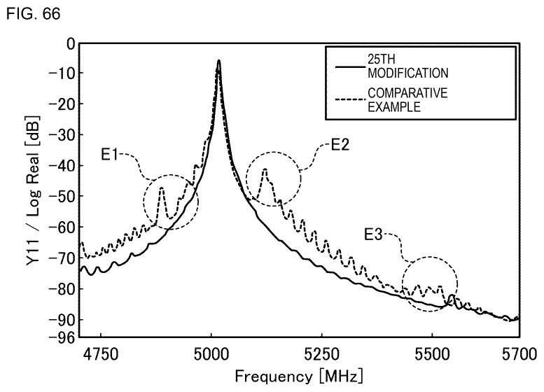

FIG. 66 is an explanatory diagram illustrating an example of the admittance characteristics of the acoustic wave device according to the 25th modification. As illustrated in FIG. 66, in the acoustic wave device 10U according to the 25th modification, the ripples indicated by dotted lines E1, E2, and E3 are reduced or prevented, compared with the comparative example. Thus, even when the electrode width of the first electrode finger 31a is smaller than that of the other electrode fingers 31 and 32 and the electrode pitch P2 is smaller than the electrode pitch P1, ripples and propagation loss are reduced or prevented. In the acoustic wave device 10U according to the 25th modification, the propagation loss is effectively reduced or prevented over a wide frequency range of, for example, about 4700 MHz to about 5500 MHz, compared with the example embodiments and modifications described above.

In the structure of the 25th modification illustrated in FIG. 65, the electrode width of the single first electrode finger 31a is smaller than that of the other electrode fingers 31 and 32. However, the present invention is not limited thereto. The electrode width of multiple electrode fingers 31 and 32 positioned outermost in the arrangement direction of the plurality of electrode fingers 31 and 32 may be smaller than that of the other electrode fingers 31 and 32 positioned in the center. In a similar manner, the electrode pitch P of three or more electrode fingers 31 and 32 positioned outermost in the arrangement direction of the plurality of electrode fingers 31 and 32 may be smaller than the electrode pitch P of the other electrode fingers 31 and 32 positioned in the center.

In the structure of the 25th modification illustrated in FIG. 65, the load film 50 is provided in a region that does not overlap the first electrode finger 31a. However, the present invention is not limited thereto. In the 25th modification, the load film 50 may be provided in a region that overlaps the first electrode finger 31a. The load film 50 is provided on the first protective film 41, but the present invention is not limited thereto. The 25th modification can be combined with any of the example embodiments and modifications described above.

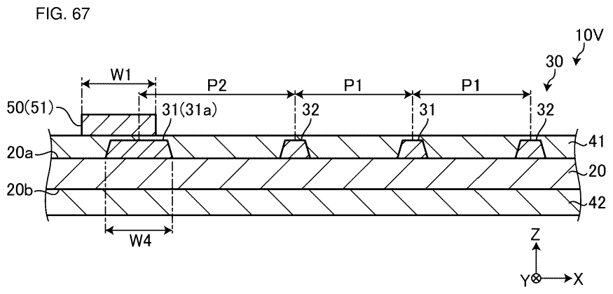

FIG. 67 is a cross-sectional view of an acoustic wave device according to a 26th modification. As illustrated in FIG. 67, in an acoustic wave device 10V according to the 26th modification, an electrode width W4 of the first electrode finger 31a, which is positioned outermost in the arrangement direction of the plurality of electrode fingers 31 and 32, is greater than the electrode width of the electrode fingers 31 and 32 positioned in the center in the arrangement direction. Furthermore, the outermost electrode pitch P2 in the arrangement direction is greater than the electrode pitch P1, which is closer to the center than the electrode pitch P2.

Specifically, for example, the electrode width of the first electrode finger 31a, which is positioned outermost in the arrangement direction, is about 1.0 μm, and the electrode width of the other electrode fingers 31 and 32 positioned in the center is about 0.6 μm. The electrode pitch P2, which is positioned outermost in the arrangement direction, is, for example, about 2.58 μm, and the electrode pitch P1, which is closer to the center than the electrode pitch P2, is, for example, about 2.38 μm.

In the 26th modification, the load film 50 is provided in a region that overlaps the first electrode finger 31a, which is positioned outermost among the plurality of electrode fingers 31 and 32 in the arrangement direction thereof. The width W1 of the load film 50 is, for example, about 0.8 μm. The film thickness of the load film 50 is, for example, about 15 nm. One side surface of the load film 50 is positioned offset toward the adjacent electrode finger 32 relative to the widthwise center of the first electrode finger 31a. The width of the overlap region of the load film 50 with the first electrode finger 31a is, for example, about 0.7 μm. The width of the non-overlap region of the load film 50 is, for example, about 0.1 μm.

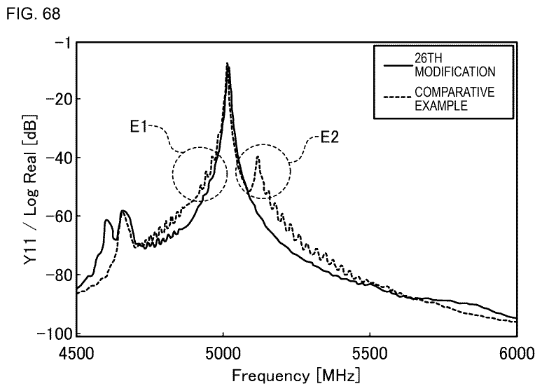

FIG. 68 is an explanatory diagram illustrating an example of the admittance characteristics of the acoustic wave device according to the 26th modification. As illustrated in FIG. 68, in the acoustic wave device 10V according to the 26th modification, the ripples indicated by dotted lines E1 and E2 are reduced or prevented, compared with the comparative example. Thus, even when the electrode width of the first electrode finger 31a is greater than that of the other electrode fingers 31 and 32 and the electrode pitch P2 is greater than the electrode pitch P1, ripples and propagation loss are reduced or prevented.

In the configuration of the 26th modification illustrated in FIG. 67, the electrode width of the single first electrode finger 31a is greater than the other electrode fingers 31 and 32. However, the present invention is not limited thereto. In the arrangement direction of the plurality of electrode fingers 31 and 32, the electrode width of multiple electrode fingers 31 and 32 positioned outermost may be greater than that of the other electrode fingers 31 and 32 positioned in the center. In a similar manner, in the arrangement direction of the plurality of electrode fingers 31 and 32, the electrode pitch P of three or more electrode fingers 31 and 32 positioned outermost may be greater than the electrode pitch P of the other electrode fingers 31 and 32 positioned in the center.

In the configuration of the 26th modification illustrated in FIG. 67, the load film 50 is provided in a region that overlaps the first electrode finger 31a. However, the present invention is not limited thereto. Furthermore, the load film 50 is provided on the first protective film 41, but the present disclosure is not limited thereto. The 26th modification can be combined with any of the example embodiments and modifications described above.

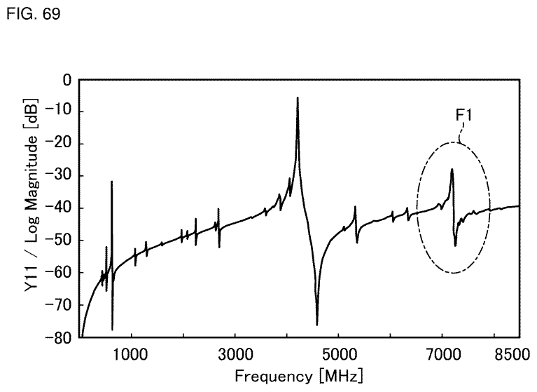

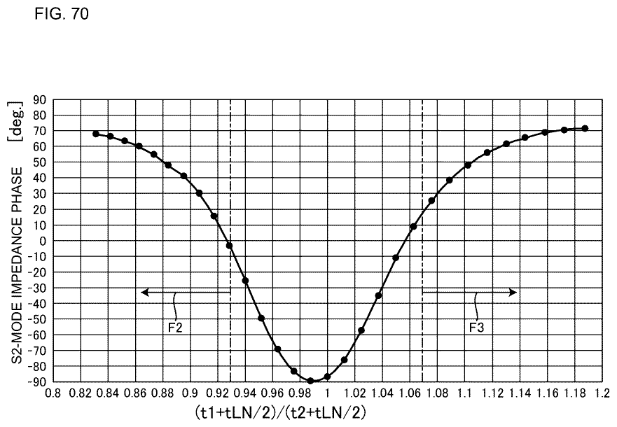

FIG. 69 is an explanatory diagram illustrating an example of the admittance characteristics of an acoustic wave device according to a 27th modification. FIG. 70 is an explanatory diagram illustrating an example of the impedance phase at high-order modes. The acoustic wave device according to the 27th modification illustrated in FIG. 69 has a structure in which the first and second protective films 41 and 42 have different film thicknesses in the acoustic wave device 10 according to the aforementioned first example embodiment.

FIG. 69 illustrates the frequency characteristics of the absolute value of admittance of the acoustic wave device according to the 27th modification. As illustrated in FIG. 69, in the acoustic wave device according to the 27th modification, a high-order mode resonance (hereinafter, referred to as S2 mode) occurs in the frequency region indicated by a dashed-dotted line F1, which is different from the resonant frequency.

The horizontal axis of the graph illustrated in FIG. 70 represents a ratio (t1+tLN/2)/(t2+tLN/2) of the sum (t1+tLN/2) of the film thickness t1 of the first protective film 41 and the half the film thickness tLN of the piezoelectric layer 20 and the sum (t2+tLN/2) of the film thickness t2 of the second protective film 42 and the half the film thickness tLN of the piezoelectric layer 20. The vertical axis of the graph illustrated in FIG. 70 corresponds to S2 mode intensity.

In FIG. 70, the ranges indicated by arrows F2 and F3 represent the ratio (t1+tLN/2)/(t2+tLN/2) in the configuration of the acoustic resonator device described in Japanese Unexamined Patent Application Publication No. 2022-524136. In the acoustic resonator device described in Japanese Unexamined Patent Application Publication No. 2022-524136, the ratio (t1+tLN/2)/(t2+tLN/2) is 0.93 or less and 1.07 or more, and the S2 mode intensity is high.

In the 27th modification, the ratio (t1+tLN/2)/(t2+tLN/2) is in the range of, for example, about 0.94 to about 1.06, inclusive, and the S2 mode intensity is lower than that of the acoustic resonator device described in Japanese Unexamined Patent Application Publication No. 2022-524136. In other words, in the 27th modification, for example, it is preferable that the value of A/B is about 1-0.06 or more and about 1+0.06 or less where A is the total distance from the film thickness center of the piezoelectric layer 20 to the top surface of the first protective film 41 and B is the total distance from the film thickness center of the piezoelectric layer 20 to the top surface of the second protective film 42.

In the description of the 27th modification, the first and second protective films 41 and 42 have different film thicknesses in the acoustic wave device 10 according to the first example embodiment. However, the present invention is not limited thereto. The relationship in the 27th modification between the film thickness t1 of the first protective film 41, the film thickness tLN of the piezoelectric layer 20, and the film thickness t2 of the second protective film 42 can be combined with any of the example embodiments and modifications described above.

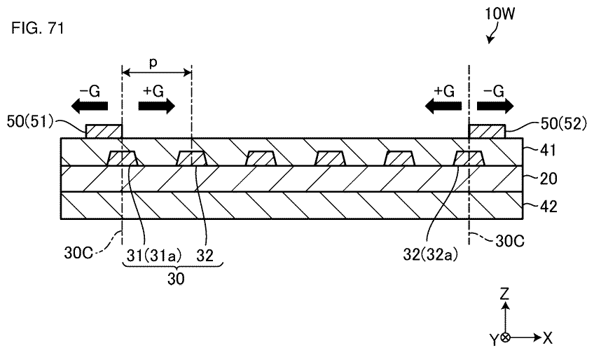

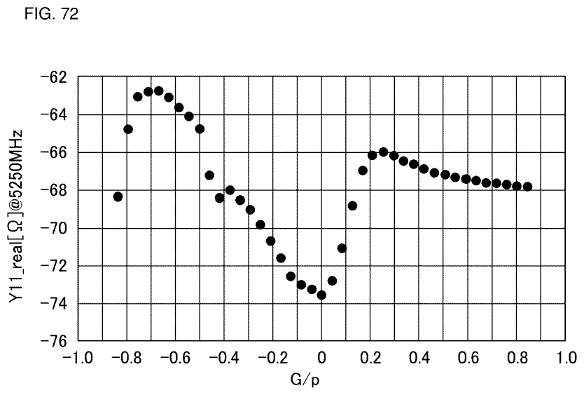

FIG. 71 is a cross-sectional view of an acoustic wave device according to a 28th modification. FIG. 72 is an explanatory diagram illustrating the relationship between the offset amount of the load film and the admittance in the acoustic wave device according to the 28th modification. As illustrated in FIG. 71, in an acoustic wave device 10W according to the 28th modification, the position of one side surface of the load film 50 is offset relative to a widthwise midpoint 30C of the first electrode finger 31a, which is positioned outermost in the arrangement direction of the plurality of electrode fingers 31 and 32.

In the 28th modification, in the arrangement direction of the plurality of electrode fingers 31 and 32, the distance between one side surface of the load film 50 and the widthwise midpoint 30C of the first electrode finger 31a is indicated by an “offset amount G of the load film 50”. The offset amount is indicated by +G when the one side surface of the load film 50 is positioned on the inner side of the widthwise midpoint 30C of the first electrode finger 31a in the arrangement direction of the plurality of electrode fingers 31 and 32. The offset amount is indicated by −G when the one side surface of the load film 50 is positioned on the outer side of the widthwise midpoint 30C of the first electrode finger 31a in the arrangement direction of the plurality of electrode fingers 31 and 32. In FIG. 71, the one side surface of the load film 50 is disposed overlapping the widthwise midpoint 30C of the first electrode finger 31a, and the offset amount G of the load film 50 is about 0, for example.

Although the following description is provided for the load film 50 that overlaps the first electrode finger 31a, the same applies to the load film 50 that is disposed overlapping the second electrode finger 32a, which is positioned on the opposite side to the first electrode finger 31a. In this case, the distance between one side surface of the load film 50 and the widthwise midpoint 30C of the second electrode finger 32a is referred to as the offset amount G of the load film 50. The description about the first electrode finger 31a and the load film 50 that overlaps the first electrode finger 31a is applicable to the second electrode finger 32a and the load film 50 that overlaps the second electrode finger 32a.

The horizontal axis of the graph illustrated in FIG. 72 represents a ratio G/p of the offset amount G of the load film 50 to the center-to-center distance p between adjacent electrode fingers 31 and 32. The vertical axis represents the real portion of the admittance at a frequency of about 5250 MHz.

As illustrated in FIG. 72, the admittance shows its minimum value when the ratio G/p is about 0 and increases as the ratio G/p is increases in the positive direction or decreases in the negative direction. In other words, the admittance shows its minimum value when the position of one side surface of the load film 50 overlaps the widthwise midpoint 30C of the first electrode finger 31a, which is positioned outermost in the arrangement direction of the plurality of electrode fingers 31 and 32. The admittance increases when the position of the one side surface of the load film 50 is offset relative to the widthwise midpoint 30C of the first electrode finger 31a.

To be more specific, on the +G side, the admittance increases when the ratio G/p is in the range of about +0 to about +0.2, inclusive, and reaches a maximum value when the ratio G/p is in the range of about +0.2 to about +0.3, inclusive. On the −G side, the admittance increases when the ratio G/p is in the range of −0 to −0.7, inclusive, and reaches a maximum value when the ratio G/p is around about −0.7. As described above, for example, in the 28th modification, the ratio G/p of the offset amount G of the load film 50 to the center-to-center distance p between adjacent electrode fingers 31 and 32 satisfies about −0.2≤G/p≤about +0.2.

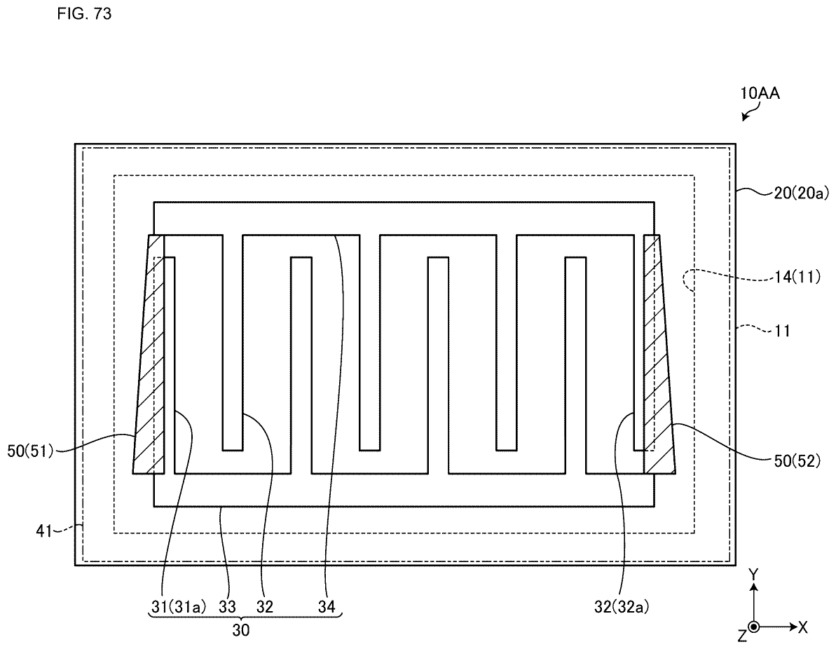

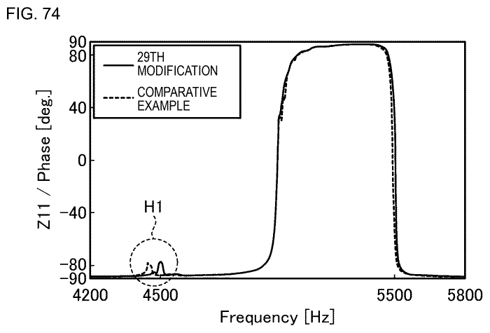

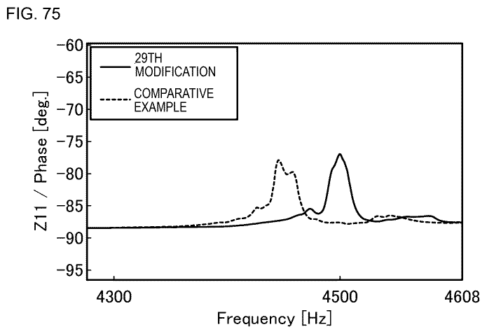

FIG. 73 is a plan view of an acoustic wave device according to a 29th modification. FIG. 74 is an explanatory diagram illustrating an example of the impedance characteristics of the acoustic wave device according to the 29th modification. FIG. 75 is an enlarged explanatory diagram of the portion indicated by a dotted line Hi in FIG. 74.

As illustrated in FIG. 73, an acoustic wave device 10AA according to the 29th modification differs from the example embodiments and modifications described above in that the width of each load film 50 in the X direction (the arrangement direction) varies in the Y direction (the direction perpendicular or substantially to the arrangement direction). Specifically, the width of each load film 50 in the X direction continuously increases from one side toward the other side in the Y direction. The width of the load film 50 in the X direction at the end on the busbar electrode 33 side is greater than that at the end on the busbar electrode 34 side. FIG. 73 is merely an example, and the shape of the load films 50 can be properly changed. For example, at least a portion of each load film 50 in the extending direction may differ in width in the X direction from that of the other portion.

The film thickness of the piezoelectric layer 20 according to the 29th modification is, for example, about 180 nm. The first and second protective films 41 and 42 include, for example, silicon oxide. The film thicknesses of the first and second protective films 41 and 42 are, for example, about 142 nm, respectively. The electrode structure of the IDT electrode 30 is, for example, a laminate film of Ti, AlCu, Ti, and AlCu from the piezoelectric layer 20 side, and their film thicknesses are about 12 nm, about 70 nm, about 18 nm, and about 12 nm, respectively. The total number of electrode fingers 31 and 32 of the IDT electrode 30 is, for example, 101. The electrode pitch of the electrode fingers 31 and 32 is, for example, about 2.38 μm, and the electrode widths thereof are, for example, about 0.6 μm, respectively. The lengths of the electrode fingers 31 and 32 in the extending direction within the intersecting region C are, for example, about 40 μm.

The material of the load film 50 is, for example, silicon oxide, and the film thickness of the load film 50 is, for example, about 55 nm. The width W1 of the load film 50 is, for example, about 0.8 μm. The width W1a of the overlap region of the load film 50 with the first and second electrode fingers 31a and 32a is, for example, about 0.3 μm. The width W1 of the load film 50 changes by about 0.4 μm along the Y direction.

As illustrated in FIGS. 74 and 75, the acoustic wave device 10AA according to the 29th modification can reduce or prevent spurious emissions at frequencies lower than the resonant frequency. That is, in the 29th modification, spurious emissions occur at higher frequencies than in the comparative example where the load film 50 has a constant width.

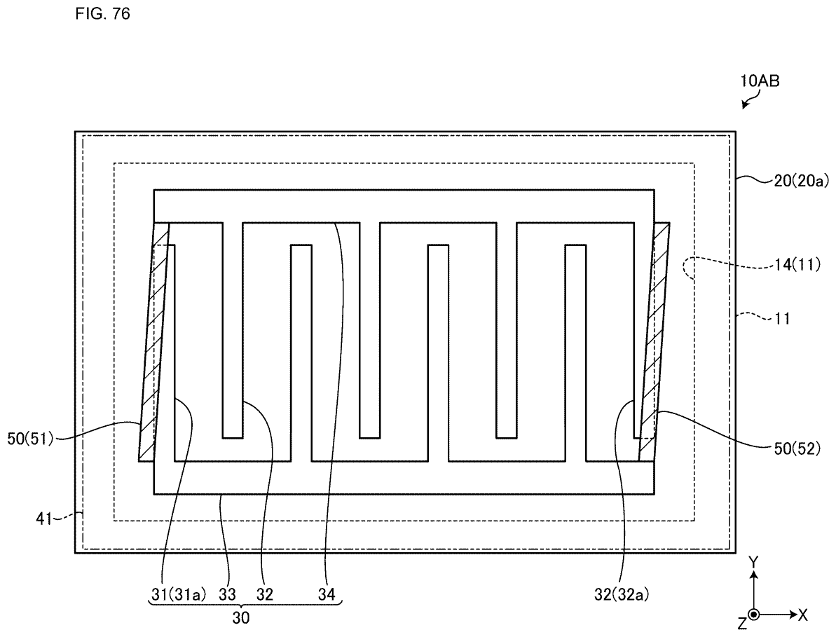

FIG. 76 is a plan view of an acoustic wave device according to a 30th modification. As illustrated in FIG. 76, an acoustic wave device 10AB according to the 30th modification differs from the example embodiments and modifications described above in that the extending direction of the load film 50 is inclined with respect to the extending direction (the Y direction) of the first and second electrode fingers 31a and 32a.

To be more specific, the width of the load films 50 in the X direction is constant in the extending direction of the load films 50. Furthermore, the widths W1a of the overlap regions of the load films 50 with the first and second electrode fingers 31a and 32a are inclined toward the same side with respect to the extending direction (the Y direction) of the first and second electrode fingers 31a and 32a, so that the first and second extending portions 51 and 52 of the load films 50 are parallel to each other.

The width W1a of the overlap region of the load film 50 (the first extending portion 51) with the first electrode finger 31a at the end on the busbar electrode 33 side is smaller than the width W1a of the overlap region with the first electrode finger 31a at the end on the busbar electrode 34 side. The width W1a of the overlap region of the load film 50 (the second extending portion 52) with the second electrode finger 32a at the end on the busbar electrode 33 side is greater than the width W1a of the overlap region with the second electrode finger 32a at the end on the busbar electrode 34 side.

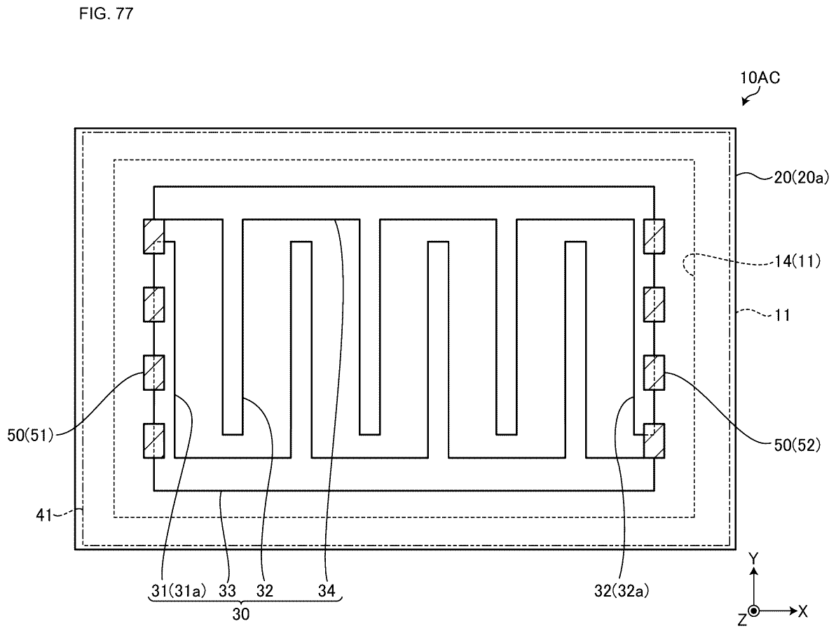

FIG. 77 is a plan view of an acoustic wave device according to a 31st modification. As illustrated in FIG. 77, an acoustic wave device 10AC according to the 31st modification differs from the example embodiments and modifications described above in that a plurality of load films 50 are spaced apart from each other in the extending direction (the Y direction) of the first and second electrode fingers 31a and 32a. Four load films 50 are aligned, overlapping the single first electrode finger 31a. Furthermore, four load films 50 are aligned, overlapping the single second electrode finger 32a. The number of load films 50 overlapping the single first electrode finger 31a may be three or less or five or more. The number of load films 50 overlapping the single second electrode finger 32a may be three or less or five or more.

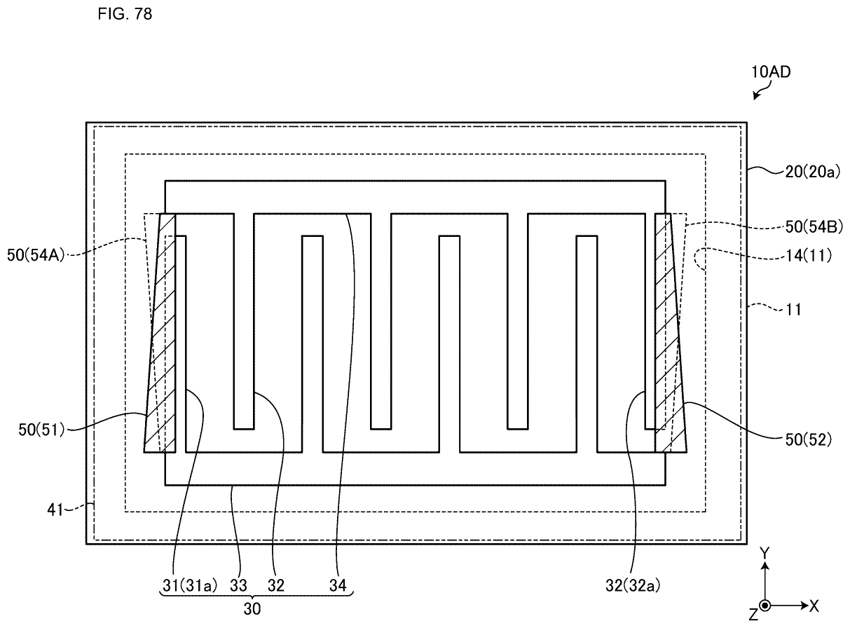

FIG. 78 is a plan view of an acoustic wave device according to a 32nd modification. As illustrated in FIG. 78, an acoustic wave device 10AD according to the 32nd modification differs from the example embodiments and modifications described above in that the shape of the load films 50 (the first and second extending portions 51 and 52) provided on the first major surface 20a side of the piezoelectric layer 20 is different from the shape of the load films 50 (the first and second lower extending portions 54A and 54B) provided on the second major surface 20b side of the piezoelectric layer 20.

The load films 50 (the first and second extending portions 51 and 52) provided on the first major surface 20a side of the piezoelectric layer 20 increase in width in the X direction from one side toward the other side in the Y direction. The load films 50 (the first and second lower extending portions 54A and 54B) provided on the second major surface 20b side of the piezoelectric layer 20 decreases in width in the X direction from the one side toward the other side in the Y direction.

The shape of the load films 50 (the first and second extending portions 51 and 52) provided on the first major surface 20a side of the piezoelectric layer 20 and the shape of the load films 50 (the first and second lower extending portions 54A and 54B) provided on the second major surface 20b side of the piezoelectric layer 20, which are illustrated in FIG. 78, are merely an example and may be any shape.

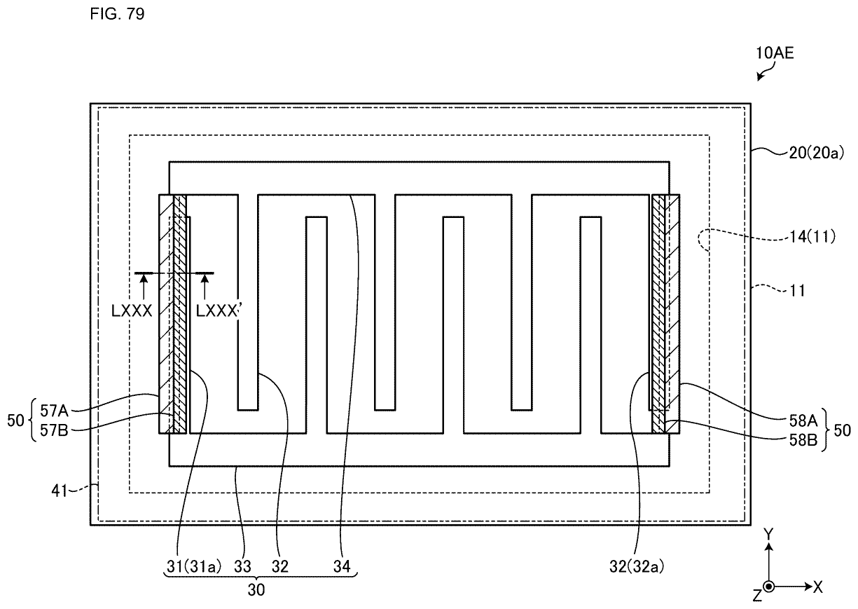

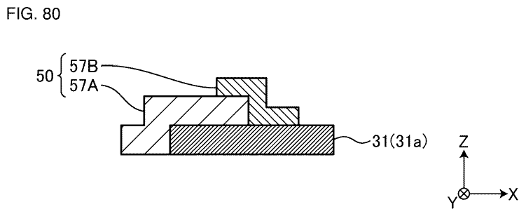

FIG. 79 is a plan view of an acoustic wave device according to a 33rd modification. FIG. 80 is a cross-sectional view along a line LXXX-LXXX′ in FIG. 79. As illustrated in FIGS. 79 and 80, an acoustic wave device 10AE according to the 33rd modification differs from the example embodiments and modifications described above in that the load film 50 overlapping the first electrode finger 31a includes a first load film 57A and a second load film 57B that overlaps a portion of the first load film 57A and the load film 50 overlapping the second electrode finger 32a includes a first load film 58A and a second load film 58B that overlaps a portion of the first load film 58A. The acoustic reflection plane of each load film 50 has a stepped shape.

As illustrated in FIG. 80, the first load film 57A of the load film 50 is positioned offset outward relative to the first electrode finger 31a in the arrangement direction of the plurality of electrode fingers 31 and 32. One side surface of the first load film 57A is disposed at the widthwise center of the first electrode finger 31a, and the other side surface of the first load film 57A is positioned on the outer side of the first electrode finger 31a in the arrangement direction. That is, the first load film 57A includes an overlap region that overlaps the first electrode finger 31a and a non-overlap region that does not overlap the first electrode finger 31a.

The second load film 57B is provided covering the one side surface of the first load film 57A. The second load film 57B includes an overlap portion that overlaps the first load film 57A and a non-overlap portion that overlaps the first electrode finger 31a and does not overlap the first load film 57A.

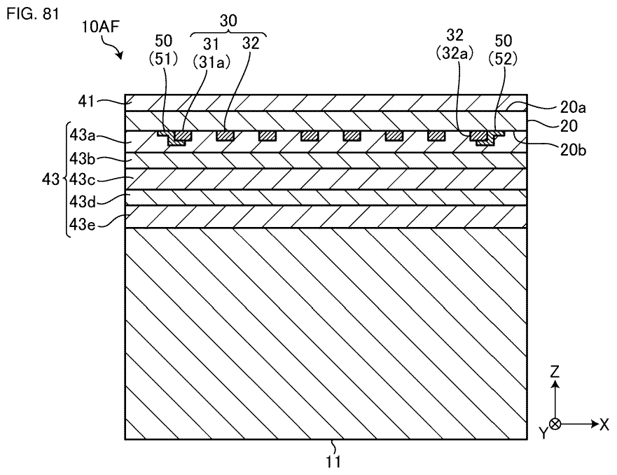

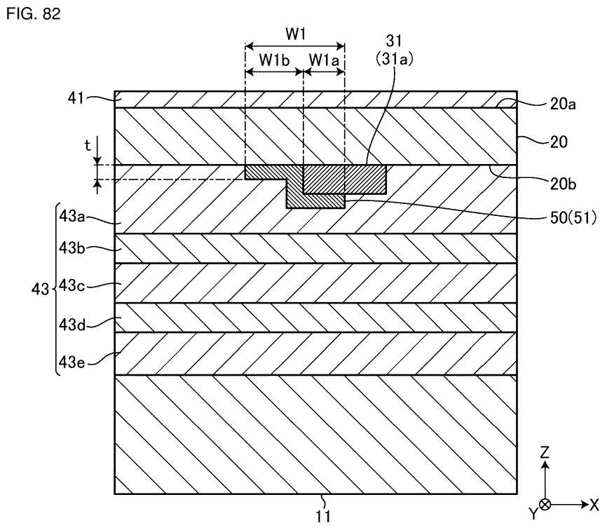

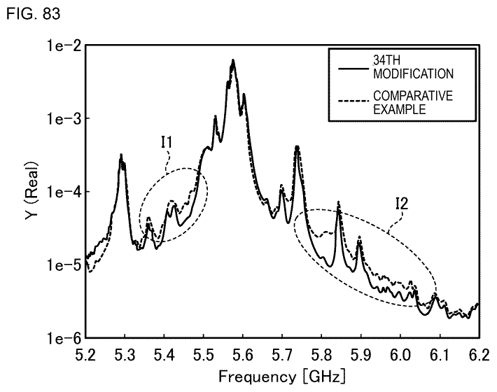

FIG. 81 is a cross-sectional view of an acoustic wave device according to a 34th modification. FIG. 82 is an enlarged cross-sectional view of a portion of FIG. 81. FIG. 83 is an explanatory diagram illustrating an example of the admittance characteristics of the acoustic wave device according to the 34th modification. As illustrated in FIGS. 81 and 82, an acoustic wave device 10AF according to the 34th modification differs from the 23rd modification (see FIG. 63) in that the IDT electrode 30 is provided on the piezoelectric layer 20 so as to be embedded in the high acoustic impedance layer 43b or 43d or the low acoustic impedance layer 43a, 43c, or 43e. In the acoustic wave device 10AF according to the 34th modification, the material of the load films 50 differs from that of the layer in which the IDT electrode 30 is embedded.

To be more specific, the IDT electrode 30 and the load films 50 are provided on the second major surface 20b of the piezoelectric layer 20, and the low acoustic impedance layer 43a covers the IDT electrode 30 and the load films 50.

In the 34th modification, the first protective film 41 includes, for example, silicon oxide (SiO₂), and the film thickness of the first protective film 41 is, for example, about 33 nm.

The piezoelectric layer 20 includes, for example, lithium niobate (LiNbO₃) and is a 1200±10° rotated Y cut. The film thickness of the piezoelectric layer 20 is, for example, about 300 nm.

The IDT electrode 30 includes, for example, Al, and the film thickness of the IDT electrode 30 is, for example, about 92 nm. The total number of electrode fingers 31 and 32 of the IDT electrode 30 is, for example, 43. The electrode pitch of the electrode fingers 31 and 32 of the IDT electrode 30 is, for example, about 3 μm, and the electrode width thereof is, for example, about 0.9 μm.

The acoustic multilayer film 43 includes, for example, SiO₂ (about 200 nm), Ta₂O₅ (about 122 nm), SiO₂ (about 188 nm), Ta₂O₅ (about 122 nm), SiO₂ (about 188 nm), Ta₂O₅ (about 122 nm), and SiO₂ (about 188 nm) laminated in this order from the second major surface 20b of the piezoelectric layer 20.

The support substrate 11 includes, for example, silicon (Si(100)).

The material of the load film 50 is, for example, Ta₂O₅, and the film thickness t of the load film 50 is, for example, about 80 nm. The width W1 of the load film 50 is, for example, about 800 nm. The width W1a of the overlap region of the load film 50 is, for example, about 450 nm. The width W1b of the non-overlap region of the load film 50 is, for example, about 350 nm.

As illustrated in FIG. 83, in the acoustic wave device 10AF according to the 34th modification, the loss in the frequency regions indicated by dotted lines I1 and I2 is reduced or prevented, compared with a comparative example not including any load films 50.

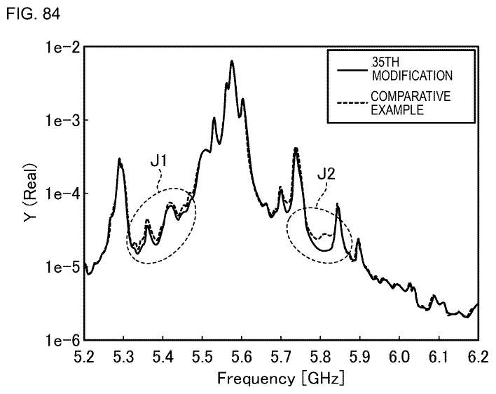

FIG. 84 is an explanatory diagram illustrating an example of the admittance characteristics of an acoustic wave device according to a 35th modification. The 35th modification differs from the 34th modification in that the material of each load film 50 is, for example, Si₃N₄. The film thickness t of the load film 50 is, for example, about 100 nm. The width W1 of the load film 50 is, for example, about 1000 nm. The width W1a of the overlap region of the load film 50 is, for example, about 450 nm. The width W1b of the non-overlap region of the load film 50 is, for example, about 550 nm.

As illustrated in FIG. 84, in the acoustic wave device according to the 35th modification, the loss in the frequency regions indicated by dotted lines J1 and J2 is reduced or prevented, compared with a comparative example not including any load films 50.

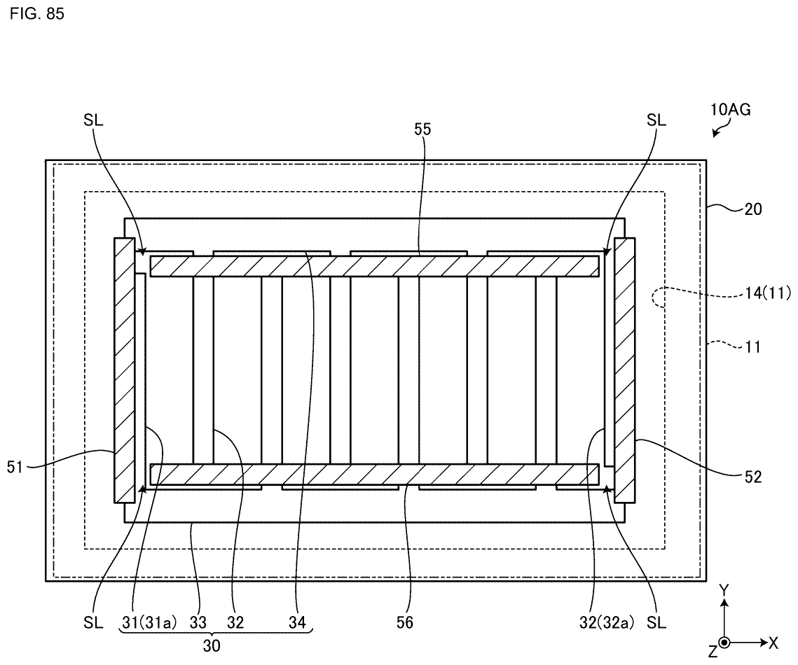

FIG. 85 is a plan view of an acoustic wave device according to a 36th modification. As illustrated in FIG. 85, an acoustic wave device 10AG according to the 36th modification differs from the acoustic wave device 10O according to the eighth example embodiment illustrated in FIG. 59 in that the first, second, third, and fourth extending portions 51, 52, 55, and 56 of the load film 50 are spaced apart from each other with slits SL interposed therebetween.

Specifically, the first extending portion 51 is provided in a region overlapping the first electrode finger 31a, which is positioned outermost in the arrangement direction of the plurality of electrode fingers 31 and 32, and extends in the extending direction of the first electrode finger 31a. The first extending portion 51 is disposed at the ends of the third and fourth extending portions 55 and 56 on one side in the extending direction and is spaced apart from the third and fourth extending portions 55 and 56 with the slits SL interposed therebetween.

One end of the first extending portion 51 in the extending direction (the Y direction) extends to a region overlapping the busbar electrode 34. The other end of the first extending portion 51 in the extending direction (the Y direction) extends to the region overlapping the busbar electrode 33.

The second extending portion 52 is provided in a region overlapping the second electrode finger 32a, which is positioned outermost in the arrangement direction of the plurality of electrode fingers 31 and 32 on the opposite side to the first electrode finger 31a and extends in the extending direction of the second electrode finger 32a. The second extending portion 52 is disposed at the ends of the third and fourth extending portions 55 and 56 on the other side in the extending direction and is spaced apart from the third and fourth extending portions 55 and 56 with the slits SL interposed therebetween.

One end of the second extending portion 52 in the extending direction (the Y direction) extends to a region overlapping the busbar electrode 34. The other end of the second extending portion 52 in the extending direction (the Y direction) extends to the region overlapping the busbar electrode 33.

The third extending portion 55 is disposed between the first and second extending portions 51 and 52 in the X direction and extends in the arrangement direction of the plurality of electrode fingers 31 and 32. The third extending portion 55 extends overlapping the ends of the plurality of electrode fingers 31 in the extending direction.

The fourth extending portion 56 is disposed between the first and second extending portions 51 and 52 in the X direction and extends in the arrangement direction of the plurality of electrode fingers 31 and 32. The fourth extending portion 56 extends overlapping the ends of the plurality of electrode fingers 32 in the extending direction.

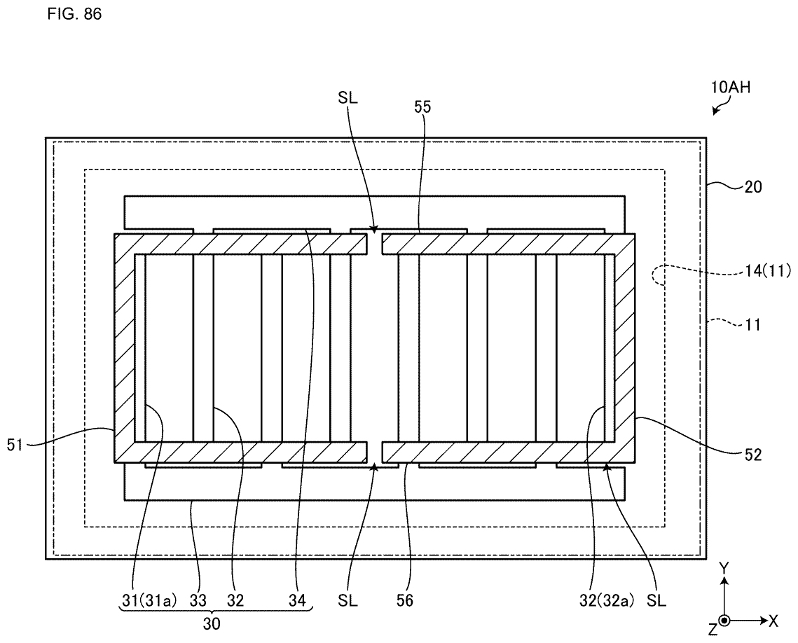

FIG. 86 is a plan view of an acoustic wave device according to a 37th modification. As illustrated in FIG. 86, an acoustic wave device 10AH according to the 37th modification differs from the acoustic wave device 100 according to the eighth example embodiment illustrated in FIG. 59 in that a slit SL is provided at the center of the third extending portion 55 of the load film 50 in the X direction and another slit SL is provided at the center of the fourth extending portion 56 in the X direction.

The third extending portion 55 is connected to ends of the first and second extending portions 51 and 52 on one side in the extending direction and extends in the arrangement direction of the plurality of electrode fingers 31 and 32. The third extending portion 55 overlaps the ends of the plurality of electrode fingers 31 on the other side in the extending direction. The third extending portion 55 is divided into two portions by the slit SL.

The fourth extending portion 56 is connected to the ends of the first and second extending portions 51 and 52 on the other side in the extending direction and extends in the arrangement direction of the plurality of electrode fingers 31 and 32. The fourth extending portion 56 overlaps the ends of the plurality of electrode fingers 32 in the extending direction. The fourth extending portion 56 is divided into two portions by the slit SL.

The positions of the slits SL are not limited to the center of the third extending portion 55 in the X direction and the center of the fourth extending portion 56 in the X direction and may be other different positions. The third extending portion 55 may be provided with two or more slits SL and may be divided into three or more portions by the slits SL. The fourth extending portion 56 may be provided with two or more slits SL and may be divided into three or more portions by the slits SL.

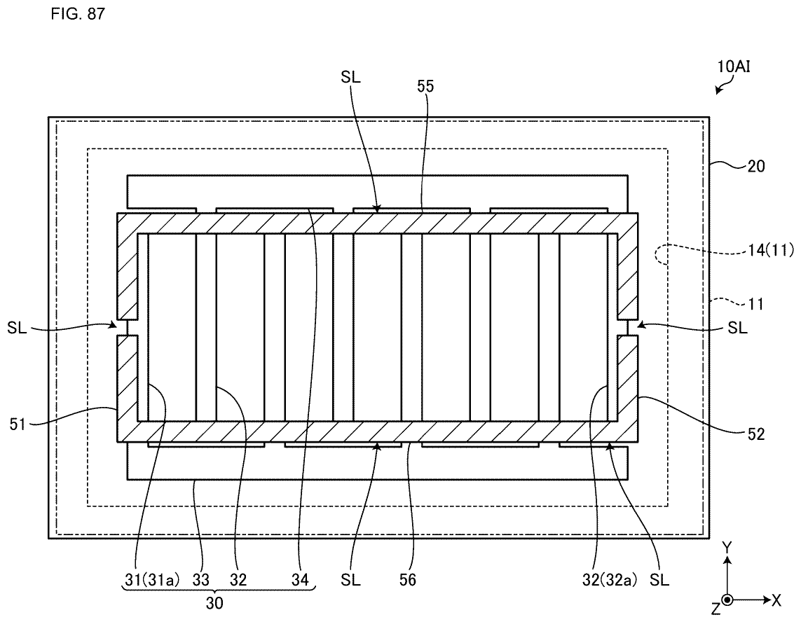

FIG. 87 is a plan view of an acoustic wave device according to a 38th modification. As illustrated in FIG. 87, an acoustic wave device 10AI according to the 38th modification differs from the acoustic wave device 10O according to the eighth example embodiment illustrated in FIG. 59 in that a slit SL is provided at the center of the first extending portion 51 of the load film 50 in the Y direction and another slit SL is provided at the center of the second extending portion 52 in the Y direction.

The first extending portion 51 is provided in a region overlapping the first electrode finger 31a, which is positioned outermost in the arrangement direction of the plurality of electrode fingers 31 and 32, and extends in the extending direction of the first electrode finger 31a. The first extending portion 51 is connected to ends of the third and fourth extending portions 55 and 56 on one side in the extending direction. The first extending portion 51 is divided into two portions by the slit SL.

The second extending portion 52 is provided in a region overlapping the second electrode finger 32a, which is positioned outermost in the arrangement direction of the plurality of electrode fingers 31 and 32 on the opposite side to the first electrode finger 31a, and extends in the extending direction of the second electrode finger 32a. The second extending portion 52 is connected to the ends of the third and fourth extending portions 55 and 56 on the other side in the extending direction. The second extending portion 52 is divided into two portions by the slit SL.

The positions of the slits SL are not limited to the center of the first extending portion 51 in the Y direction and the center of the second extending portion 52 in the Y direction and may be other different positions. The first extending portion 51 may be provided with two or more slits SL and may be divided into three or more portions by the slits SL. The second extending portion 52 may be provided with two or more slits SL and may be divided into three or more portions by the slits SL.

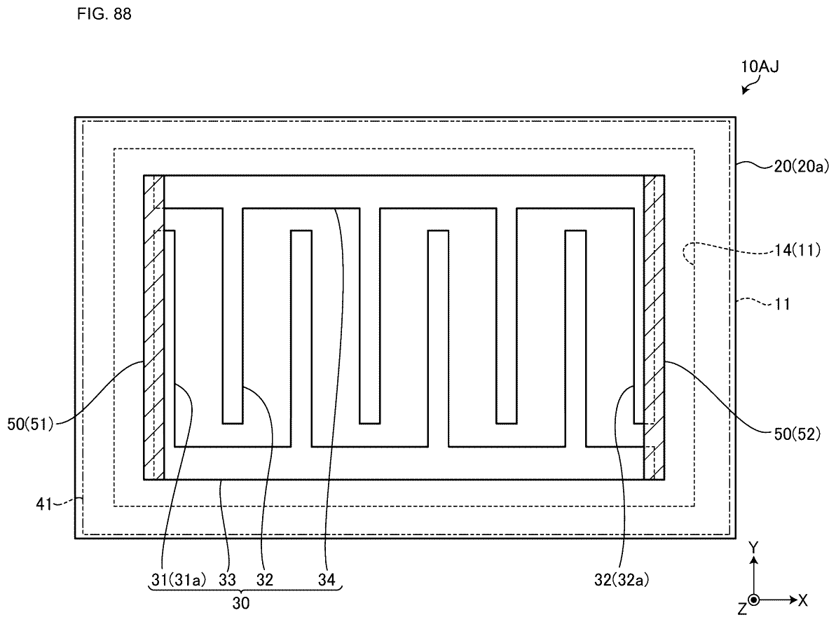

FIG. 88 is a plan view of an acoustic wave device according to a 39th modification. As illustrated in FIG. 88, an acoustic wave device 10AJ according to the 39th modification differs from the acoustic wave device 10 according to the first example embodiment illustrated in FIG. 1 in that each load film 50 extends to the positions overlapping the busbar electrodes 33 and 34.

One end of the first extending portion 51 of the load films 50 in the extending direction (the Y direction) overlaps an end of the busbar electrode 34 in the Y direction (the end on the opposite side to the electrode fingers 32). The other end of the first extending portion 51 in the extending direction (the Y direction) overlaps an end of the busbar electrode 33 in the Y direction (the end on the opposite side to the electrode fingers 31).

One end of the second extending portion 52 of the load films 50 in the extending direction (the Y direction) overlaps an end of the busbar electrode 34 in the Y direction (the end on the opposite side to the electrode fingers 32). The other end of the second extending portion 52 in the extending direction (the Y direction) overlaps the end of the busbar electrode 33 in the Y direction (the end on the opposite side to the electrode fingers 31).

With such a configuration, the acoustic wave device 10AJ according to the 39th modification can favorably reduce leakage of acoustic waves in the arrangement direction of the plurality of electrode fingers 31 and 32. The ends of the load films 50 in the extending direction coincide with the ends of the busbar electrodes 33 and 34. However, the present invention is not limited thereto, and the length of the load films 50 in the extending direction can be properly changed.

The materials of the load films 50 illustrated in the example embodiments and modifications described above are merely examples and can be properly changed. The load films 50 include, for example, at least one of carbon-added silicon oxide, silicon oxide, silicon nitride, tantalum oxide, aluminum nitride, alumina, hafnium oxide, niobium oxide, or tungsten oxide. Each load film 50 is not limited to a single-layer film and may be a multilayer film. Each load film 50 may include a combination of two or more of the materials described above.

The above-described example embodiments are provided to facilitate understanding of the present invention and are not intended to limit the present invention. The present invention can be modified or improved without departing from the spirit and scope thereof, and equivalents thereof are also included within the present invention.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a piezoelectric layer including a first major surface and a second major surface facing the first major surface in a first direction;
an interdigital transducer (IDT) electrode on at least one of the first major surface or the second major surface of the piezoelectric layer and including a plurality of electrode fingers arranged in a predetermined direction;
a support facing the second major surface of the piezoelectric layer and including an acoustic reflection portion on the second major surface side of the piezoelectric layer; and
a load film in a region that, in plan view in the first direction, overlaps at least one end portion of the IDT electrode in an arrangement direction of the plurality of electrode fingers; wherein
the end portion includes a first electrode finger positioned outermost in the arrangement direction among the plurality of electrode fingers; and
d/p is about 0.5 or less where d is a thickness of the piezoelectric layer and p is a center-to-center distance between adjacent ones of the plurality of electrode fingers.

2. The acoustic wave device according to claim 1, further comprising a protective film on at least one of the first major surface or the second major surface of the piezoelectric layer.

3. The acoustic wave device according to claim 2, wherein
the protective film includes a first protective film on the first major surface of the piezoelectric layer and covering the IDT electrode; and
the load film is on the first protective film.

4. The acoustic wave device according to claim 3, wherein, in a region overlapping the first electrode finger positioned outermost in the arrangement direction of the plurality of electrode fingers, a portion where the first protective film is provided and the load film is not provided and a portion where the load film and the first protective film are laminated define a step.

5. The acoustic wave device according to claim 2, wherein
the protective film includes a first protective film on the first major surface of the piezoelectric layer and covering the IDT electrode, and a second protective film on the second major surface of the piezoelectric layer; and
the load film is on a surface of the second protective film facing the support.

6. The acoustic wave device according to claim 1, wherein, in the first direction of the piezoelectric layer, the load film is located between the first major surface of the piezoelectric layer and the first electrode finger.

7. The acoustic wave device according to claim 1, wherein the load film is provided in a region overlapping the first electrode finger and one of the plurality of electrode fingers adjacent to the first electrode finger.

8. The acoustic wave device according to claim 1, wherein a number of the plurality of electrode fingers overlapping the load film is six or less, including the first electrode finger, an electrode finger adjacent to the first electrode finger, a second electrode finger positioned outermost in the arrangement direction on an opposite side to the first electrode finger, and an electrode finger adjacent to the second electrode finger.

9. The acoustic wave device according to claim 1, wherein the load film includes a first extending portion in a region overlapping the first electrode finger, and an outer load film in a region that does not overlap the IDT electrode on an outer side of the first extending portion in the arrangement direction.

10. The acoustic wave device according to claim 2, wherein
the protective film includes a first protective film on the first major surface of the piezoelectric layer and covering the IDT electrode, and a second protective film on the second major surface of the piezoelectric layer; and
the load film includes an upper load film on the first protective film, and a lower load film on a surface of the second protective film facing the support.

11. The acoustic wave device according to claim 10, wherein a width of the upper load film differs from a width of the lower load film.

12. The acoustic wave device according to claim 10, wherein a film thickness of the upper load film is smaller than a film thickness of the lower load film.

13. The acoustic wave device according to claim 10, wherein a material of the upper load film differs from a material of the lower load film.

14. The acoustic wave device according to claim 2, wherein a film thickness of the protective film is smaller than a film thickness of the piezoelectric layer.

15. The acoustic wave device according to claim 10, wherein at least one of the upper load film or the lower load film has a Young's modulus of about 50 GPa or higher.

16. The acoustic wave device according to claim 2, wherein the load film is on the first electrode finger positioned outermost in the arrangement direction.

17. The acoustic wave device according to claim 16, wherein
the protective film includes a first protective film on the first major surface of the piezoelectric layer and covering the load film and the IDT electrode; and
a region overlapping the first electrode finger positioned outermost in the arrangement direction includes a portion where the load film is provided and the first protective film is not provided, and a portion where the first protective film is provided and the load film is not provided.

18. The acoustic wave device according to claim 16, wherein
the protective film includes a first protective film on the first major surface of the piezoelectric layer and covering the load film and the IDT electrode; and
the load film includes a protrusion portion protruding from an upper surface of the first protective film.

19. The acoustic wave device according to claim 16, wherein
the protective film includes a first protective film on the first major surface of the piezoelectric layer and covering the load film and the IDT electrode; and
an upper surface of the load film is located in a same plane as an upper surface of the first protective film.

20. The acoustic wave device according to claim 2, wherein
the protective film includes a first protective film on the first major surface of the piezoelectric layer and covering the IDT electrode, and a second protective film on the second major surface of the piezoelectric layer;
the load film is provided on the second major surface of the piezoelectric layer; and
the second protective film covers the load film.

21. The acoustic wave device according to claim 2, wherein
the protective film includes a first protective film on the first major surface of the piezoelectric layer and covering the IDT electrode, and a second protective film on the second major surface of the piezoelectric layer;
the load film faces the second major surface of the piezoelectric layer and is spaced apart from the second major surface; and
the second protective film is located between the second major surface of the piezoelectric layer and the load film and covers a surface of the load film opposite to the piezoelectric layer.

22. The acoustic wave device according to claim 1, wherein the load film is provided on an outer side of the second major surface of the piezoelectric layer in the first direction.

23. The acoustic wave device according to claim 1, wherein the IDT electrode includes IDT electrodes provided on both of the first major surface and the second major surface of the piezoelectric layer.

24. An acoustic wave filter device, comprising:
at least one connected resonator including the acoustic wave device according to claim 1.

25. The acoustic wave filter device according to claim 24, further comprising:
an input terminal, an output terminal, a series arm coupling the input terminal and the output terminal, and a parallel arm coupling a node of the series arm and ground; wherein
the at least one resonator includes a plurality of resonators including a series arm resonator in the series arm and a parallel arm resonator in the parallel arm; and
the load film of the series arm resonator has a different configuration from the load film of the parallel arm resonator.

26. The acoustic wave device according to claim 1, wherein
the load film includes a first extending portion, a second extending portion, a third extending portion, and a fourth extending portion;
the first extending portion is provided in a region overlapping the first electrode finger positioned outermost in the arrangement direction, the first extending portion extending in an extending direction of the first electrode finger;
the second extending portion is provided in a region overlapping a second electrode finger positioned outermost in the arrangement direction on an opposite side to the first electrode finger, the second extending portion extending in an extending direction of the second electrode finger;
the third extending portion is connected to ends of the first and second extending portions on one side in an extending direction thereof and extends in the arrangement direction; and
the fourth extending portion is connected to ends of the first and second extending portions on another side in the extending direction thereof and extends in the arrangement direction.

27. The acoustic wave device according to claim 1, wherein
the load film includes a first extending portion, a second extending portion, a third extending portion, and a fourth extending portion;
the first extending portion is provided in a region overlapping the first electrode finger positioned outermost in the arrangement direction, the first extending portion extending in an extending direction of the first electrode finger;
the second extending portion is provided in a region overlapping a second electrode finger positioned outermost in the arrangement direction on an opposite side to the first electrode finger, the second extending portion extending in an extending direction of the second electrode finger;
the third extending portion is located at ends of the first and second extending portions on one side in an extending direction thereof and extends in the arrangement direction;
the fourth extending portion is located at ends of the first and second extending portions on another side in the extending direction thereof and extends in the arrangement direction; and
at least one of the third extending portion or the fourth extending portion is spaced apart from the first and second extending portions.

28. An acoustic wave device, comprising:
a piezoelectric layer including a first major surface and a second major surface opposite to the first major surface;
an interdigital transducer (IDT) electrode on the first major surface of the piezoelectric layer and including a plurality of electrode fingers arranged in a predetermined direction;
a support facing the second major surface of the piezoelectric layer;
a protective film on at least one of the first major surface or the second major surface of the piezoelectric layer; and
a load film in a region that does not overlap the IDT electrode on an outer side of a first electrode finger in an arrangement direction of the plurality of electrode fingers, the first electrode finger being positioned outermost among the plurality of electrode fingers in the arrangement direction; wherein
d/p is about 0.5 or less where d is a thickness of the piezoelectric layer and p is a center-to-center distance between adjacent ones of the plurality of electrode fingers; and
L/p is about 0.9 or less where L is a distance between the first electrode finger and the load film in the arrangement direction of the plurality of electrode fingers.

29. The acoustic wave device according to claim 2, wherein the load film includes a material with a higher density than a density of the protective film.

30. The acoustic wave device according to claim 2, wherein the load film includes a material with a lower density than a density of the protective film.

31. The acoustic wave device according to claim 2, wherein the load film includes a material with a higher Young's modulus than a Young's modulus of the protective film.

32. The acoustic wave device according to claim 2, wherein
the load film and the protective film include a same material; and
a density of the load film differs from a density of the protective film.

33. The acoustic wave device according to claim 2, wherein the protective film includes silicon oxide.

34. The acoustic wave device according to claim 1, wherein the piezoelectric layer includes lithium niobate or lithium tantalate and is a 120°±10° rotated Y cut or a 90°±10° rotated Y cut.

35. The acoustic wave device according to claim 2, wherein the protective film includes a first protective film on the first major surface of the piezoelectric layer and covering the IDT electrode, and a second protective film on the second major surface of the piezoelectric layer.

36. The acoustic wave device according to claim 2, wherein a film thickness of the protective film is greater than a film thickness of the IDT electrode.

37. The acoustic wave device according to claim 35, wherein A/B is about 1−0.06 or more and about 1+0.06 or less, where A is a total distance from a film thickness center of the piezoelectric layer to a top surface of the first protective film and B is a total distance from the film thickness center of the piezoelectric layer to a top surface of the second protective film.

38. The acoustic wave device according to claim 35, wherein an upper surface of the first protective film and a lower surface of the second protective film are flat.

39. The acoustic wave device according to claim 1, wherein a material of the load film includes at least one of carbon-added silicon oxide, silicon oxide, silicon nitride, tantalum pentoxide, aluminum nitride, aluminum oxide, hafnium oxide, niobium pentoxide, or tungsten oxide.

40. The acoustic wave device according to claim 1, wherein
an electrode width of the first electrode finger positioned outermost in the arrangement direction is less than an electrode width of an electrode finger of the electrode fingers positioned in a center in the arrangement direction; and
an electrode pitch of the first electrode finger and an electrode finger of the electrode fingers adjacent to the first electrode finger is less than an electrode pitch of more than one electrode finger of the electrode fingers positioned in the center in the arrangement direction.

41. The acoustic wave device according to claim 1, wherein
an electrode width of the first electrode finger positioned outermost in the arrangement direction is greater than an electrode width of an electrode finger of the electrode fingers positioned in a center in the arrangement direction; and
an electrode pitch of the first electrode finger and an electrode finger of the electrode fingers adjacent to the first electrode finger is greater than an electrode pitch of more than one electrode finger of the electrode fingers positioned in the center in the arrangement direction.

42. The acoustic wave device according to claim 1, wherein d/p is about 0.24 or less.

43. The acoustic wave device according to claim 1, wherein
a region in which adjacent ones of the plurality of electrode fingers overlap each other when viewed in the arrangement direction and which is defined by centers of the adjacent ones of the plurality of electrode fingers in the arrangement direction is an excitation region; and
MR≤about 1.75(d/p)+0.075, where MR is a metallization ratio of the electrode fingers to the excitation region.

44. The acoustic wave device according to claim 1, wherein the piezoelectric layer includes lithium tantalate or lithium niobate.

45. The acoustic wave device according to claim 1, wherein Euler angles (p, θ, ψ) of lithium niobate or lithium tantalate of the piezoelectric layer are within a range defined by an expression 1, 2, or 3:
(0°±10°, 0° to 20°, any ψ) Expression (1);
(0°±10°, 20° to 80°, 0° to 60° (1−(θ−50)²/900)^{1/2}) or (0°±10°, 20° to 80°, [180°−60°(1−(θ−50)²/900)^{1/2}] to 180°) Expression (2); and
(0°±10°, [180°−30° (1−(ψ−90)²/8100)^{1/2}] to 180°, any ψ) Expression (3).

46. The acoustic wave device according to claim 1, wherein
the acoustic reflection portion includes a hollow portion; and
the support and the piezoelectric layer are arranged such that a portion of the support and a portion of the piezoelectric layer face each other across the hollow portion.

47. The acoustic wave device according to claim 1, wherein
the acoustic reflection portion includes an acoustic reflection film including a high acoustic impedance layer with a relatively high acoustic impedance and a low acoustic impedance layer with a relatively low acoustic impedance; and
the support and the piezoelectric layer are arranged such that at least a portion of the support and at least a portion of the piezoelectric layer face each other across the acoustic reflection film.

48. The acoustic wave device according to claim 1, wherein
a ratio G/p of an offset amount G of the load film to a center-to-center distance p between adjacent ones of the plurality of electrode fingers satisfies about −0.2≤G/p≤about +0.2, where in the arrangement direction of the plurality of electrode fingers, the offset amount G of the load film is a distance between one side surface of the load film and a widthwise midpoint of the first electrode finger.

49. The acoustic wave device according to claim 1, wherein a width of the load film in the arrangement direction varies in a direction perpendicular or substantially perpendicular to the arrangement direction.

50. The acoustic wave device according to claim 47, wherein
the IDT electrode is embedded in the high acoustic impedance layer or the low acoustic impedance layer; and
a material of the load film differs from a material of the high acoustic impedance layer or the low acoustic impedance layer in which the IDT electrode is embedded.
